(19) United States
(12) Patent Application Publication
(10) Pub. No.: US 2003/0007648 A1
(43) Pub. Date: Jan. 9, 2003

(54) Virtual audio system and techniques

(76) Inventor: Christopher Currell, Boulder, CO (US)

Correspondence Address: WILLIAM D. HARE, Fish & Richardson P.C., 11th Floor, 1425 K Street, N.W., Washington, DC, 20005-3500, US

(21) Appl. No.: 10/134,035

(22) Filed: Apr. 29, 2002

Related U.S. Application Data
(60) Provisional application No. 60/286,599, filed on Apr. 27, 2001.

(51) Int. Cl. H03G 3/00

(52) U.S. Cl. 381/61; 381/63

(57) ABSTRACT

A sound processing apparatus for creating virtual sound sources in a three dimensional space includes a number of modules. These include an aural exciter module; an automated panning module; a distance control module; a delay module; an occlusion and air absorption module; a Doppler module for pitch shifting; a location processor module; and an output.

### RELATED APPLICATIONS

This application claims priority from U.S. Provisional Application Serial No. 60/286,599, filed Apr. 27, 2001, the entirety of which is incorporated herein by reference.

### TECHNICAL FIELD

This invention relates generally to the field of acoustics and more particularly to a method and apparatus for reverberant sound processing and reproduction which captures both the temporal and spatial dimensions of a three-dimensional natural reverberant environment.

### BACKGROUND

A natural sound environment comprises a continuum of sound source locations including direct signals from the location of the sources and indirect reverberant signals reflected from the surrounding environment. Reflected sounds are most notable in the concert hall environment in which many echoes reflected from various different surfaces in the room producing the impression of space to the listener. This effect can vary in evoked subjective responses; for example, in an auditorium environment it produces the sensation of being surrounded by the music. Most music heard in modern times is either in the comfort of one's home or in an auditorium, and for this reason most modern recorded music has some reverberation added before distribution either. The reverberation can be added by a natural process (e.g., recordings made in concert halls) or by artificial processes (e.g., electronic reverberation techniques).

When a sound event is transduced into electrical signals and reproduced over loudspeakers and headphones, the experience of the sound event is altered dramatically due to the loss of information utilized by the auditory system to determine the spatial location of the sound events (i.e., direction and distance cues) and due to the loss of the directional aspects of reflected (i.e., reverberant) sounds. In the prior art, multi-channel recording and reproduction techniques, including reverberation from the natural environment, retain some spatial information, but these techniques do not re-create the spatial sound field of a natural environment and, therefore, create a listening experience which is spatially impoverished.

A variety of prior art reverberation systems are available which artificially create some of the attributes of natural occurring reverberation and thereby provide some distance cues and room information (i.e., size, shape, materials, etc.,). These existing reverberation techniques produce multiple delayed echoes by means of delay circuits, many providing re-circulating delays using feedback loops. A number of refinements have been developed including a technique for simulating the movement of sound sources in a reverberant space by manipulating the balance between direct and reflected sound in order to provide the listener with realistic cues as to the perceived distance of the sound source. Another approach simulates the way in which natural reverberation becomes increasingly low pass with time as the result of the absorption of high frequency sounds by the air and reflecting surfaces. This technique utilizes low pass filters in the feedback loop of the reverberation unit to produce the low pass effect.

Despite these improved techniques, existing reverberation systems fail in their efforts to simulate real room acoustics, which results in simulated room reverberation that does not sound like real rooms. This is partially due to these techniques attempting to replicate an overall reverberation typical of large reverberant rooms, thereby passing up the opportunity to utilize the full range of possible applications of sound processing applying to many different types of music and natural environments. In addition, these existing approaches attempt only to capture general characteristics of reverberation in large rooms without attempting to replicate any of the exact characteristics that distinguish one room from another, and they do not attempt to make provisions for dynamic changes in the location of the sound source or the listener, thus not effectively modeling the dynamic possibility of a natural room environment. In addition, these methods are intended for use in conventional stereo reproduction and make no attempt to localize or spatially separate the reverberant sound. One improved technique of reverberation attempts to capture the distribution of reflected sound in a real room by providing each output channel with reverberation that is statistically similar to that coming from part of a reverberant room. Most of these contemporary approaches to simulate reverberation treat reverberation as totally independent of the location of the sound source within the room and are therefore only suited to simulating large rooms. Furthermore, these approaches provide incomplete spatial cues which produces an unrealistic illusory environment.

In addition to reverberation which provides essential elements of spatial cues and distance cues, much pschyo-acoustic development and research has been done into directional cues which include primarily interaural time differences (i.e., different time of arrival at the two ears), low pass shadow effect of the head, pinna transfer functions, and head and torso related transfer functions. This research has largely been confined to efforts to study each of these cues as independent mechanisms in an effort to understand the auditory system's mechanisms for spatial hearing.

Pinna cues are important cues for determining directionality. It has been found that one ear can provide information to localize sound, and even the elevation of sound source can be determined under controlled conditions where the head is restricted and reflections are restricted. The pinna, which is the exposed part of the external ear, has been shown to be the source of these cues. The ear's pinna performs a transform on the sound by a physical action on the incident sound causing specific spectral modifications unique to each direction. In this manner, directional information is encoded into the signal reaching the ear drum. The auditory system is then capable of detecting and recognizing these modifications, thus decoding the directional information. The imposition of pinna transfer functions on a sound stream have shown that directional information is conveyed to a listener in an anechoic chamber. Previous efforts to use pinna cues and other directional cues have succeeded only in directionalizing a sound source but not in localizing (i.e., both direction and distance) the sound source in three-dimensional space.

However, when imposing pinna transfer functions on a sound stream which is reproduced in a natural environment, the projected sound paths are deformed. This results from the directional cues being altered by the acoustics of the listening environment, particularly as a result of the pattern of the reflected sounds. The reflected sound of the listening environment creates conflicting locational cues, thus altering the perceived direction and the sound image quality. This results from the auditory system tending to combine the conflicting and the natural cues evaluating all available auditory information together to form a composite spatial image.

### SUMMARY

In general, spatial room simulation consists of numerous audio signal routings to achieve realistic and complex virtual acoustic environments. These routing schematics take on different forms depending on what the desired effect is needed to be achieved. Implemented within these routing schematics may be various signal processors such as volume, delay, reverb, pitch shifters, panning and equalization that are inserted into the audio signal path. For example, if the user wishes to spatialize a stereo mix such as a CD, a specific audio signal path in conjunction with numerous positional (directionalized) audio channels would be required. Within a basic configuration, there can be many different variations that can be implemented depending on the desired effect. These different audio signal paths and routings can range from fairly simple to very complex depending on the application. All signal paths (direct and reverberent) are then directionalized through the use of head related transfer functions (“HRTF”) to achieve the illusion that the desired audio effect is coming from a specific location in a three-dimensional space. The methodologies, processes, and techniques for combining and implementing audio signal routings, signal processing, and digital reverberators are explained. A summary of the factors involved include:

1. Number of positional (directionalized) audio streams;

2. Number of positional (directionalized) reverberant streams;

3. Various audio signal connections;

4. Various audio signal routings;

5. Implementation of audio signal panning;

6. Implementation of audio signal level;

7. Implementation of audio signal delays;

8. Implementation of audio signal pitch shifting;

9. Implementation of audio signal equalization; and

10. Configurations of digital reverberators in the audio signal path.

Many basic configurations are described and/or illustrated herein, ranging from simple configurations to complex configurations, as well as variations on each.

In general, room simulation is an essential requirement for the creation of realistic virtual acoustic environments. Standard reverberators that are readily available in the professional audio marketplace are used specifically with the numerous audio signal routings described above to achieve such realistic environments. An explanation of how standard digital reverberators are implemented and directionalized is described below. Provided below is a list of important factors that are useful in the choice and use of various digital reverberators.

1. Minimum audio specifications of a digital reverberator;

2. Configurations of digital reverberator (i.e., mono, stereo, parallel etc.);

3. Multiple channels of digital reverberation;

4. Early reflections;

5. Diffuse field; and

6. Ambiance.

Described below is information on general and specific attributes a digital reverberator should generally posses to create a realistic spatial room model. Also included is an overview of the theory of digital reverberators and implementations of various techniques and configurations, and what is to be expected of each.

In one general aspect, a sound processing apparatus for creating virtual sound sources in a three dimensional space includes an aural exciter module; an automated panning module; a distance control module; a delay module; an occlusion and air absorption module; a Doppler module for pitch shifting; a location processor module; and an output.

Embodiments of the sound processing apparatus may include one or more of the following features. For example, the aural exciter module may be configured to receive an input from a multi-track output. The delay module may be configured to delay sound for between 0 milliseconds and 300 milliseconds. The location processor module may be configured to use head related transfer functions to process a signal. The location processor module may be configured to use a FIR filter to process a signal. The location processor module may be configured to use a free field equalization to process a signal.

In another general aspect, a sound processing apparatus for creating virtual sound sources in a three dimensional space includes means for providing direct audio signals; reverberation means for creating at least one reverberant stream of signals from the audio signals to simulate a desired configuration of reflected sound; and directionalizing means for applying spectral directional cues to one or multiple reverberant streams to generate at least one pair of output signals.

Embodiments of the sound processing apparatus may include one or more of the following features. For example, the multiple reverberant streams may be generated by the reverberation means and the directionalizing means may be configured to apply a directionalizing transfer function to each reverberant stream to generate multiple directionalized reverberant streams from each reverberant stream. The apparatus may further include output means for producing a multiple of output signals, each output signal comprising the sum of multiple directionalized reverberant streams, and each being derived from a different reverberant stream. Each reverberant stream may include at least one direct sound component and a free field directional cue is superimposed on the direct sound component. The apparatus may further include a stereo filter means for filtering at least one pair of directionalized reverberant streams. The apparatus may further include a gain control configured to emphasize at least one part of one reverberant stream. The apparatus may further include specifications of a reverberant apparatus for the application of scaling data to the audio signals to simulate sound absorption and reflection. The apparatus may further include specifications of a reverberant apparatus for the implementation of a filter to filter the audio signals to simulate sound absorption and reflection.

The reverberant apparatus may further include specifications for applying scaling to the filter for simulating sound absorption of reverberant sound reflections. The apparatus may further include means for controlling the reverberation apparatus and directionalizing capability responsive to input control signals. The head related transfer function based directionalizing capability may further include the capability for dynamically changing the spectral directional cues to simulate sound source and listener motion. Each reverberant stream may simulate reflections from a selected spatial location and each reverberant stream is directionalized to provide an accurate simulation of the reverberant stream coming from the selected region. The configuration of the reflected sound may be changed dynamically and the directionalizing means may further include means for modifying spectral directional cues responsive to the dynamic changes of the configuration of reflected sound.

The sound processing apparatus may include multiples of directionalized reverberant streams that are generated such that they simulate the reflection pattern of a specified room. The reverberant apparatus may include means for modifying the configuration of reflected sound in response to changes in the spectral directional cues. The directionalizing apparatus may further include the capability for generating spectral directional cues to simulate source motion. The directionalizing apparatus may further include a means for generating the dynamic directionalizing transfer functions to simulate listener motion.

In another general aspect, a spatial room simulation system for simulating the frequency and time domain of reverberant sound includes a means for processing audio signals utilizing spectral directional cues to produce at least one directionalized audio stream including reverberant audio signals providing a selected HRTF based directionalized distribution of virtual reflected sound; and a means for outputting the audio stream.

Embodiments of the spatial room simulation system may include one or more of the following features. For example, the means for processing may utilize modeled pinna cues, such as HRTFs, to produce the directionalized audio stream. The means for processing may further include a means for dynamically changing the frequency and time distribution.

In another general aspect, a reverberation apparatus includes a first means for generating a reverberation stream from a single channel input, such as a mono input, and a single channel output, such as a mono output, and a second means for generating and outputting a multiple of different mono input, mono output reverberation streams.

Embodiments of the apparatus may include one or more of the following features. For example, the apparatus may further include a directionalizing means for applying spectral directional cues to at least one of a multiple of different reverberant streams. The means for generating may include a modeling means for generating the multiples of unique reverberant streams so as to simulate a calculated reflection pattern of a selected model room. The modeling means may include a means for generating and directionalizing each different reverberant stream so as to simulate directionality and calculated reflection delays of a respective section of the selected model room. The model room may be a room of any size.

In another general aspect, a sound processing apparatus includes a means for input of source audio signals; a reverberation means for generating at least one reverberant stream of signals comprising delayed source audio signals to simulate a desired configuration of reflected sounds; a directionalizing means for applying to at least part of said one reverberant stream a directionalizing transfer function to generate at least one directionalized reverberant stream; and a means for combining at least one directionalized reverberant stream and the source audio signal, which is not directionalized by the first directionalizing means, to generate an output signal.

Embodiments of the sound processing apparatus may include one or more of the following features. For example, the sound processing apparatus may further include a second directionalizing means for applying a directionalizing transfer function to the source audio signal.

In another general aspect, a sound processing apparatus for modeling of a selected model room includes a means for providing audio signals; and a means to be responsive to the audio signals for producing multiple reverberant streams comprising multiple simulated reflections with calculated delay times and with each reverberant stream directionalized with calculated spectral directional cues so as to simulate time of arrival and direction of arrival base upon calculated values determined for the selected model room and selected source and listener locations within the model room.

Embodiments of the sound processing apparatus may include one or more of the following features. For example, a multiple of first and second order simulated reflections are delayed and directionalized based directly upon calculated values for the model room and any higher order simulated reflections have arrival times based upon the model room and are directionalized so as to simulate arrival from a calculated region of the model room. The sound processing apparatus may further include means for dynamically changing the delay times and directional cues to permit continuous change of source and listener location within the model room and continuous change in the dimensions of the model room.

It is accordingly an object to provide methodologies, processes and techniques to simulate reflected sound along with pinna cues imposed upon the reflected sound in a manner so as to overwhelm the characteristics of the actual listening environment to create a selected spatio-temporal distribution of reflected sound.

It is another object to provide methodologies, processes and techniques to utilize spectral cues to localize both the direct sound source and its reverberation in such a way as to capture the perceptual features of a three-dimensional listening environment.

It is another object to provide methodologies, processes and techniques for producing a realistic illusion of three-dimensional localization of sound source utilizing a combination of directional cues and controlled reverberation.

It is another object to provide novel audio processing methodologies, processes and techniques capable of controlling sound presence and definition independently.

According to one embodiment of the invention, an audio signal processing method is provided comprising the steps of generating at least one reverberant stream of audio signals simulating a desired configuration of reflected sound and superimposing at least one pinna directional cue on at least one part of one reverberant stream. In addition, sound processing techniques are provided for creating illusory sound sources in three-dimensional space. The sound processing technique comprises an input for receiving input audio signals and reverberation means for generating at least one reverberant stream of audio signals from the input audio signals to simulate a desired configuration of reflected sound. A directionalizing means is also provided for applying to at least part of one reverberant stream a pinna transfer function to generate at least one output signal.

The method and apparatus can provide considerable advantages. For example, imaging is excellent, including depth and height, whether playback is in the usual equilateral-triangle stereo listening situation or in a narrow-stage arrangement, such as loudspeakers flanking a television screen. The listening area is wide, without sharp sweet-spot limitations.

A good approximation of a virtual audio presentation is available by using four loudspeakers: two as a front pair and two at the sides or behind the listening position. The second pair of loud speakers receives the same signals as the front pair, at a slightly reduced level. No signal processing is required for the listener. Headphone listening of virtual audio is excellent, and a complete 360 degree immersed sound field is obtained. Virtual audio removes the annoying “in the center of your head” feeling that is common with headphones, and exteriorizes all the sounds outside the listener's head.

Mono playback is also not compromised due to the amplitude and phase flatness of the technology. Although the spatial quality is lost, intelligibility is greatly enhanced.

The details of one or more embodiments of the invention are set forth in the accompanying drawings and the description below. Other features, objects, and advantages of the invention will be apparent from the description, the drawings, and the claims.

### DESCRIPTION OF DRAWINGS

FIG. 1 is a room simulator channel block diagram.

FIG. 2 is a room simulation mixing schematic block diagram.

FIG. 3 is a virtual reflection location layout showing eight reflections.

FIGS. 4-10 are block diagrams for an early reflection, basic configuration with three, four, six, eight, ten, fourteen, and sixteen reflections, respectively.

FIGS. 11 and 12 are block diagrams for a spatial room simulation, basic configuration with three and sixteen reflections, respectively.

FIG. 13 is a block diagram of a spatially enhanced stereo system.

FIG. 14 is a digital routing diagram for an eight channel room simulation.

FIG. 15 is a block diagram for a spatial room simulator.

FIGS. 16-24 are illustrations of the paths that various sounds in a simulation.

FIGS. 25-29 are block diagrams for a virtual audio processing system.

FIG. 30 is a cross-talk cancellation illustration showing transmission paths from loudspeakers.

FIGS. 31 and 32 are virtual speaker placement diagrams for headphone listening and speaker listening simulations, respectively.

FIG. 33 is a center speaker diagram for a virtual audio processing system.

FIG. 34 is a virtual headphone block diagram.

FIG. 35 is a virtual audio reverb panning system block diagram.

FIG. 36 is a VAPS block diagram of a first configuration.

FIGS. 37 and 38 are front and side views and a block diagram for a virtual speaker system.

FIGS. 39-50 are block diagrams of configurations and implementations of virtual audio processing systems.

FIGS. 51-54 are diagrams of another configuration of a virtual audio processing system.

FIGS. 55-82 are diagrams, drawings, and illustrations of virtual audio processing systems and techniques.

Like reference symbols in the various drawings indicate like elements.

### DETAILED DESCRIPTION

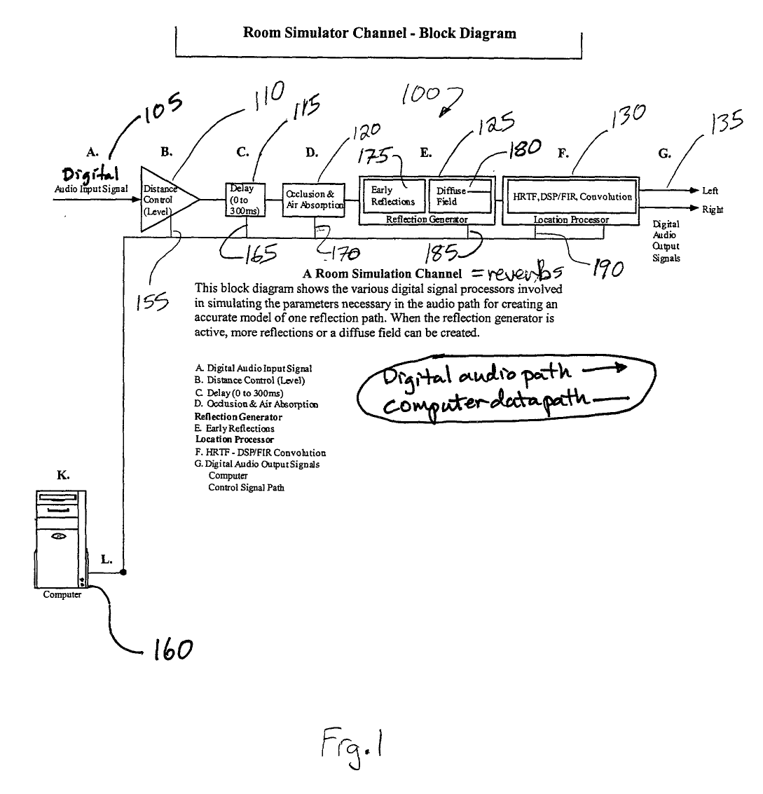

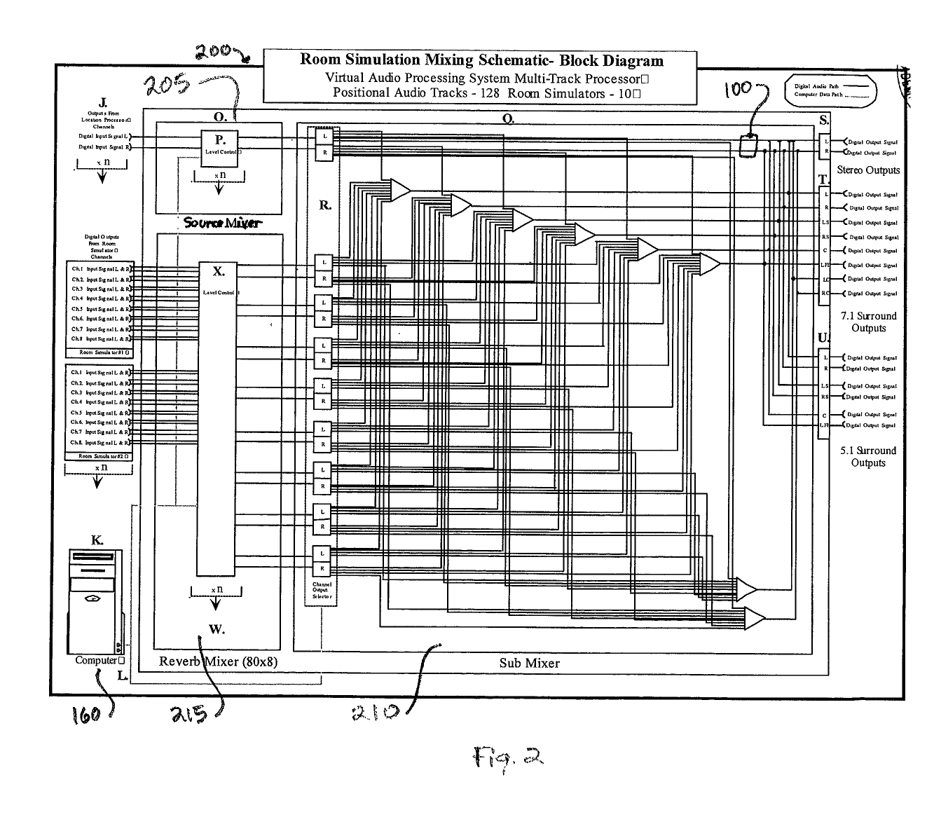

Referring to FIGS. 1 and 2, one of the basic components used to create a virtual acoustic environment is room simulation (commonly called reverberation) using a room simulator module 100. The room simulator 100 includes a digital audio input signal 105, a distance control module 110, a delay module 115, an occlusion and air absorption module 120, a reflection generator 125, a location processor 130, an output mixer 135, a source mixer 140, a sub mixer 145, and a reverb mixer 150. To accurately simulate an acoustic environment, a reverberation device generating a reverberant stream must be directionalized using measured head related transfer functions (“HRTF”). This reverberant stream (or channel) is a result of several processes which include several digital signal processing (“DSP”) modules. The signal path to one spatial room simulator channel begins with the digital audio input signal 105 whose signal amplitude feeds directly to the distance control module 110. The audio input signal 105 may be, for example, audio from a compact disc, live or recorded voice, etc.

The distance control module 110 is typically the first module in the signal path. The principal cue for distance is the loudness of the sound. For example, a sound source will be louder when it is closer to the listener than when it is farther away. However, this cue is often ambiguous because the listener does not know prior how loud the source is originally. Thus, a moderately loud crashing sound can be perceived as a quiet, close crash, or a distant, loud crash.

Another important cue for distance is the relative loudness of reverberation. When sound is produced in a reverberant space, the associated reverberation may often be perceived as background ambience, separate from the foreground sound. The loudness of the reverberation relative to the loudness of the foreground sound is an important distance cue. The reason for functioning as a cue is the acoustics of reverberant spaces. The foreground sound consists largely of the sound that propagates directly from the sound source to the listener. This so-called direct sound decreases in amplitude as the distance to the listener increases. For every doubling of distance, the amplitude of the direct sound decreases by a factor of one half, or 6 dB. The amplitude of the reverberation, on the other hand, does not decrease considerably with increasing distance. The ratio of the direct to reverberant amplitude is greater with nearby objects than it is with distant objects. Thus, distant objects sound more reverberant than do close objects. The formula for determining the intensity of a direct sound is known to be:

I_{direct sound}=QW_{Source}/4πr²

where

I_{direct sound}=the sound intensity (in W m⁻²);

Q=the directivity of the source (compared to a sphere);

W_{Source}=the power of the source (in W); and

r=the distance from the source (in m).

This equation shows that the intensity of the direct sound reduces as the square of the distance from the source, in the same way as a sound in free space. This has important consequences for listening to sound in real spaces. Essentially the distance module 110 is a volume control that is based on the size of a selected virtual room. The distance module is automated and receives its control signals 155 from the host computer 160.

After the signal passes through the distance control module 110, it is received by the delay module 115, which delays the signal from, for example, from one to three hundred milliseconds in one millisecond increments. This delay can be used for many special effects, including using a positional channel as an early reflection. The delay module 115 is automated and receives its control signals 165 from the host computer 160. The delay module 115 simulates reflections based on the reflections in a room, or other space. In general, approximately 1-85 milliseconds is used for early reflections and greater than 85 milliseconds is used for a diffuse field.

After the signal passes through the delay module 115, it is processed by the occlusion and air absorption module 120. The occlusion and air absorption module 120 is used to affect the sound based on object occlusion and air absorption, both of which are described in more detail below.

Object Occlusion relates to the characteristic of sound that occurs when a sound source is behind an occluding object, namely, the direct path sound must diffract (bend) around the occluding object to reach the listener. Low frequencies with wavelengths larger than the size of the occluding object will not be affected much by the occluding object. However, high frequencies with wavelengths smaller than the size of the occluding object will be shadowed by the object, and will be greatly attenuated. Thus, the effect of an occluding object can be simply modeled by a low pass filter whose cutoff frequency depends on the size of the occluding object. Simulating object occlusion is important to achieve realism in film/video soundtracks where sound emitting objects are visibly moving behind occluding objects, such as, for example, a person walking behind a tree or a truck, or on the opposite side of a doorway.

Air absorption relates to the characteristic of sound that occurs when a sound propagates through air, namely, some sound energy is absorbed in the air itself. The amount of energy loss depends on the frequency of the sound and atmospheric conditions. High frequencies are more readily absorbed than low frequencies, such that the high frequencies are reduced with increasing distance. For example, at 100 meters distance, 20 degrees Celsius, and 20% humidity, a 4 kHz tone will be attenuated by about 7.4 dB. However, the attenuation is less than 1 dB for distances less than 10 meters. Similar to occlusion, the effect can be simply modeled by a low pass filter whose cutoff frequency depends on the distance to the source.

Realistic occlusion is implemented, for example, with a finite input response (“FIR”) filter (e.g., equalizer that equalizes treble, base, and other frequencies) that is designed to reflect Sabine coefficients. Sabine coefficients are the mathematical equivalents to absorption and reflection characteristics of materials in a room, such as the walls and the furniture of a room. In general, the occlusion and air absorption module 120 simulates the equalization changes in the source signal when it strikes an object, a wall, or air. Below is a reference example of Sabine coefficients of different materials including air absorption:

| Material | 125 Hz | 250 Hz | 500 Hz | 1 kHz | 2 kHz | 4 kHz |
|---|---|---|---|---|---|---|
| Plaster on lath | 0.14 | 0.10 | 0.06 | 0.05 | 0.04 | 0.03 |
| Carpet on Concrete | 0.02 | 0.06 | 0.14 | 0.37 | 0.60 | 0.65 |
| Floor (wood joist) | 0.15 | 0.11 | 0.10 | 0.07 | 0.06 | 0.07 |
| Painted plaster | 0.01 | 0.01 | 0.02 | 0.02 | 0.02 | 0.02 |
| Walls (1/2 inch plasterboard) | 0.29 | 0.10 | 0.05 | 0.04 | 0.07 | 0.09 |
| Windows (float glass) | 0.35 | 0.25 | 0.18 | 0.12 | 0.07 | 0.04 |
| Wood Paneling | 0.30 | 0.25 | 0.20 | 0.17 | 0.15 | 0.10 |
| Curtains (cotton draped to half area) | 0.07 | 0.31 | 0.49 | 0.81 | 0.66 | 0.54 |
| Air absorption (per m² | — | — | — | — | 0.012 | 0.038 |
| @ 20° and 30% RH) | | | | | | |

When functioning as a normal positional audio channel (direct sound ), the occlusion and air absorption module 120 can be used to create the effect of air absorption interacting with the sound. When the positional audio channel is used as a reflection, occlusion characteristics as well as absorption and reflective effects of different room materials can be added.

The absorption coefficient of a material defines the amount of energy or power, that is removed from a sound when it strikes it. In general, the absorption coefficient of real materials will vary with frequency. The amount of energy, or power removed by a given area of absorbing material will depend on the energy, or power, per unit striking it. Given the intensity level at 1 m, the intensity of the early reflection can be calculated with the following equation:

I_{early reflection}I_{1 m}−20 log₁₀(Path length)

Because the sound intensity is a measure of power per unit area, the intensity of the sound reflected is reduced in proportion to the absorption coefficient. That is:

Intensity_{reflected}=Intensity_{incident}×(1−α)

where

Intensity_{reflected}=the sound intensity reflected after absorption (in W m⁻²)

Intensity_{incident}=the sound intensity before absorption (in W m⁻²)

and α=the absorption coefficient

Because a multiplication of sound levels is equivalent to adding the decibels together, this equation can be expressed directly in terms of the decibels as:

Intensity_{absorbed}=Intensity_{incident}+10 log(1−α)

which can be combined with the following equation to give a means of calculating the intensity of an early reflection from an absorbing surface:

I_{early reflection}=I_{1 m}−20 log₁₀(Path length)+10 log(1−α)

The occlusion and air absorption module 120 is automated and receives its control signals 170 from the host computer 160.

The audio signal is fed from the occlusion and air absorption module 120 into the reflection generator module 125. This module is divided basically into two processing sections. A first 175 module in the signal path creates early reflections. This module can simulate, for example, one to 100 reflections. A second module 180 simulates the diffuse field (reverberation). Both modules 175, 180 combine to give an accurate simulation of a single reflection. The reflection generator 125 receives signal 185 from the computer 160.

By simulating the acoustical interactions that occur in the natural world, spatial room simulation can advantageously achieve superior, realistic re-creations, above and beyond what is possible with merely directionalizing a direct sound. Spatial room simulation combines positional audio with accurate simulations of the following acoustic phenomena: distance cues, Doppler motion effect, air absorption, and object occlusion. The following is a brief discussion on the theory of room simulation and how it is implemented in a virtual acoustic environment.

When an object in a room produces a sound, a sound wave expands outward from the source, reaching walls and other objects where sound energy is both absorbed and reflected.

Technically speaking, all reflected energy is called reverberation. Assuming a direct path exists between the source and the listener, the listener will first hear the direct sound, followed by reflections off nearby surfaces, called early reflections. After a few tenths of a second, the number of reflected waves becomes very large, and the resulting reverberation is characterized by a dense collection of sound waves traveling in all directions, called diffuse reverberation. The time required for the reverberation to decay 60 dB below the initial level is defined as the reverberation time. Generally, reverberation in a small room decays much faster than reverberation in a large room because, in a small room, the sound waves collide with walls much more frequently, and thus are absorbed more quickly, than in a large room.

Reverberation is an important acoustic phenomena. There is at most one direct path from the source to the listener, whereas there may be millions of indirect paths, particularly in a room where a sound can bounce around hundreds of times before being absorbed. Thus, in typical listening situations, most of the energy listeners hear from a sound source is actually reflected energy.

The perception of reverberation depends on the type of reverberation and the type of sound. In a small room with fast decaying reverberation, the reverberation imparts a tonal quality to the sound that is readily identified as a small room signature. In a larger room, the reverberation can create a background ambience that is easily distinguished from the foreground sound, and this is readily identified as a characteristic of large spaces. In this manner, reverberation imparts useful spatial information about the size of the surrounding space.

Reverberation that contains a lot of high frequency energy in the decay is associated with rooms that have hard, reflective walls, which do not readily absorb high frequencies. Similarly, reverberation that is dull sounding is associated with rooms that contain soft materials, such as plush carpets and drapes, which readily absorb high frequencies. In this manner, reverberation imparts useful information about the composition of the surrounding space.

Reverberation is also important for establishing distance cues. In a reverberant space, when the distance between the source and the listener is increased, the level of the direct sound decreases considerably, but the level of reverberation does not decrease much. Thus, the level of direct to reverberant sound can be used as a distance cue, with dry (non-reverberant) sounds perceived as being close, and reverberant sounds perceived as being distant.

Simulating reverberation is essential for establishing the spatial context of an auditory scene. Reverberation advantageously gives information about the size and character of the surrounding space, is necessary for correctly perceiving distances, and adds greatly to the realism of the simulation.

Reverberation is often simulated by considering a simple geometrical model of the simulated space. Based on the positions of the source, listener, and the reflective surfaces (walls, floor, and ceiling), it is relatively easy to calculate the time and direction of all early reflections. Each reflection can then be rendered using: (1) a delay line to delay the sound according to the total travel time along the reflected path, (2) an attenuation or filter to approximate the transmission and reflection losses, and (3) a binaural synthesizer to properly spatialize the reflection.

The early reflection model does not address the late portion of the reverberation, which contains millions of reflections traveling in all directions. Alternative methods must be used to generate the late reverberation (diffuse field). Late reverberation is usually generated using recursive filters (i.e., filters that have feedback elements) such as comb and allpass filters. Other recursive filter topologies have been proposed for rendering reverberation, including allpass feedback loops, feedback delay networks, and waveguide reverberators. The challenge with reverberation algorithm design is to produce a natural sounding reverberation without excessive coloration in the late decay.

A good approach is to render a generic reverberation which provides both a natural pattern of early reflections and a natural late reverberation. The reflection generator module 125 is specifically designed to feed the location processor module 130, or other less specific location processor module, so that the early reflections will be localized near the sound source, whereas the late reverberation is spatially diffuse. A very realistic simulation of a virtual acoustic environment can be created by processing up to eight signal paths each with its own reflection generator module 125 and positioning each of these eight signals (reflections) in virtual space using the location processor modules 130 on each of the channels. Complete spatial control over a moving sound object can be realized with the implementation of panning a source around the virtual room with a positional audio source. The resulting reflection generator module 125 has many properties that make it effective for use in simulating virtual acoustic environments. Some of these properties include: (1) localization of early reflections depends on location of source; (2) early reflections and late reverberation depend on room size; (3) independent control of reverberation time, room size, and damping frequency; (4) natural colorless decay; and (5) spatially diffuse late reverberation. A realistic room simulation requires a multipurpose algorithm, which with the comprehensive amount of parameters in both the early reflection parts; the reverb tail, and the modulation, makes it possible to adjust the reflections and the diffuse field in many different ways.

The character of the reverberation needs to be controlled by several independent parameters. The following are the typically minimum required parameters for the reflection generator module 125.

Reverberation

Decay: (0.01-20 seconds)—the decay time of the reverb. Usually this is associated with the time it takes the reverb tail to decay 60 dB. This is the overall master decay for the four band decay parameters (described below) which are multiples of this base reverb time.

Early Lev: (−100 dB-0 dB)—the output level of the early reflections. When Early Lev is set completely off, the reverb effect will consist entirely of reverb tail.

Rev Lev: (−100 dB-0 dB)—the output level of the reverb tail. When Rev Lev is set completely off, the effect will consist entirely of early reflections.

Mix: (0%-100%)—Wet/Dry mix.

Out Level: (−100 dB-0 dB)—the overall output level of the reverb.

Pre Delay: (0-200 ms)—a delay placed at the input of the algorithm. This sets how long after the dry sound the early reflections will begin.

Rev Delay: (0-200 ms)—a delay to the tail of the reverb. This adds additional time between the early reflections and the onset of the “tail” of the reverb.

Lo Color: This relates to adjusting the spectral balance in the low end frequencies and is generally a simple way of adjusting a complex selection of frequencies.

Early Reflections

Room Shape relates to the choice between different room shapes. Changing the room shape will change the early reflections.

Early Size (e.g., Small, Medium, Large)—changes the size of the early Type parameter.

Early Bal (−100 dB R, Center, −100 dB L)—the left/right balance of the Early Reflections. An offset for the Early Reflections from the normal center position.

Hi Color (±50)—adjusts the spectral balance of the Early Type. The Color parameter is actually an advanced Hi Cut parameter.

Lo Cut (20 Hz-400 Hz)—this adjustable filter removes low frequencies for the Early Reflections.

Reverb (tail)

Rev Type (Smooth, Natural, Alive, Fast St., Fast Wd.)

Diffuse (±50)—this parameter provides more or less diffusion. For optimum performance the diffusion is automatically adjusted behind the scenes whenever decay time is changed. This parameter gives you the added control to vary the diffusion around this automatic setting.

Rev Bal (−100 dB R, center, −100 dB L)—the left/right balance of the Reverb tail; provides the ability to offset the tail from the normal center position.

Hi Cut (1 kHz-20 kHz)—rolls off the top end as it enters the Reverb tail, and is used in conjunction with Hi Soften and Hi Decay to “darken” a room.

Hi Soften (+/−50)—Hi Soften is a special filter used to “soften” the high frequencies of Reverb tail. This is not a simple Hi Cut filter but a complex set of filters working together to remove those frequencies that make a reverb sound “brittle” or harsh sounding. Hi Soften is scaled/linked to the Hi Cut and Hi Decay parameters.

Hi Decay (0.1-2.5)—a multiplier for the frequencies above the Hi Xₒᵥₑᵣ frequency. For example, if the main decay parameter is set to 2.0 seconds and the Hi Decay parameter is set to 1.5, frequencies above the Hi-Xₒᵥₑᵣ will decay for 3.0 sec. Conversely if this parameter is set to 0.5 the Decay time above the Hi Xₒᵥₑᵣ point will be 1 sec.

Hi Xover (1 kHz-20 KHZ)—sets the frequency at which the transition from the mid frequencies to the high frequencies takes place.

Mid Decay (0.01-2.5)—the ratio control multiplier for the mid frequencies. This parameter is normally set to 1.0 as it is the main parameter adjusted by the main decay parameter. This parameter is used as a fine adjustment tool to “tweak” a preset to sound just right without having to adjust the master decay parameter.

Mid Xₒᵥₑᵣ (200 Hz-2 kHz)—sets the frequency at which the transition from the low-mid to the mid frequencies takes place.

Lo mid Decay (0.1-2.5)—the ratio control multiplier for the low-mid frequencies

Lo Xₒᵥₑᵣ (20 Hz-500 Hz)—sets the frequency at which the transition from the low to the low-mid frequencies takes place.

Lo Decay (0.1-2.5)—the ratio control multiplier for the low frequencies.

Lo Damp Freq (20 Hz-200 Hz)—sets the Lo Cut frequency for the next parameter, Lo Damp. These two parameters are used to take away any objectionable low frequencies entering the Reverb tail processor.

Lo Damp (−18 dB-0 dB)—sets the amount of cut in dBs. Used with the Lo Damp Freq parameter.

Reverb Modulation

Type—Adjusts the type of modulation.

Rate (−100, default, +100)—allows the user to offset the speed of the LFO from the default assigned to each Type.

Width (0%-200%)—sets the Width of the modulation.

Space Mod—This group of parameters sets the way the sound moves about the room.

Type (Off, Normal, Fast, Slow, MidFreq, Sync).

Rate (−100, default, +100)—the ability to offset the speed of the LFO from the default assigned to each type.

Width (0%-100%)—sets the width of the modulation.

Depth (−50, default, +50)—the ability to offset the amount of space modulation from the default.

The location processor 130 receives the signal from the reflection generator 125 and is directionalized by using measured HRTFs. The location processor 130 receives control signal 190 from the computer 160. The output of the location processor 130 is a left and right head related pair of signals that are fed into a mixer for routing and mixing with direct audio signals which have also been directionalized. The location processor can be viewed as two components, one as a HRTF, DSP, FIR filter component for convolution and one for free field location/equalization. The function of the location processor has a basis in how humans localize sounds using only two ears. A sound generated in space creates a sound wave that propagates to the ears of the listener. When the sound is to the left of the listener, the sound reaches the left ear before the right ear, and thus the right ear signal is delayed with respect to the left ear signal. In addition, the right ear signal will be attenuated because of “shadowing” by the head. Both ear signals are also subject to a complicated filtering process caused by acoustical interaction with the torso, head, and in particular, the pinna (i.e., the external ear). The various folds in the pinna modify the frequency content of the signals, reinforcing some frequencies and attenuating others in a manner that depends on the direction of the incident sound. Thus an ear acts like a complicated tone control that is direction dependent. People unconsciously use the time delay, amplitude difference, and tonal information at each ear to determine the location of the sound. These indicators are called sound localization “cues”. Sound localization by human listeners has been studied extensively.

The transformation of sound from a point in space to the ear canal can be measured accurately; these measurements are called head-related transfer functions (“HRTF”). The measurements are usually made by inserting miniature microphones into the ear canals of a human subject or a dummy head. A measurement signal is played by a loudspeaker and recorded by the microphones. The recorded signals are then processed by a computer to derive a pair of HRTFs (one for the left and one for the right ears) corresponding to the sound source location. Each HRTF, typically consisting of several hundred numbers, describes the time delay, amplitude, and tonal transformation for the particular sound source location to the left or right ear of the subject. The measurement procedure is repeated for many locations of the sound source relative to the head, resulting in a database of hundreds or even thousands of HRTFs that describe the sound transformation characteristics of a particular head.

Directionalization processing works by mimicking the process of natural hearing, essentially reproducing the sound localization cues at the ears of the listener. This is most easily done by using a pair of measured HRTFs as a specification for a pair of finite impulse response (“FIR”) filters. When an impulse is input to a device such as an FIR filter, the output is the filter's impulse response. The impulse response can completely characterize a system; a filter can be described by its time-domain impulse response or its frequency response. Furthermore, multiplying an input spectrum by a desired filter transfer function in the frequency domain is equivalent to convolving the input time-domain function with the desired filter's impulse response in the time domain. Convolution provides the means for implementing a filter directly from the impulse response because convolving the input signal with the filter impulse response gives the filtered output. When a sound signal is processed by the digital filters and listened to over speakers or headphones, the sound localization cues for each ear are reproduced, and the listener perceives the sound at the location specified by the HRTFs. This process is called binaural synthesis (binaural signals are defined as the signals at the ears of a listener).

Binaural synthesis works extremely well when the listener's own HRTFs are used to synthesize the localization cues. However, measuring HRTFs is a complicated procedure, so other 3D audio systems typically use a single set of HRTFs previously measured from a particular human or dummy head subject. Localization performance generally suffers when a listener listens to directional cues synthesized from HRTFs measured from a different head, called non-individualized HRTFs. Human heads are all different sizes and shapes and, similarly, there is also great variation in the size and shape of individual pinnae. This means that every individual has a different set of directional cues. The greatest differences are in the tonal transformations at high frequencies caused by the pinnae. It is known that we become accustomed to localizing with our own ears, and thus our localization abilities are diminished when listening through another person's ears. Our uniqueness as individuals is generally the source of the greatest limitation of 3D technology.

The signal from the location processor 130 is passed to an output mixer 200 (FIG. 2). The stereo outputs 135 of all directionalized room simulator reflections and the directionalized direct audio channels are fed into a mixer or are directly used. This mixer can be configured many ways. It primarily is configured to input all directionalized direct audio channels and the spatial room simulator channels for mixing to an output. The output mixer 200 contains a source mixer 205, a sub mixer 210, and a reverb mixer 215.

The source mixer 205 receives multiple ouputs from the directionalized direct audio channels. The source mixer 205 has the same amount of outputs as inputs and allows volume level control, equalization and automation for each channel. Its outputs are feed directly to the sub mixer 210. The sub mixer 210 takes the outputs from the source mixer 205 and mixes them together with the outputs from the reverb mixer 215. It is within this module that surround panning between selected outputs is created. Panning laws are implemented within this module. All panning parameters are automated. The outputs can be configured for stereo or in 5.1 or 7.1 surround format.

The reverb mixer 215 receives multiple ouputs from the spatialized room simulator channels (e.g., one or more room simulator modules 100) into this mixer. The source mixer 205 down mixes the multiple inputs to eight pairs of outputs. Each pair of inputs can be assigned to any of the eight pairs of outputs. The reverb mixer 215 implements volume level control, equalization, and automation for each channel. Its eight pairs of outputs are fed directly to the sub mixer 210.

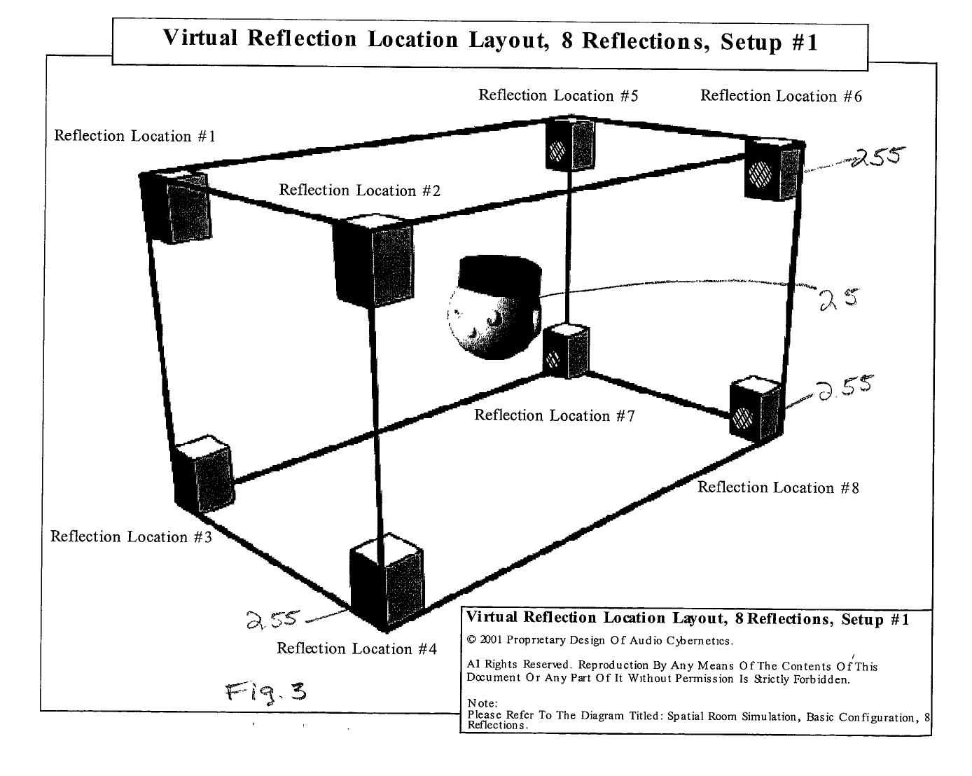

Referring to FIG. 3, as part of this process above, virtual reflections and virtual speakers are used. When assigning a directionalized reverberant stream to a specific location in three-dimensional space, a special type of sound object, called a virtual speaker, is used. FIG. 3 illustrates a virtual reflection layout for eight reflections and includes a virtual listener 250 and eight virtual speakers 255. Virtual speakers are intended to simplify the management of virtual surround processing. Using virtual speakers it is easy to convert a conventional stereo sound into an immersive 3D sound. A virtual speaker can be compared to a stationary sound object; namely, it is fixed in space and assigned a sound. Unlike a stationary sound object, however, a virtual speaker is not subject to environmental effects. Thus, the Doppler effect, air absorption, object occlusion, and reverberation have no effect on a virtual speaker. Only the angle and distance of the virtual speaker with respect to the listener is important; these are used to synthesize the 3D location and amplitude of the virtual speaker.

Instead of environmental effects, virtual speakers implement a variable delay line, gain control. Optional outboard user-defined filters can be used to permit customization of the signal that feeds each virtual speaker. For example, using a bandpass filter, one can easily set up a virtual speaker that reproduces only certain frequency ranges of the input sound thereby simulating a certain type of speaker specification; these virtual speakers can then be positioned anywhere around the listener. This makes it easy to create pseudo-surround mixes from conventional stereo inputs. When a directionalized source sound is used (i.e., no reverb), the term virtual speaker is used. In this application, the primary use of virtual speakers are for environmental (reverberation) effects; therefore when a virtual speaker is used only for an environmental effect it is called a “virtual reflection”. The implementation of the room simulators uses virtual speaker placement in the form of directionalization of reflections and the diffuse field.

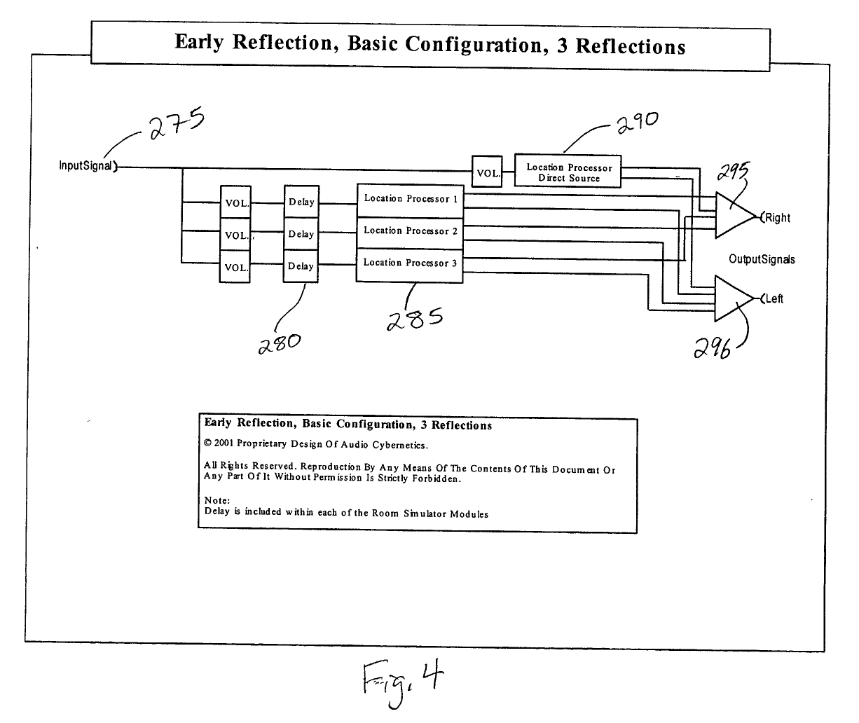

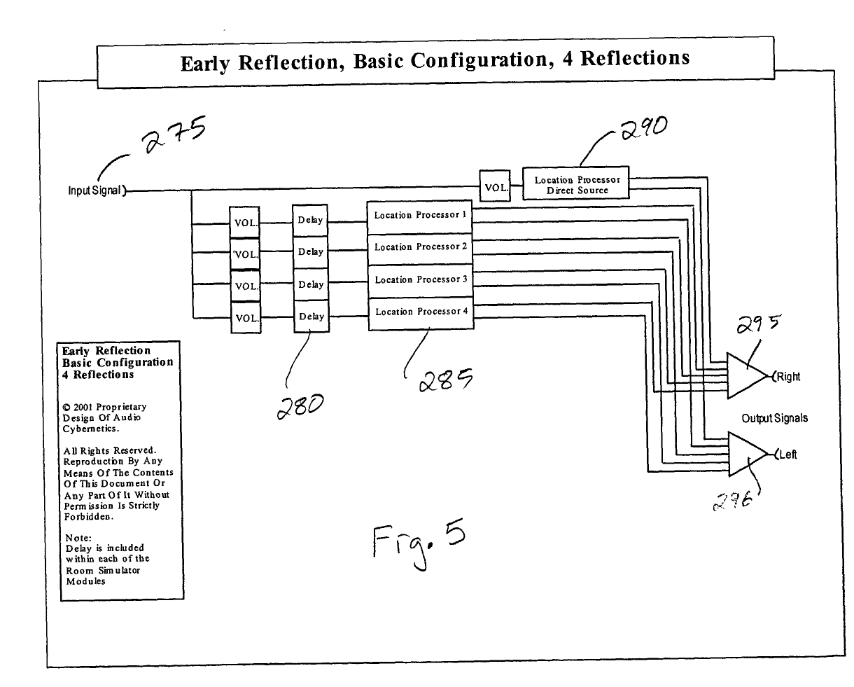

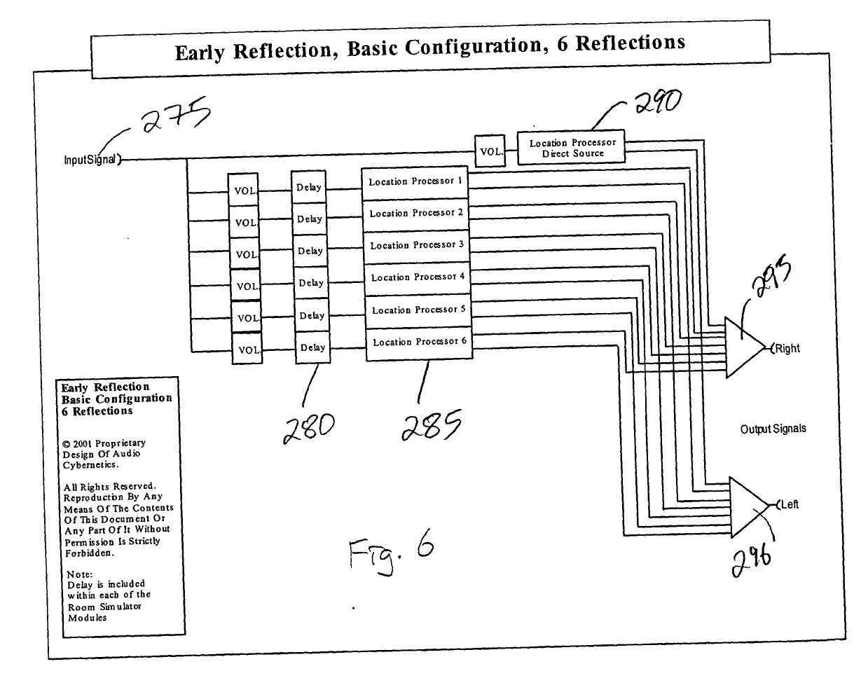

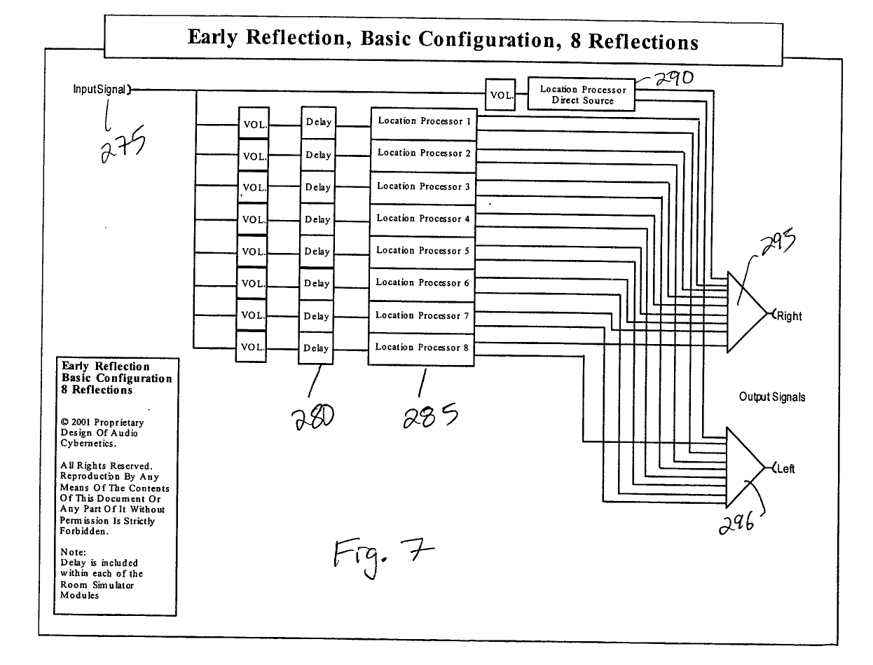

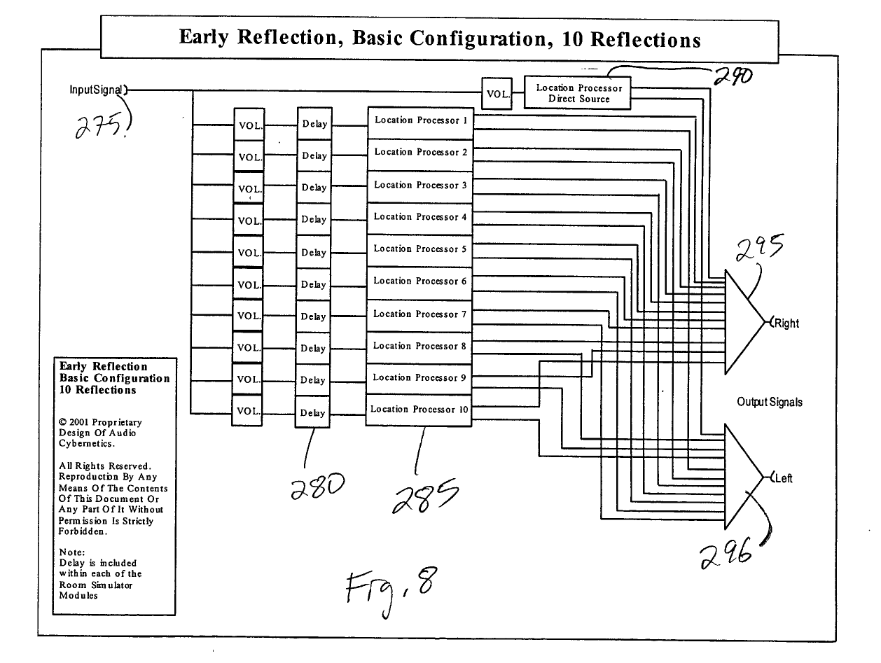

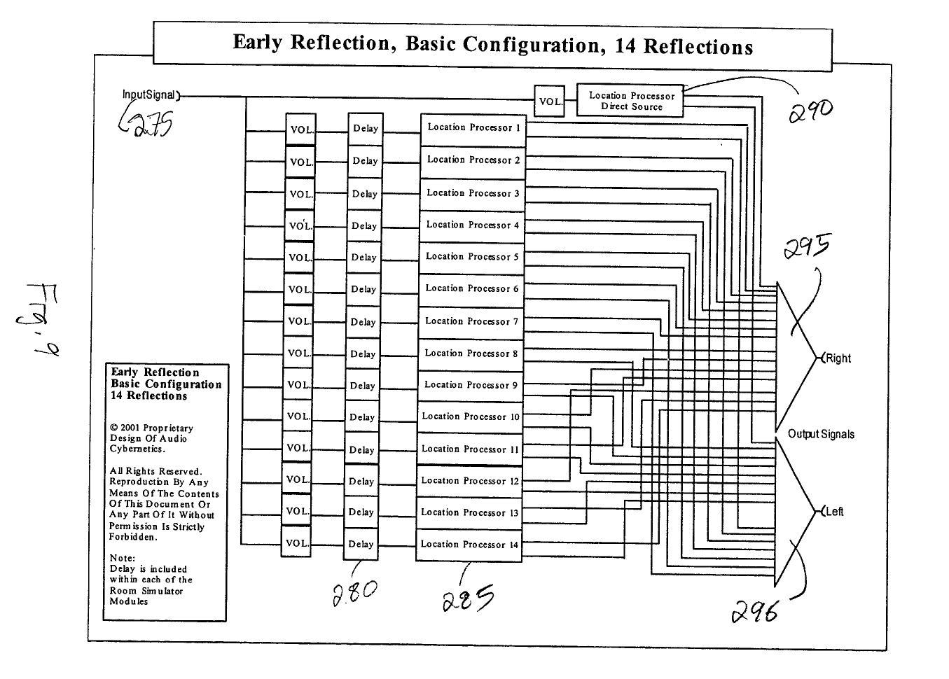

Referring to FIG. 4, the processing for a virtual reflection is illustrated. The input sound or signal 275 can be processed through a user-adjustable variable delay and a user-adjustable filter 280. The filter may be, for example, a bandpass, lowpass, highpass, or notch (bandstop) filter. A directionalizing transfer function 285 is then superimposed on the delayed and filtered signal to position it as a virtual reflection. A minimum of three early reflections are required to create a spatialized three-dimensional room simulation. The output of the spatial effect is then summed with the direct signal(s) of a directionalized source sound 290 through a gain 295, 296 that adjusts the distance between the virtual reflection and the listener according to the current distance model. As illustrated in FIGS. 5-10, the processing of virtual reflections can be implemented using four, six, eight, ten, fourteen, and/or sixteen reflections, respectively.

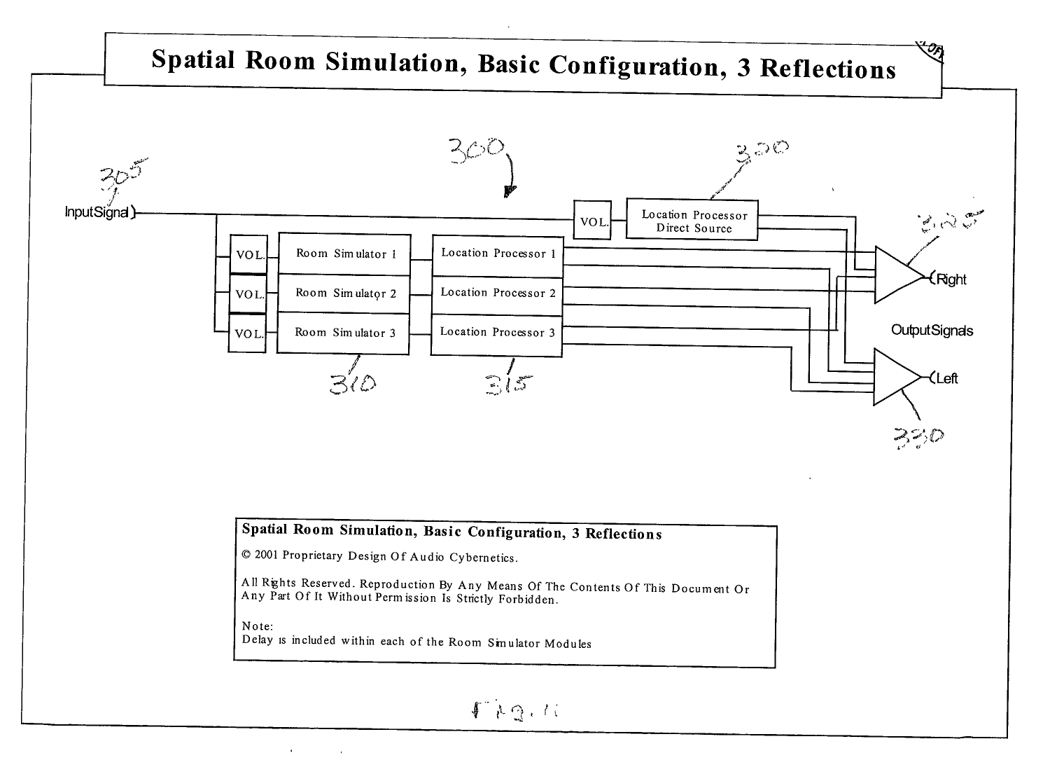

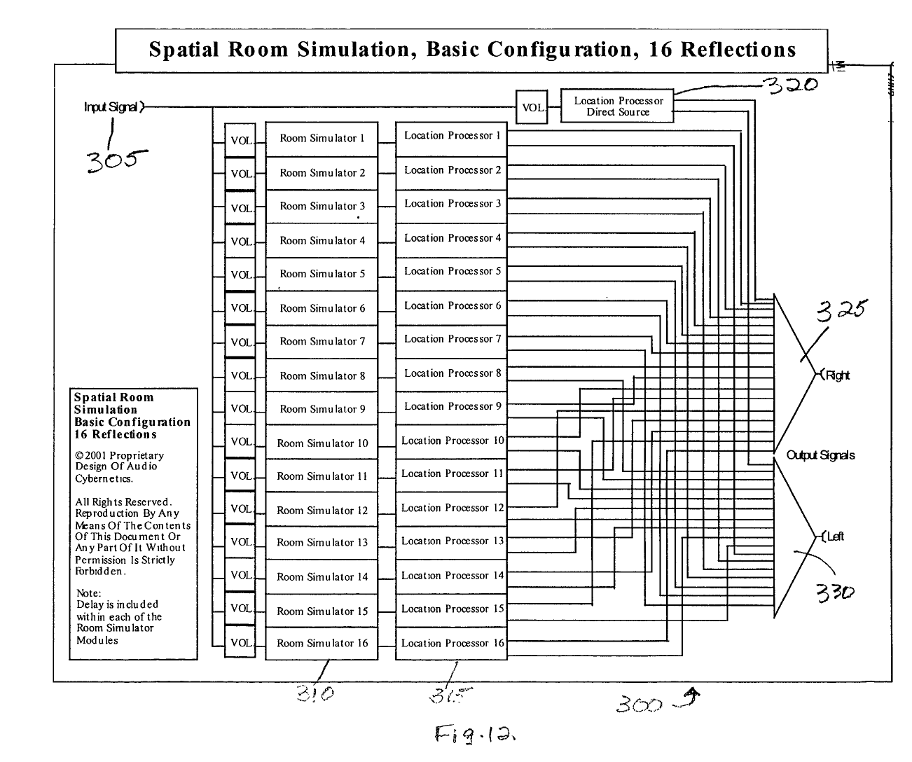

Referring to FIGS. 11 and 12, a spatial room simulation 300 can be configured using, for example, three reflections and/or sixteen reflections, respectively. Similarly to the virtual reflections, other amounts of reflections can be implemented, such as four, six, eight, ten, and/or fourteen reflections. The spatial room simulation 300 includes an input signal 305, a room simulator 310, a location processor 315, and a location processor for a directionalized source sound 320. The outputs are summed through a gain 325, 330 according to the techniques described above.

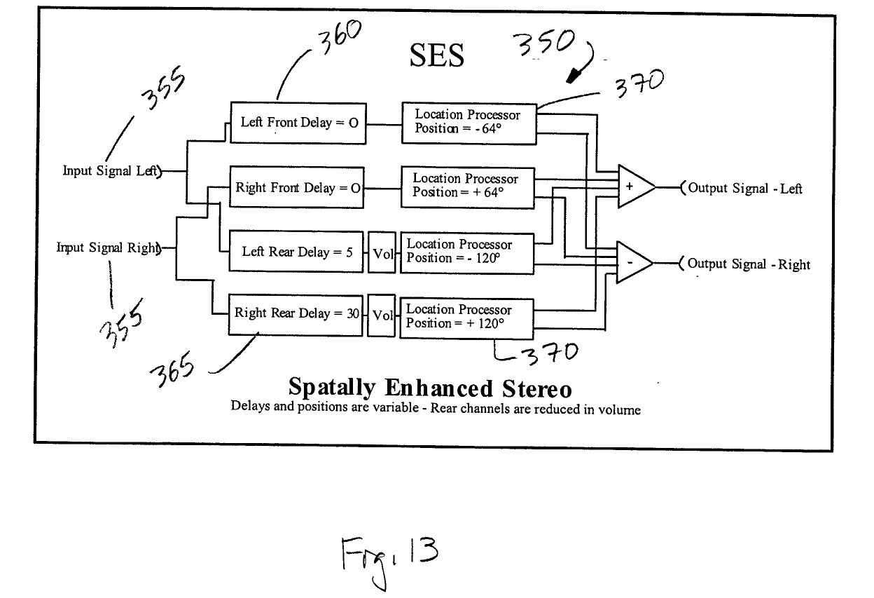

Referring to FIG. 13, the techniques can be implemented as spatially enhanced stereo 350 in a process that includes input signals 355, front delays 360, rear delays 365, and a location processor 370 that is similar to the location processor 190 above. The delays 355, 360 provide delay to the signal, as described above. The location processors 370 apply one or more of the HRTF, FIR filter, DSP, and convolution, as described above.

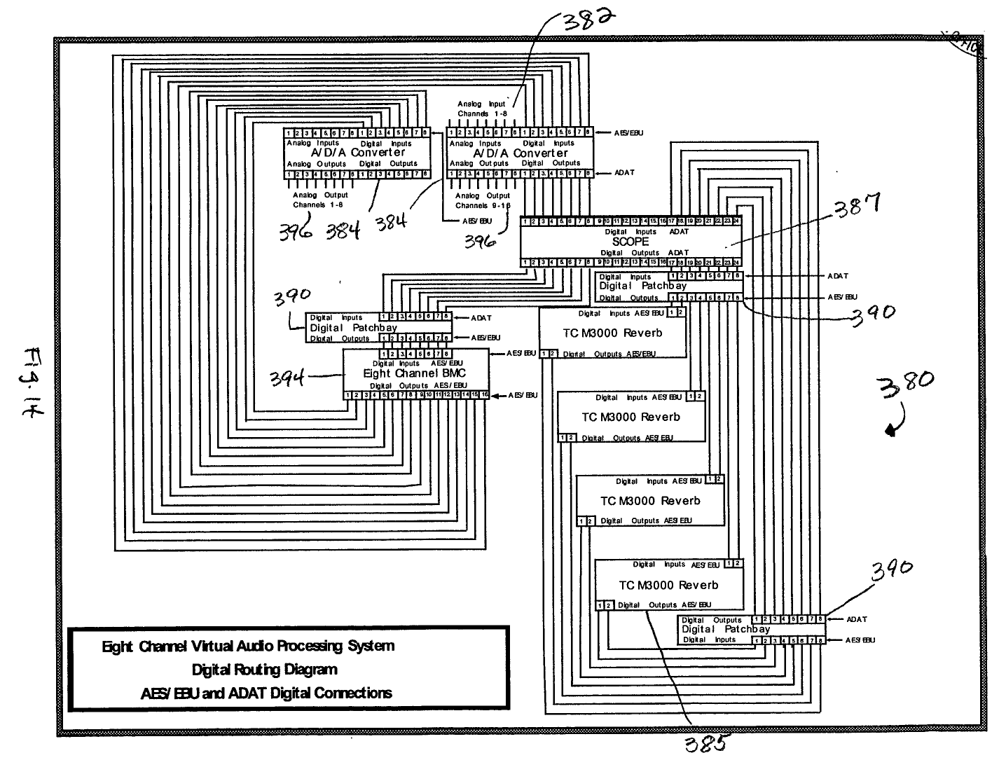

Referring to FIG. 14, the digital routing diagram 380 for an eight channel room simulation, as described above, is illustrated. The diagram 380 includes analog input channels 382, A/D/A converters 384, reverb 385, a scope 387, digital patchbays 390, reverb 392, eight channel BMC 394, and analog outputs 396.

The spatial room simulation utilizing the hardware modules described above can be implemented, for example, in a professional audio/film industry scenario. Normally recorded audio can be processed into a three-dimensional spatial environment and then matched to moving images on a motion picture screen. The spatial process is described below in a step by step format with variations and explanations of each step. In the scenario in which the spatial room simulation is implemented, audio from a three-minute scene in a movie is processed into a three-dimensional spatial environment. The scene consists of two people (male and female) outdoors in the forest talking, then they walk up to a stream, and then walk off the screen right, talking and laughing. There are various background ambiences such as birds, a chipmunk and occasional light wind in the trees. There also is some light chamber music playing in the background, generally consisting of a violin, a cello and flute. The objective that needs to be accomplished is to create a highly realistic spatial audio environment, which matches events taking place on the screen. Some of the audio, such as dialog, will have to track the actors motion on the screen as they move around. Ambient background sound has to completely surround the listener in a 360-degree sound field. The musical instruments need to appear as if they are being played at various locations in the woods.

The first step is to acquire the source audio for the scene. This step consists of the following categories of audio: (1) dialog for the two actors each recorded separately on individual audio tracks; (2) ambient forest sounds, such as different types of birds, one or more chipmunks, and light wind, all on separate audio tracks; (3) a stream; and (4) the music track, which consists of each instrument on a separate audio track (e.g., a violin, a cello and a flute).

The dialog audio source will have been recorded either on location and/or re-recorded in a studio while watching the actual picture. In either case, the audio has to be recorded in sync with the picture using SMTE time code. The ambient sounds, including the stream, can be location recordings or from a sound effects library. The music source will be either original music prepared by the composer or from a music library. The music tracks will be formatted for either a multi-track tape recorder or a digital audio workstation (DAW) along with SMPTE time code.

The recording of the source audio must adhere to the following guidelines below for optimal directionalization and spatialization. Tthe recordings should be as of a high a quality as possible. In the process of converting standard audio signals into a directionalized virtual acoustic environment, the HRTFs function best in response to a broad frequency range. Take bass as an example, even though the general frequency range is in the lower region, there are upper harmonics of the sound, which additionally contribute to the accuracy of the HRTFs to place the bass discreetly as a point source. An effort also should be made to keep a very good signal to noise ratio. One of the benefits of this invention is that all elements of a sound are heard with much more detail. This also includes the artifacts of poorly recorded sound such as noise. The reason for this is that the spatially encoded sounds are in phase. In normal sound recordings, there is a lot of subtle phase cancellation at different frequencies, masking details in the sound. These subtle phase cancellations typically are not present using this technique. The result is that some things that a listener wouldn't hear in a normal recording become very noticeable once it is spatially processed. This includes noise and hiss.

Mono sources are best for discreet placement of a sound. This is contrary to current thinking in the audio production world because mono sound sources are usually much better for discreetly placed sounds when working in 3D-space. Stereo sounds are generally good if used as over all ambience. There are some 3D-space panning methods that can be incorporated to move stereo sounds that work well but mono is generally better. Finally, for optimum control, sounds should have no ambience or reverb mixed into the initial recording. In other words “dry ” recordings are best.

The second step is the session setup. This includes the monitor playback configuration. For accurate processing and mixing, correct speaker monitoring is essential. This can range from a standard two speaker configuration, a standard 5.1 surround configuration set up to ITU specifications or headphones. The choice of speakers is vast but the preferred basic specifications for best results are listed as follows: (1) flat response from 30 Hz out to 18 KHz; (2) free field equalized; and (3) a 40 to 60 degree dispersion pattern. For headphone listening, best results are obtained from a flat response; free field equalized headphone. Many commercial headphones are not flat. The highs and lows are exaggerated for consumer market use.

The current embodiment functions best if not using the center (mono) channel in a 5.1 surround listening environment. The reason for this is as follows. First, an unprocessed sound when panned center, will appear to be in the middle of the listener's head. This can be observed very clearly on headphones. A spatially processed sound is exteriorized outside the listener's head at the proximity determined by (a) the distance at which the HRTF impulse response was measured from the human head and (b) the size of the spatially processed room that is applied. If a spatially processed sound source is rotating around the head in virtual space and is crossfaded into a mono source at the center speaker, the signal will jump into the center of the listener's head. To eliminate this problem, the center speaker is bypassed altogether.

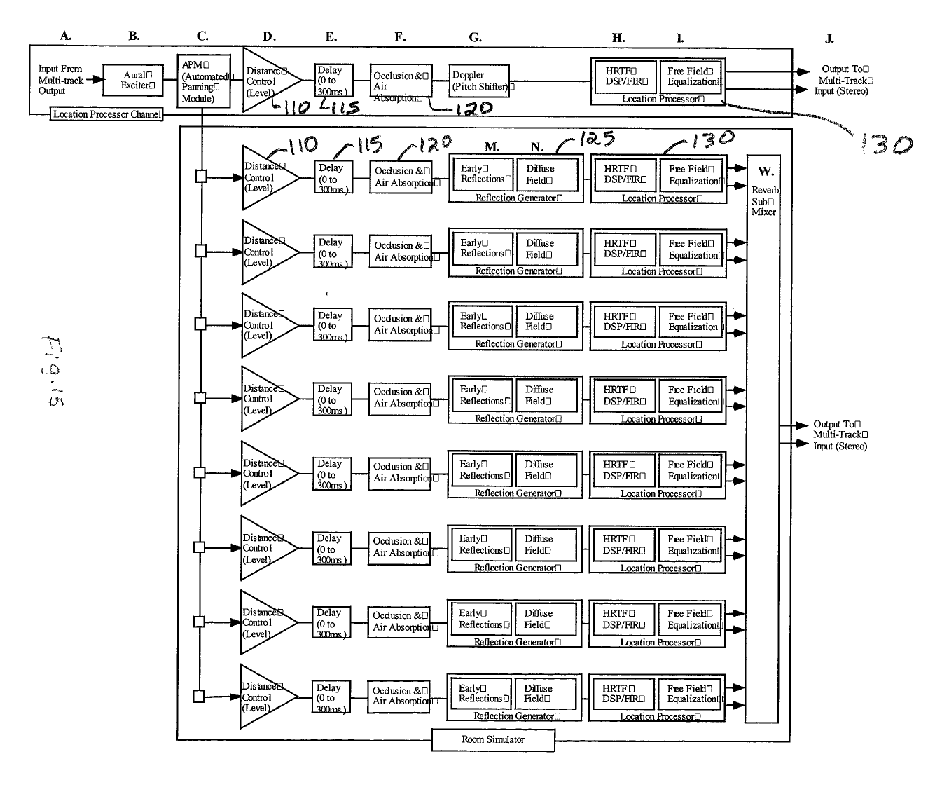

The session setup also includes a multi-track playback and recording system. The audio elements are recorded on individual tracks on a multi-channel recorder which is locked to the picture using SMPTE time code. This assures that all the audio will be synchronized to the various picture elements on screen. The audio elements will already be positioned on a time line that matches the picture as per normal recording procedures. The audio input and output routing for each of the spatial processing modules for each track on the multi-track are shown below in FIG. 15, in which the modules correspond to the modules described above. It is optimum if these connections are digital connections. Note that many audio channels can use the same room simulator but each audio channel must have its own location processor channel. There can be many room simulators, each with a different size room within a mix.

The outputs of each location processor and the outputs of each room simulator are routed back to the multi-track recorder for recording the spatially processed audio. Each location processor channel is mono in and stereo out. The stereo output channels of the location processor are routed to two input channels of the multi-track for recording. The stereo output channels of the room simulator are routed to two input channels of the multi-track for recording. By keeping the room simulation channels separate from the location processor channels allow more control over the final mix.

The third step is the processing of the ambient sounds. The first step in processing the ambient sounds is to create the virtual acoustic environment that the actors will be in. For example, the first step in the processing of the ambient sounds is spatial processing of the sounds created by the birds. As noted above, the sound of the birds is mono. If it is stereo, it is usually best to take the channel that has the best signal to noise ratio (loudest) and use that channel for the source audio. The bird sound is then fed to the input of a location processor channel. The user must make sure that they are monitoring only the stereo outputs of the location processor on the multi-track and not the source, otherwise no spatial effect will be heard.

With respect to the location processor channel, if the sound has been recorded well with a full range frequency response, the aural exciter module can be bypassed and turned off. If the sound has been recorded poorly or the high frequencies are deficient, conservative use of this module will synthesize the missing harmonics. Overuse of this module can result in unnatural brightness or “brittleness” of the sound. Correct use of this module will give the HRTFs more harmonic information resulting in more accurate placement of the sound.

The APM Module is the control used for panning a sound through a virtual room. Using this module, the user can assign from three to eight “sends” to the room simulator. The user can also assign how many room simulation channels (also called virtual speakers) are required to create the most realistic proximity effect for a particular source sound. A minimum of three virtual room reflections are required with a maximum of eight available. For the bird sound, a choice of eight will accomplish all the potential reflection positions that a bird would create/move when it is flying. Eight is also a good choice because the scene is taking place in only one environment. Moreover, by using eight reflections, this room simulator configuration can be used for all the sounds in the scene. If there were multiple environments, such as two different size rooms that the actors would move through, more than one room simulator, each with different parameters corresponding to the different room sizes, would be required. Within each room simulator, the positions of each reflection can be placed anywhere in a 360 degree sound field. FIG. 3 above is a diagram of a typical eight-reflection room simulator shown with one of many reflection placement configurations. This configuration will be the one used in this example. Note that the speakers shown in the diagram are virtual speakers and do not really exist in the real world.

The distance control module controls the proximity (distance) of the sound from the listener's perspective. This control is interactive with the reflections generated by the room simulator. Its distance parameter is dependent on the size room programmed into the room simulator. The distance control function can be controlled by automation locked to time code as well as real-time using a slider. The more volume that the sound is given, the closer the sound appears to the listener. The inverse is also true, namely, the softer the volume, the further away the sound appears. During setup, this control defaults to unity gain.

The delay module is generally used for special effects, such as multiple repeats of a source sound. For this example, this module is set at its default setting of zero milliseconds.

The occlusion and air absorption module is used to adjust for the frequency response of the source sound in any particular room. For instance, if the room simulator was creating a room with dense curtains and carpets, which result in absorption, the source sound would lose high frequency as its proximity moves further away from the listener. The inverse is also true, as a sound comes closer to the listener, the frequency response becomes flat. This parameter is programmed to respond using Sabine coefficients generated from whichever room has been selected and programmed in the room simulator. It is not user accessible, but can be turned on or off. In this example, it is turned on.

The Doppler module simulates Doppler, the effect of a sound raising in pitch as it approaches the listener and dropping in pitch as it moves away. This provides a realistic effect for race cars, trains, motorcycles and airplanes as they pass by the listener. Doppler intensity (i.e., degree of pitch shift) is dependent on the speed at which the sound is moving and its distance relative to the listener. This module is interactive with the location processor module's direction panner and the room simulator parameters. The Doppler module's algorithm is based on actual physics. This module is not user accessible except for an on/off switch and an intensity control (i.e., degree of pitch shift) that over-rides and modifies the actual physics model. For the bird in this scenario, this module should be turned off.

The location processor module contains the head model (HRTF) that creates the actual spatialization of the source sound. The user controls for this module include input volume and a x, y panning. The panner can be operated in real time with a track ball, which incorporates three selectable buttons. The buttons select control of the horizontal (x), vertical (y) axis as well as the volume of the sound. The location processor panner can be synchronized using SMPTE time code. The location processor also sends its x/y coordinates to control the APM module which duplicates the location processor's panning motion path within the room simulator. The output of the location processor is two channels which represent the left and right ear. These are returned to the multi-track inputs for recording. An alternate output method would be to use a mixer whose output is the finale mix. This could be a stereo, 5.1, 7.1 or any multi-channel playback format.

The Room Simulator consists of eight room simulation channels. When the Reflection Generator is not used, these eight channels become the equivalent of eight early reflections. When the Reflection Generator is used, these channels become sound sources whose function is to feed the Reflection Generator.

The APM Module is the control used for panning a sound through a virtual room. It is accessed on a Location Processor channel. Using this module, the user can assign from three to eight “sends” to the room simulator. The user can also assign how many room simulation channels (also called virtual speakers) that are required to create the most realistic proximity effect for a particular source sound. Minimums of three virtual room reflections are required with a maximum of eight available. For the bird sound, a choice of eight will accomplish all the potential reflection positions that a bird would create/move when it is flying. Eight is also a good choice because the scene is taking place in only one environment. By using eight reflections, this room simulator configuration can be used for all the sounds in the example scene.

The distance control module works slightly differently than the distance control module on a location processor channel. This module acts as a level control of a room simulation channel. This is useful in controlling the strength/balance of each of the room simulation channels (reflections). The distance control function can be controlled by automation locked to time code as well as real-time using a slider. Automation of these room simulation channels can give a very realistic effect of how the reflections interact as a sound moves to various locations in the room. During setup, level control defaults to unity gain.

When the Reflection Generator is not used, the delay module controls the time that the early reflection arrives at the listener. When the Reflection Generator is used, this module can be used to create special effects like subtle changes in the size of the room without having to re-program the Reflection Generators. All eight delays can be separately automated, grouped and synchronized to SMPTE time code. For this example, this module is set at its default setting of zero milliseconds.

The occlusion and air absorption module is used to adjust for the frequency response of the reflection in any particular room. For instance, if the room simulator was creating a room with dense curtains and carpets (i.e., high absorption surfaces) each reflection would lose high frequencies. This parameter is programmed to respond using Sabine coefficients generated from whichever room has been selected and programmed in the Reflection Generator. It is not user accessible, although each module within a room simulation channel can be turned on or off and can be automated. In this example, it is turned on.

The Reflection Generator creates digital reverb that is accomplished by digital signal processing (“DSP”) algorithms (traditionally, networks of all pass filters and comb filters) that roughly mimic the results of the acoustic reverberation process. The module is a mono in, mono out processor that generates multiple reflections (up to 64) and a diffuse field (reverb). It is fully programmable and can be automated. The Reflection Generator creates much more subtleties, density and detail in the early reflections and the diffuse field than the eight room simulation channels. The Reflection Generator is useful when creating complex room models. For more simple and discreet effects at close proximity, the eight location channels used alone as early reflections work very well. For this example, a room that simulates the outdoors is selected. Each of the eight reflection generators are programmed slightly different to simulate the non-symmetrical aspect of a wooded outdoor environment.

The location processor module contains the head model (i.e., HRTFs) that create the actual spatialization of the refection channel. The user controls of this module include input volume and a x,y panning. The panner can be operated in real time with a track ball, which incorporates three selectable buttons. The buttons select control of the horizontal (x) and vertical (y) axis as well as the volume of the sound. Generally, once the positions are selected for the reflections, they do not move. There are special situations were the reflection positions may need to move. In those special occasions, the Location Processor panner can be synchronized using SMPTE time code. The output of the Location Processor is two channels which represent the left and right ear. These are returned to the multi-track inputs for recording. An alternate output method would be to a mixer whose output is the finale mix. This could be a stereo, 5.1, 7.1 or any multi-channel playback format.

There are up to ten different bird sounds in this example. Eight of them are placed randomly up in the trees. This is accomplished by using eight location channels and statically (non-moving) placing them in the trees at various horizontal and vertical coordinates as follows:

Bird #1—H 10×V +45

Bird #2—H 62×V +62

Bird #3—H 102×V +70

Bird #4—H 130×V +60

Bird #5—H 184×V +82

Bird #6—H 232×V +38

Bird #7—H 268×V +48

Bird #8—H 356×V +88

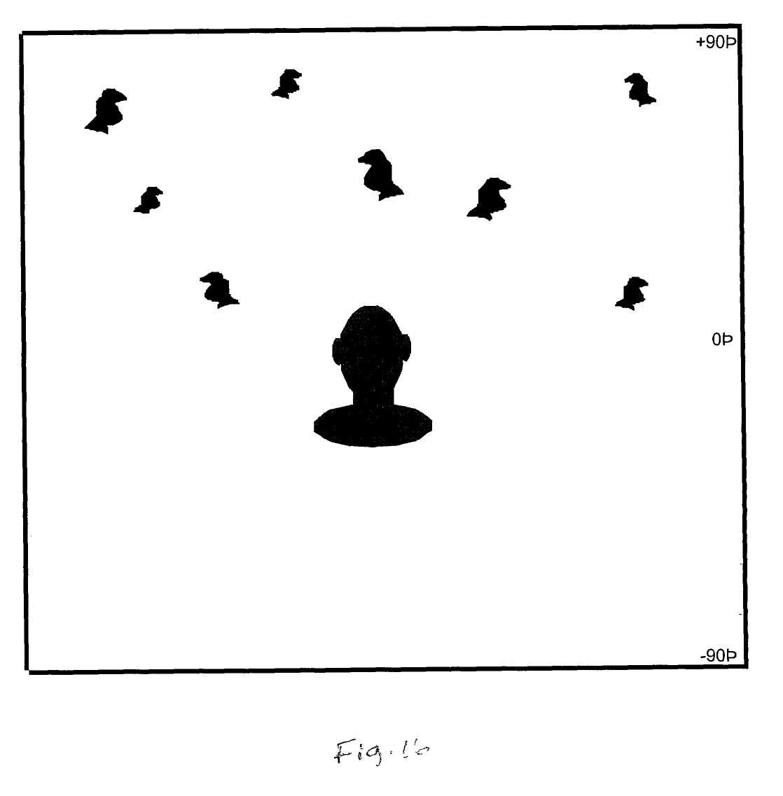

By adjusting the Distance Control Module levels, various distances from the listener (z axis) to each bird can be created. Since there is no visual on-screen display of the birds, the operator can be creative in their placement around the listener, as illustrated in FIG. 16. The remaining two birds will fly around the listener. Bird #9 will fly by and Bird #10 will circle above the listener's head. The motion will be accomplished by moving the location channel of each bird while recording the motions with automation. To increase realism, the motion paths of each bird need to vary slightly on the x axis, y axis and z axis planes.

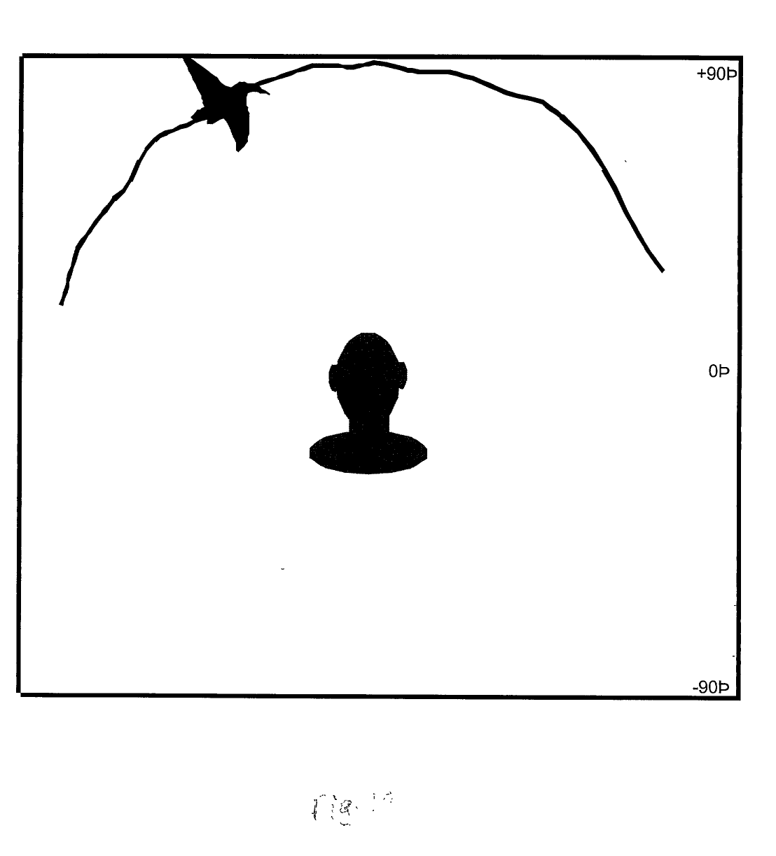

Bird #9 will fly from 280 left to 40 right, as illustrated in FIG. 17. To make the path realistic, it must follow the curve of the earth. While traveling from left to right, the bird's path is moved in an arc that varies slightly on the vertical path shown in the figure. The horizontal plane is varied as well. The motion path should not be a perfect arc. Since there is no bird shown onscreen, the height of the flying bird must be high enough and wide enough so that it is above the top of and beyond the edges of the movie screen. The listener hears the bird but does not see it. Changing or varying the volume at the Distance Control module will make the bird appear closer or further away from the listener.

If the user would like the bird to appear to be very high above the listener's head, they must reduce the Distance Control parameter. If the user wants the bird to fly close to the listener but then fly off into the distance to the right, the user must increase the Distance Control parameter as the bird flies overhead and then reduce the Distance Control as the bird moves to the far right.

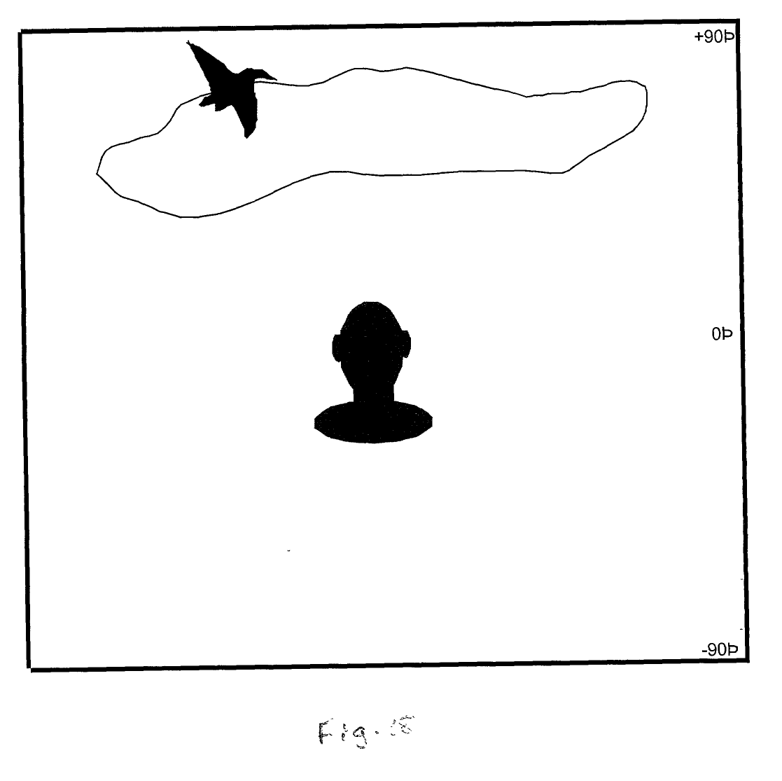

Bird #10 will fly in a circle over the listener's head, as illustrated in FIG. 18. To make the path realistic, the motion path must vary from a perfect circle. For example, while rotating above the listener's head, the bird's path is moved slightly on the x axis, y axis and z axis planes shown in FIG. 18. The motion path should not be a perfect circle. The speed of the rotation must be varied as well. Changing or varying the volume at the Distance Control module will make the bird appear to be closer or further away from the listener. Since there is no bird shown onscreen, the height of the circling bird must be high enough so that it is above the top of the movie screen such that the listener only hears the bird but does not see it.

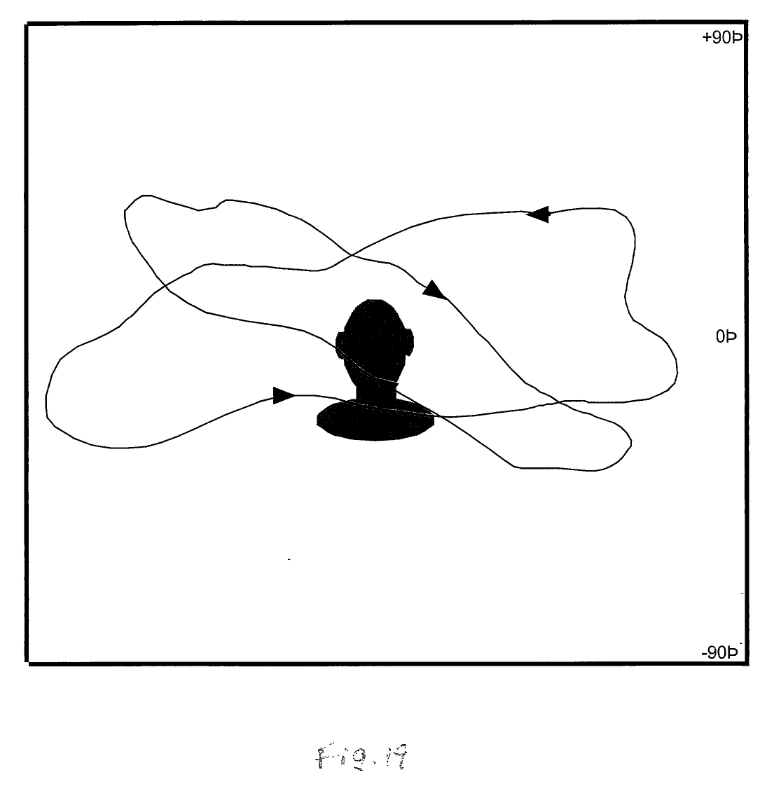

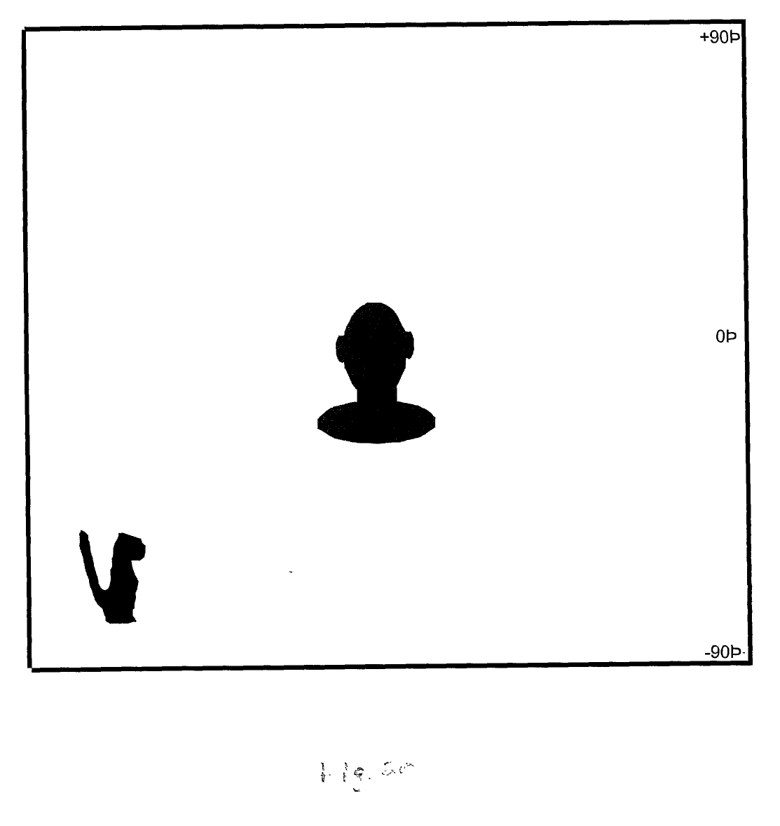

The next effect to process is the wind, as illustrated in FIG. 19. This could be a stereo sound or two mono sounds. Each channel should move in a random type fashion in a circle around the listener. If the sound is stereo, the user moves each channel as if they were separate independent channels. The sound source is a soft breeze so the motion speed should be rather slow. A faster speed would be good for a storm. The volume of the source audio should randomly get louder and softer. Most wind sound sources have the volume dynamic built in so changing the volume will most likely be unnecessary. If the two sound sources play at the same time, the paths should move at the same time at different speeds in completely different motion paths around the listener as shown in FIG. 20. Changing or varying the volume at the Distance Control module will make the wind sound closer or further away from the listener. For optimum realism, the Distance Control module setting should be louder (i.e., closer) when the sound source is louder and when the inverse, the Distance Control module setting should be softer (i.e., further) when the source sound is softer. This, in effect, mimics the presence of the wind and creates the proximity effects of real wind in the environment.

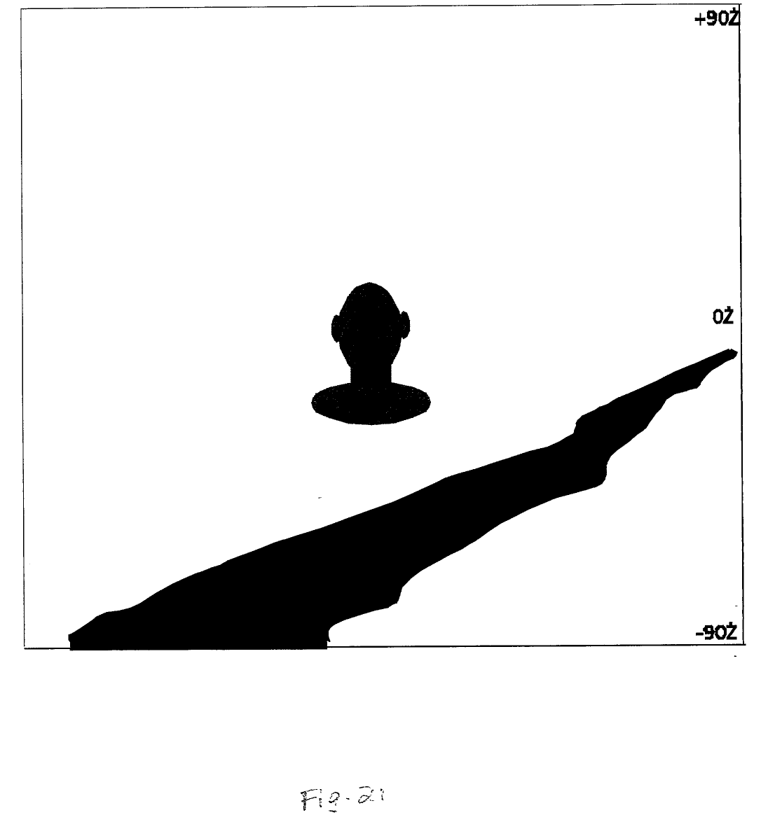

The next sound to be processed is the chirping of a chipmunk, as illustrated in FIG. 21. For this example, the chipmunk is placed behind, below and to the left rear of the listener. Approximate coordinates for the chipmunk are—H 194×V −72 . The Distance Control module parameter is used to place the chipmunk approximately ten feet away from the listener. Although the chipmunk does not move in this example, there is no technological reason why the chipmunk cannot be moved around the listener's feet in, for example, a circle. The technique would be similar to that applied to the bird #10, above. The difference would be that the vertical coordinates would be negative numbers (below) instead of positive numbers (above).

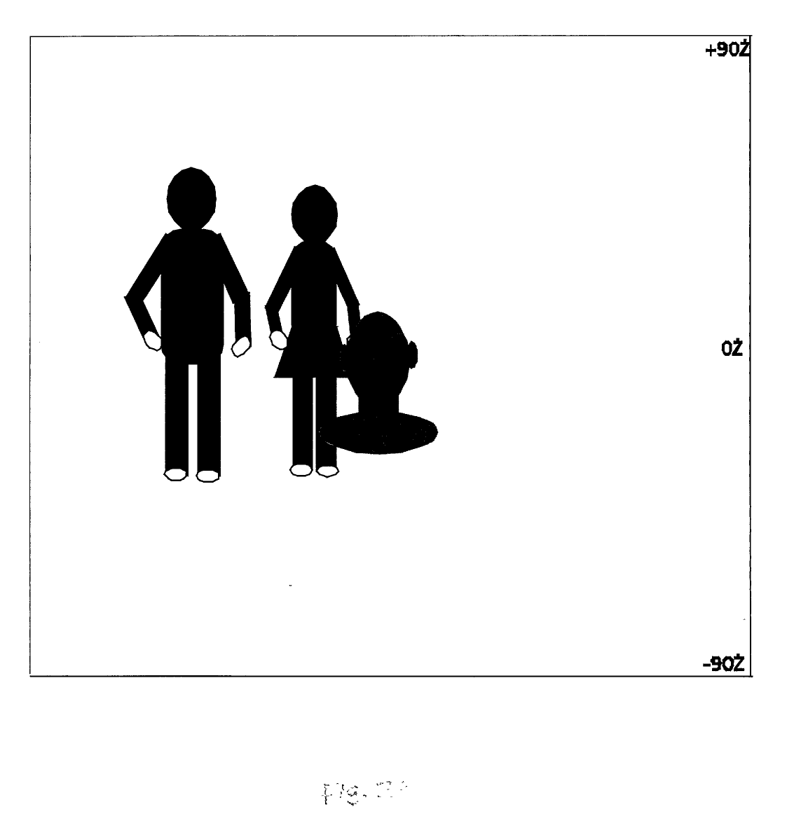

Referring to FIG. 22, there are interesting techniques for creating the stream. One way would be to take a mono source of the water and move it from right to left, below the listener. This technique is not very realistic since it simulates just a point source and does not cover the continuous length of the water moving from left to right. It is possible to take many different mono sources of water and move them sequentially from right to left, which mimics the flow of the water. In addition, the user can mix in a couple of sources that remain stationary, which provides a good effect. In this example, the water source is stereo, recorded originally so that the water is moving from the left to the right in front of the listener. The left channel is directionalized at the coordinates: Stream Left—H 185×V −85. Using the Distance Control module parameter to raise the level (close), the water is made to sound very close behind, below and to the left rear of the listener at an apparent distance of about five feet. The right channel of the source is placed at these coordinates: Stream Right—H 65×V −65 . Using the Distance Control module parameter to lower the level (distance), the water is made to sound in front, below and to the right of the listener at an apparent distance of about 30 feet distance. The effect is that the stream is close behind the listener to the left and the water flows to the right and slightly in front of the listener. This approach is a very simple solution that works quite well.

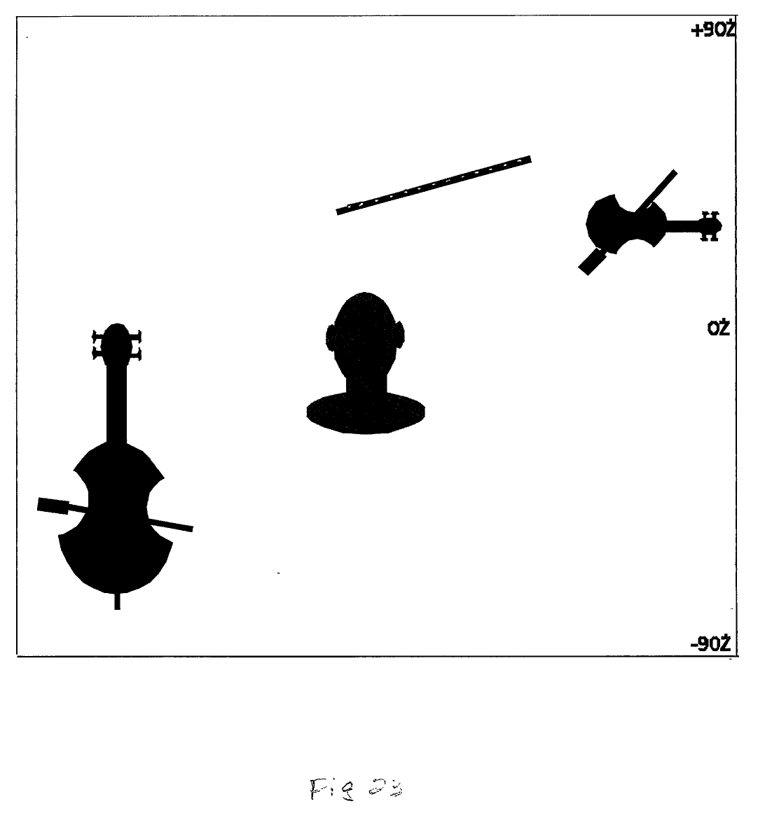

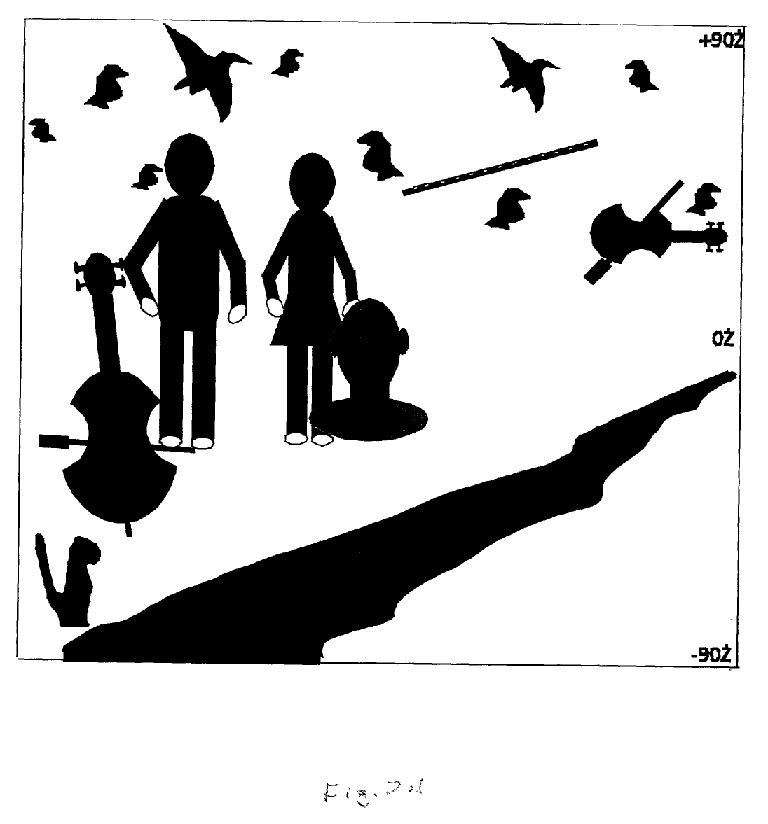

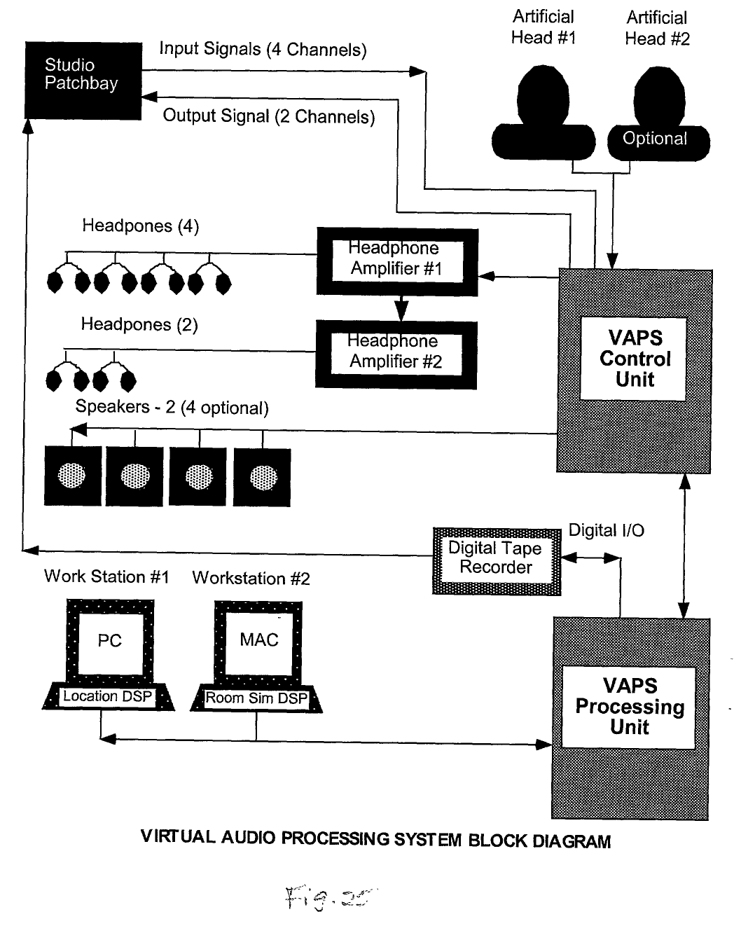

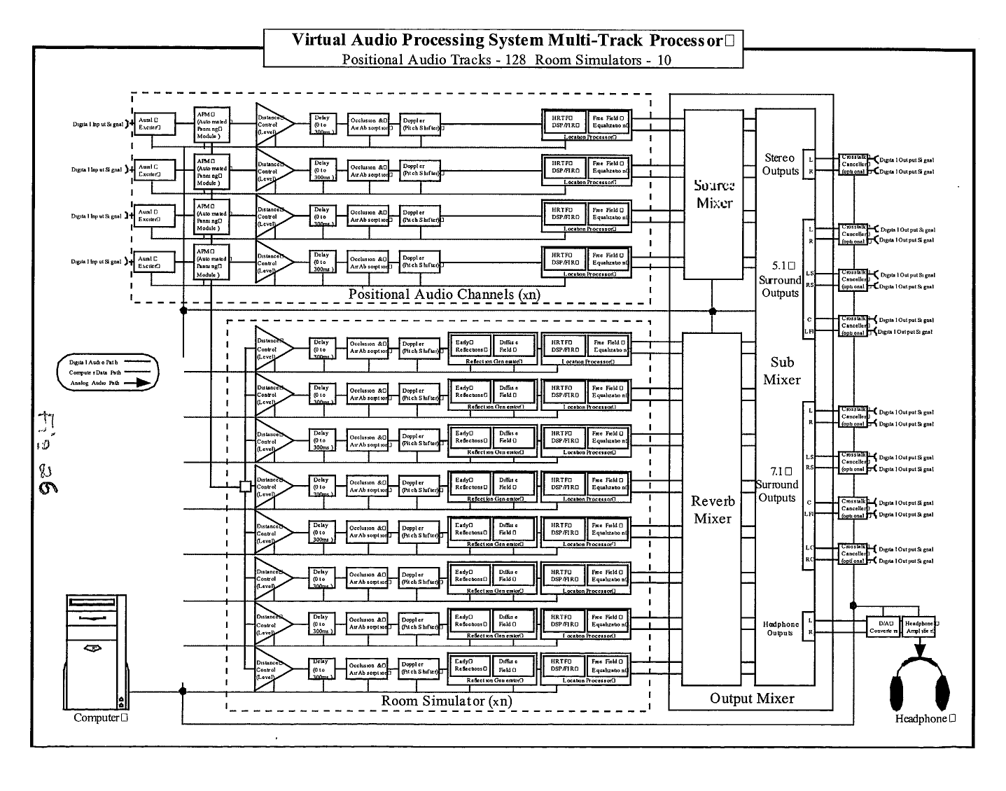

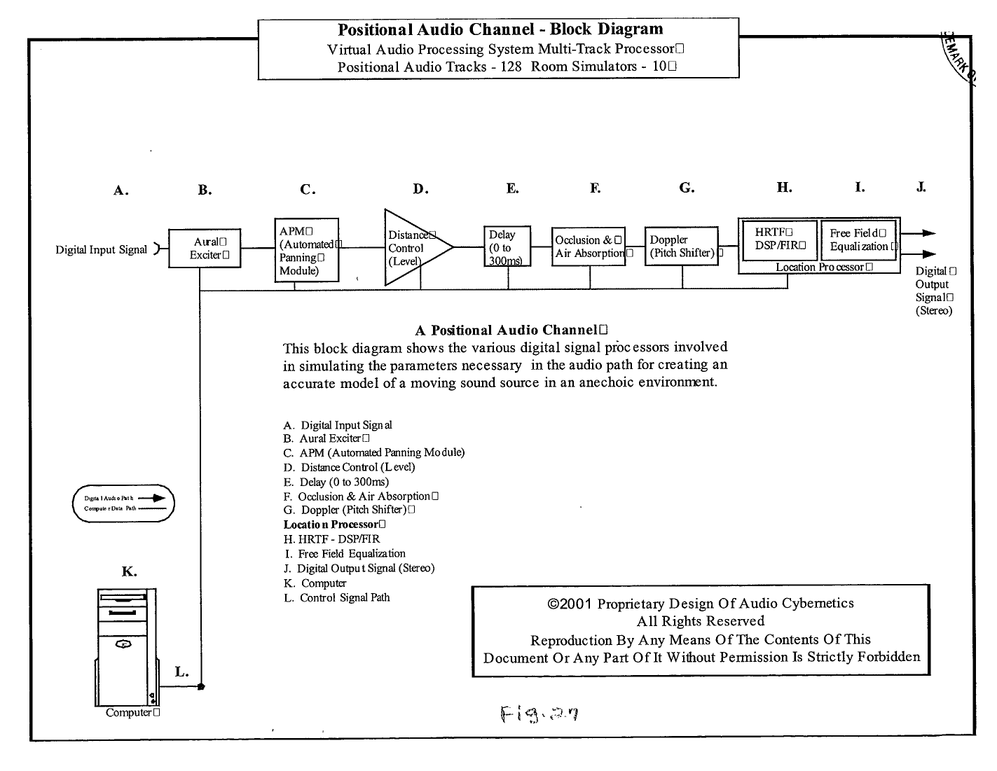

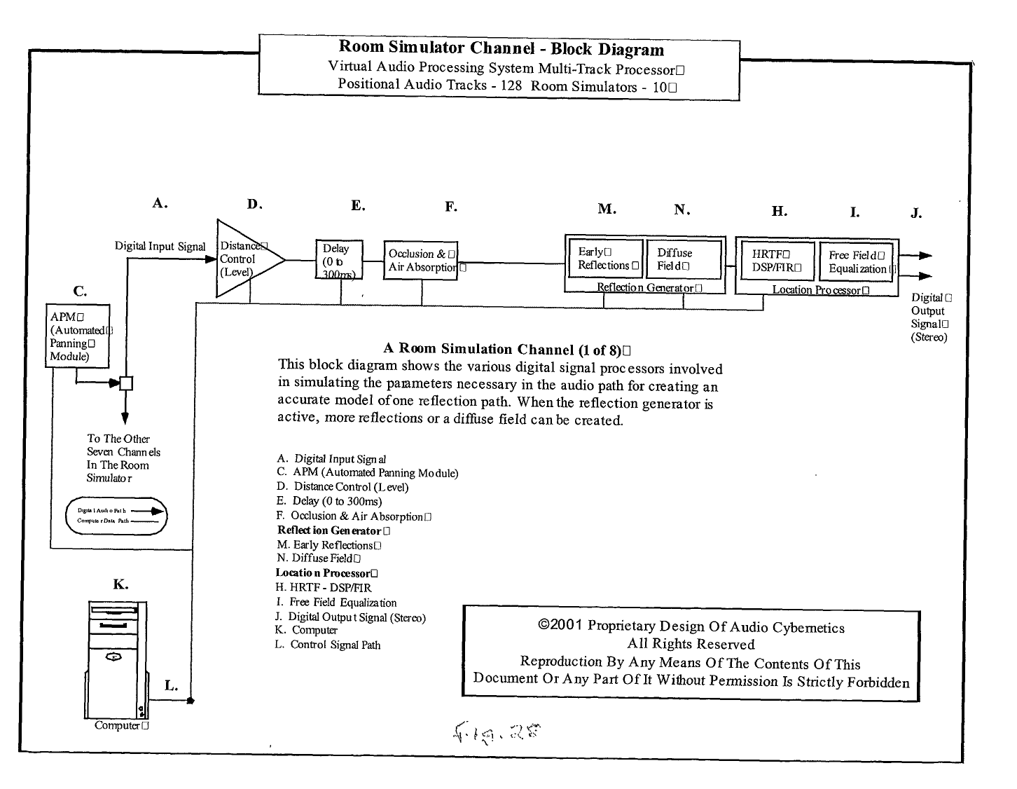

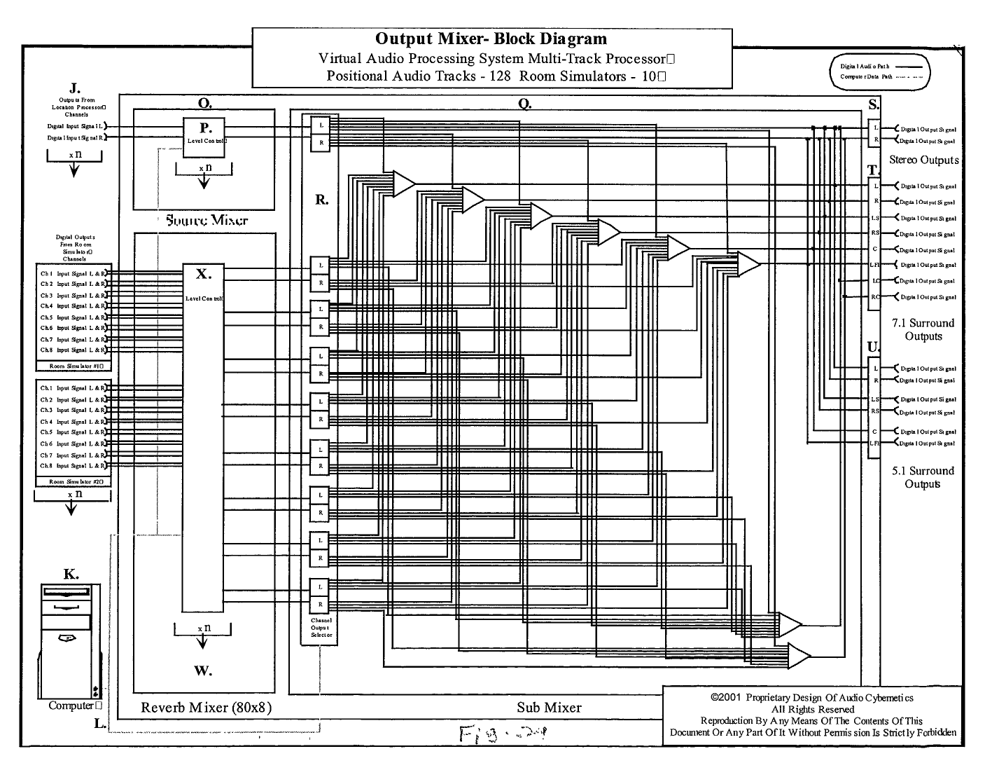

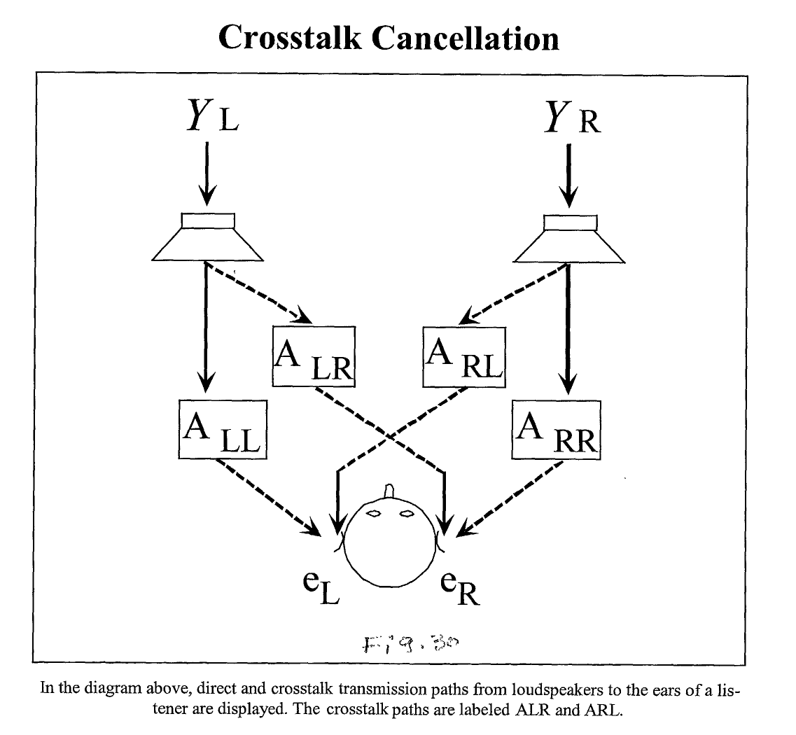

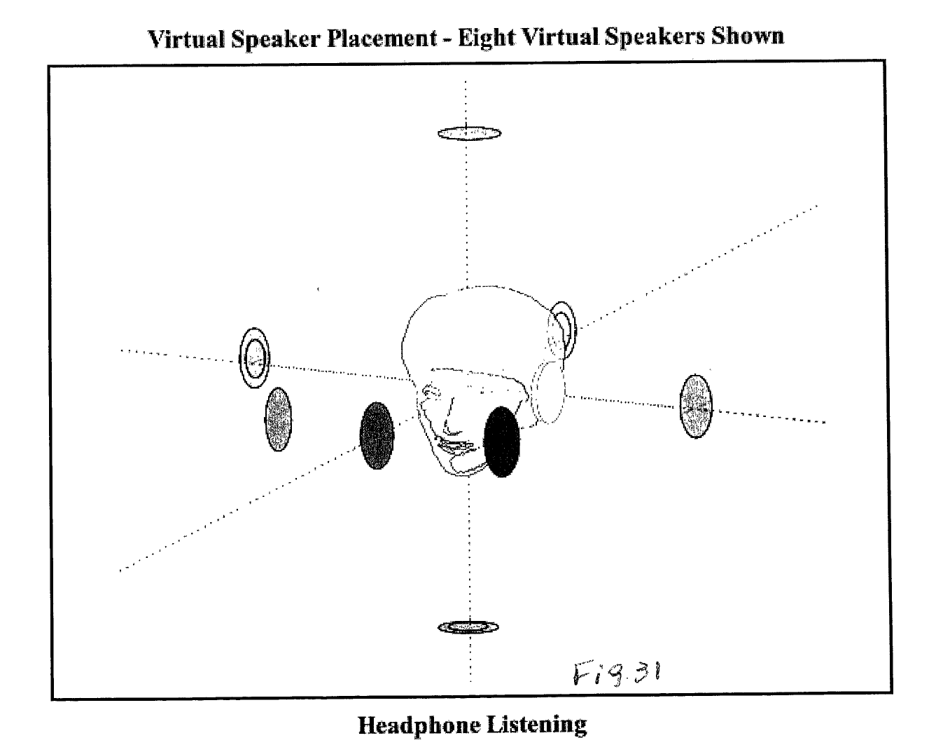

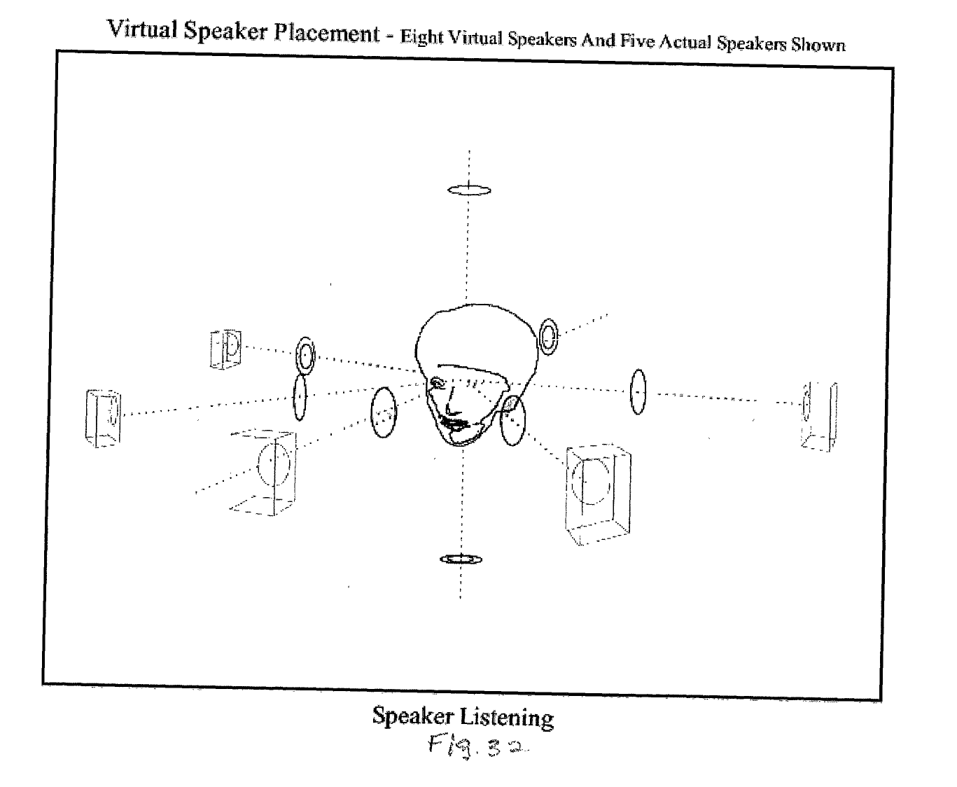

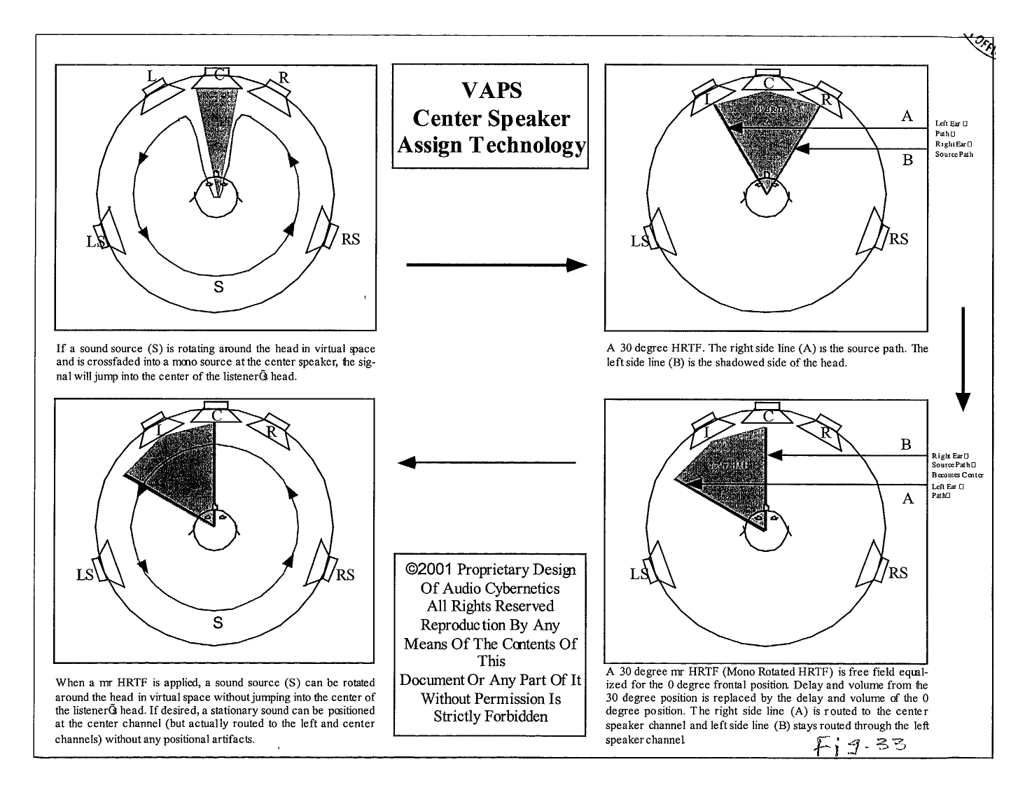

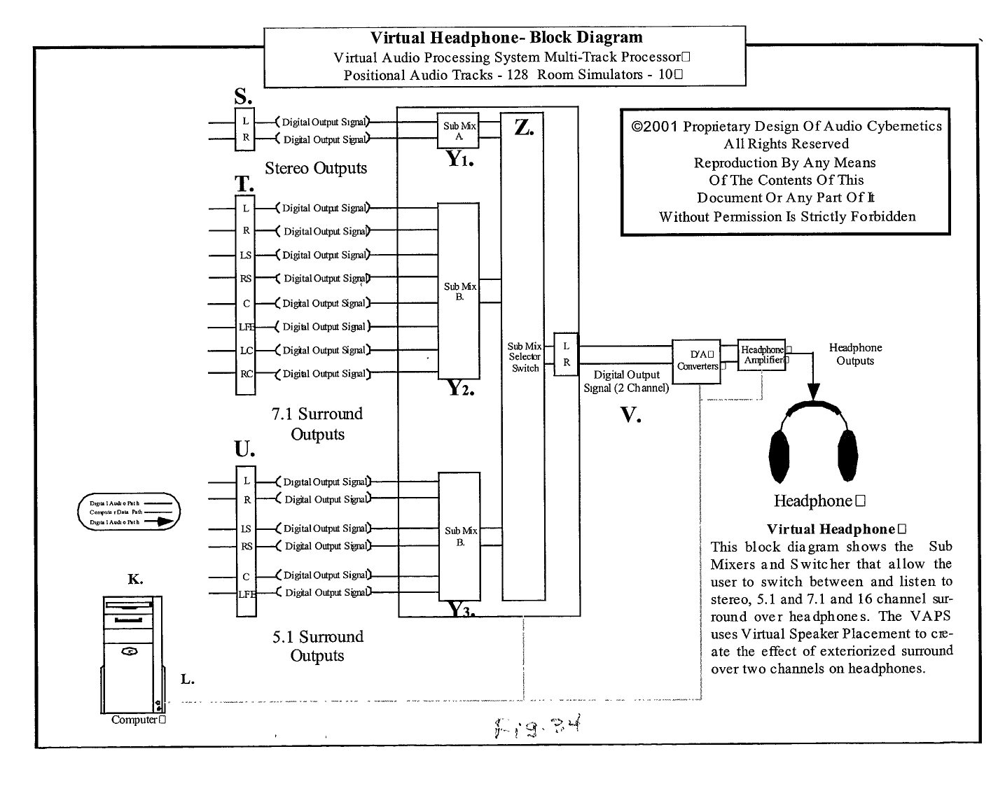

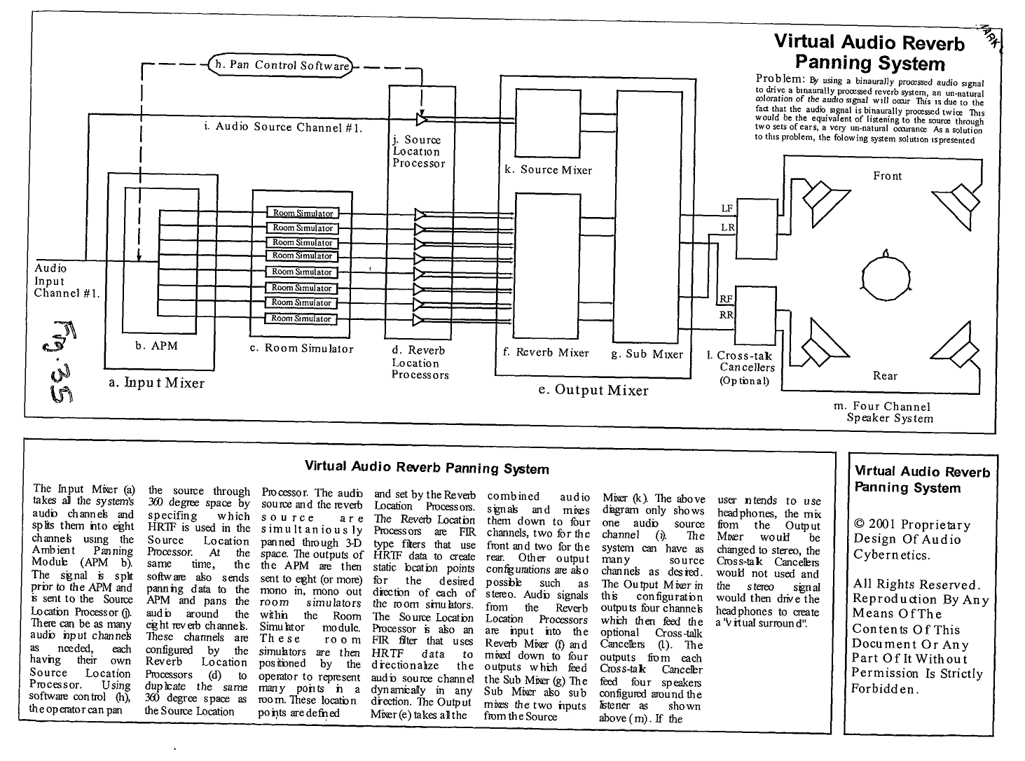

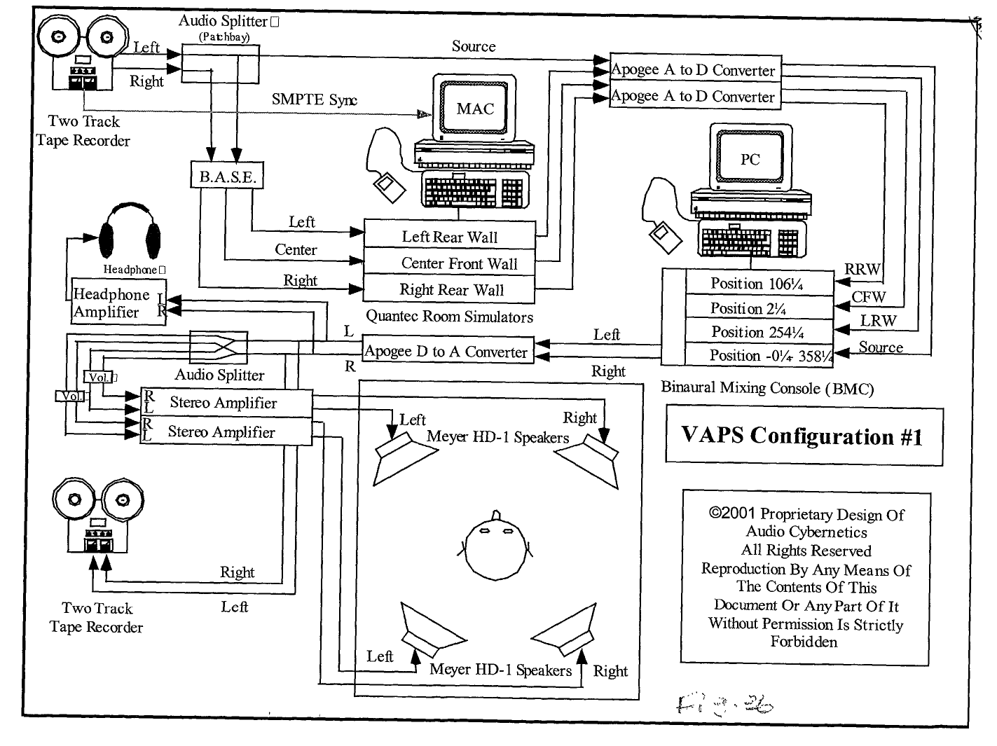

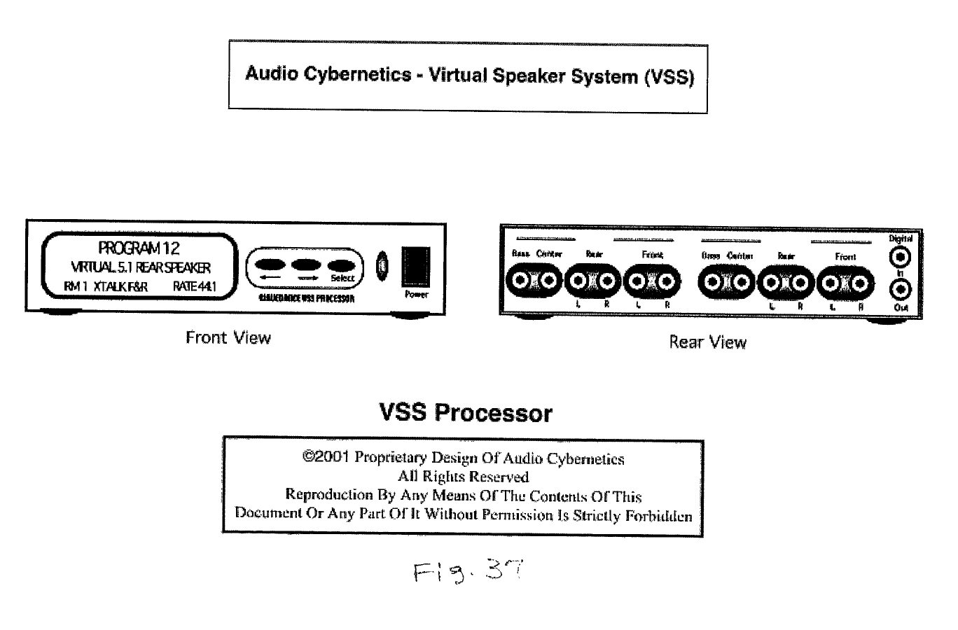

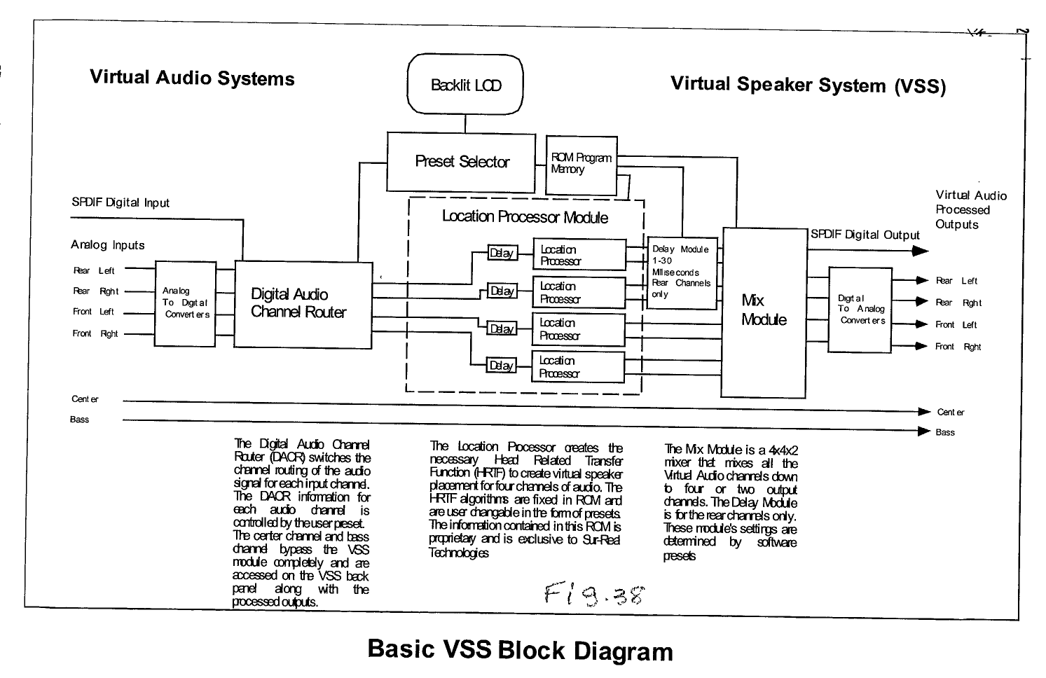

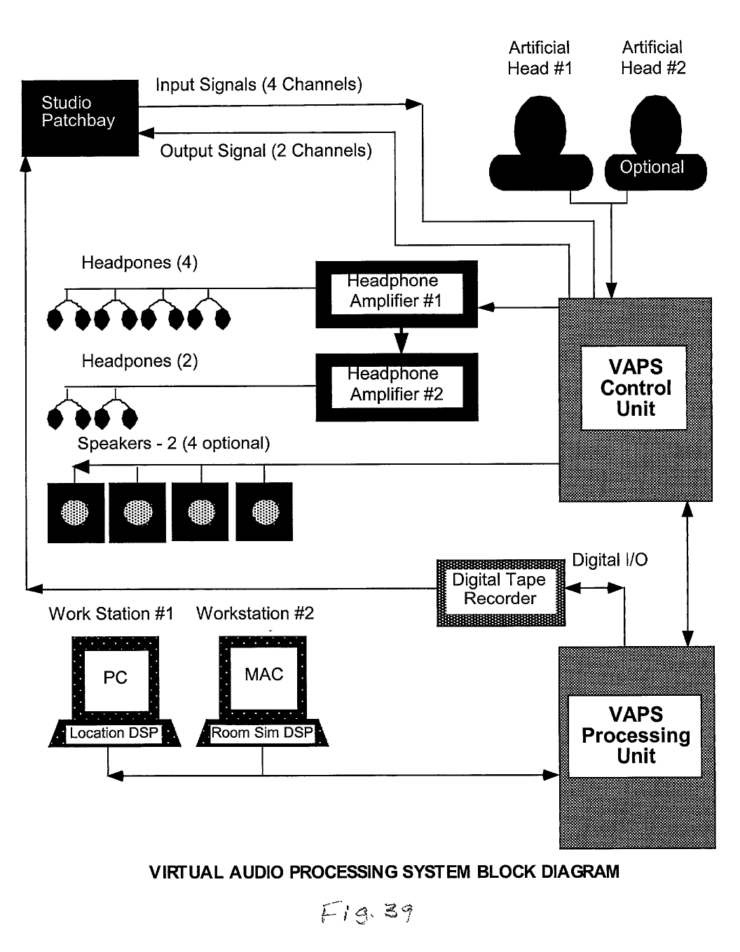

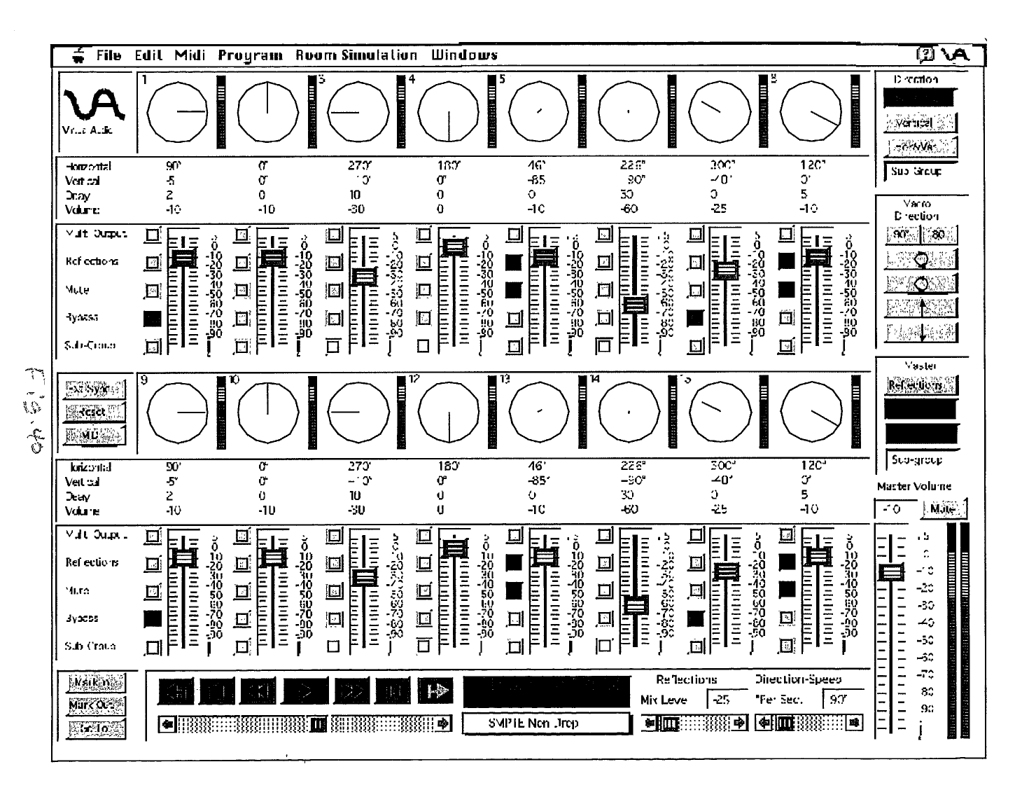

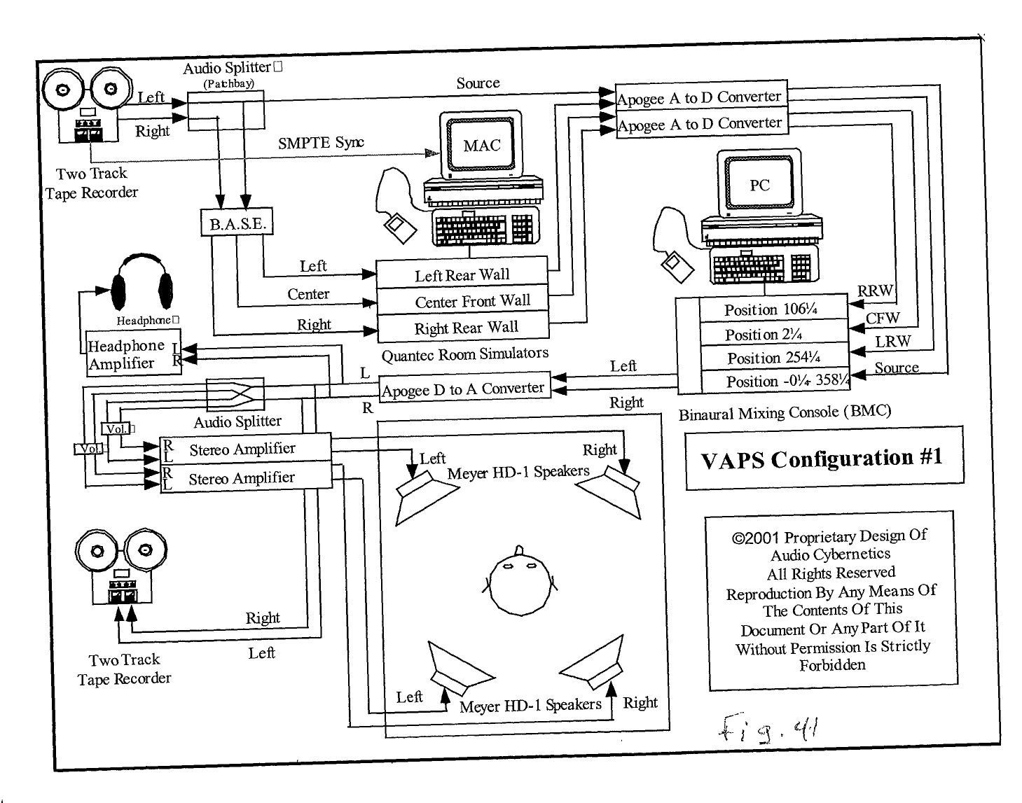

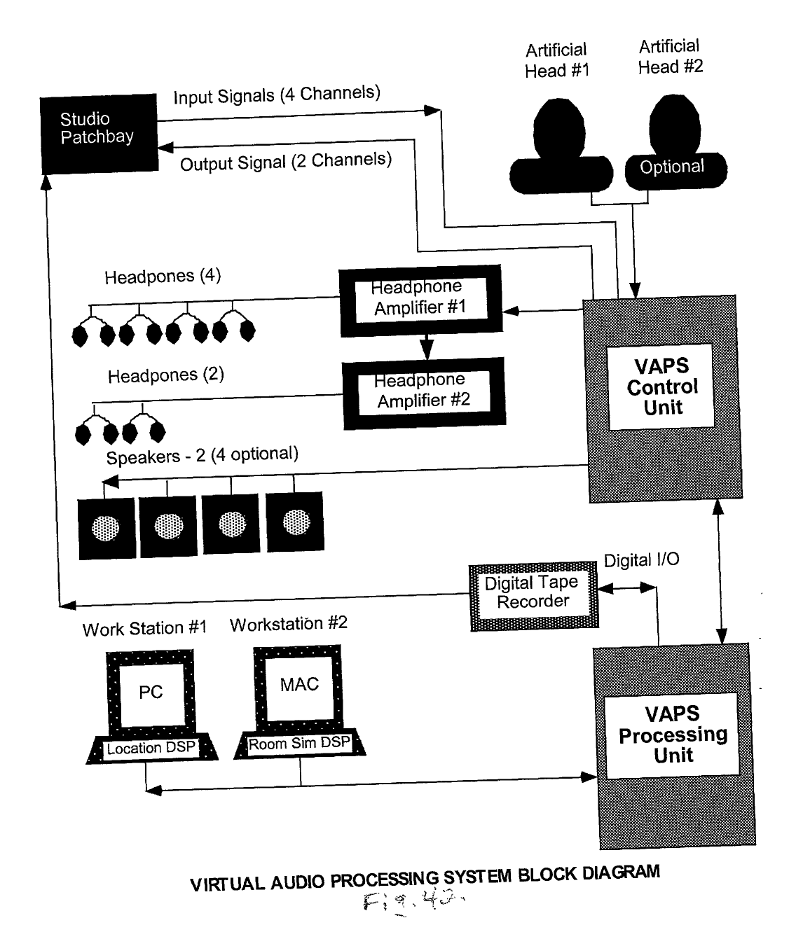

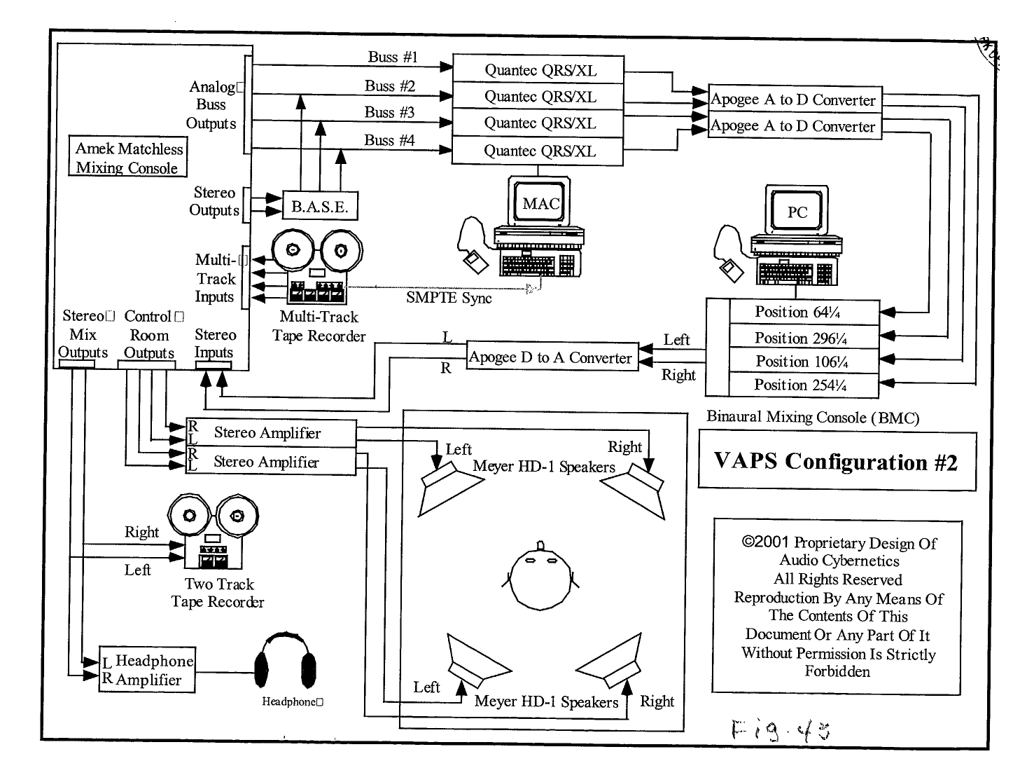

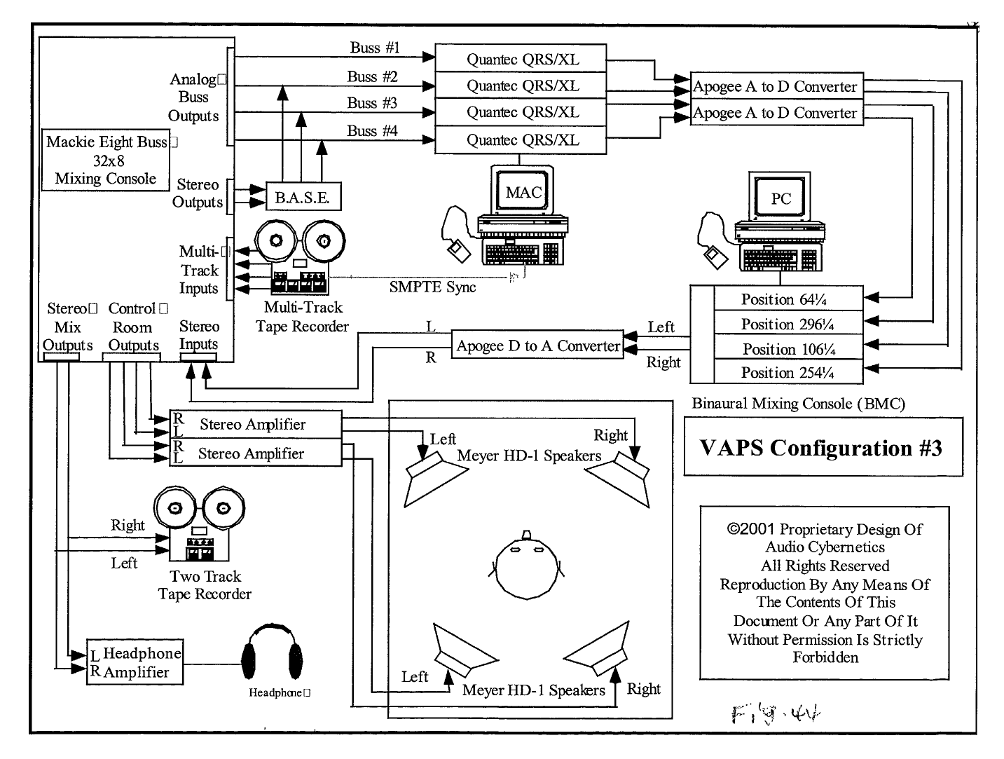

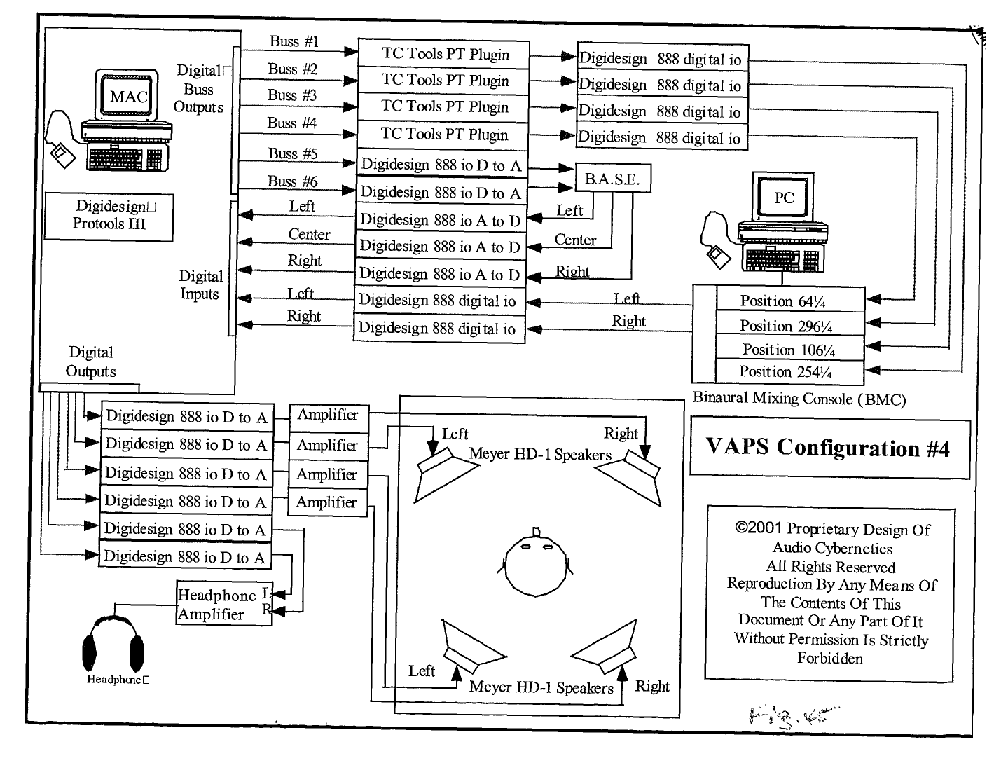

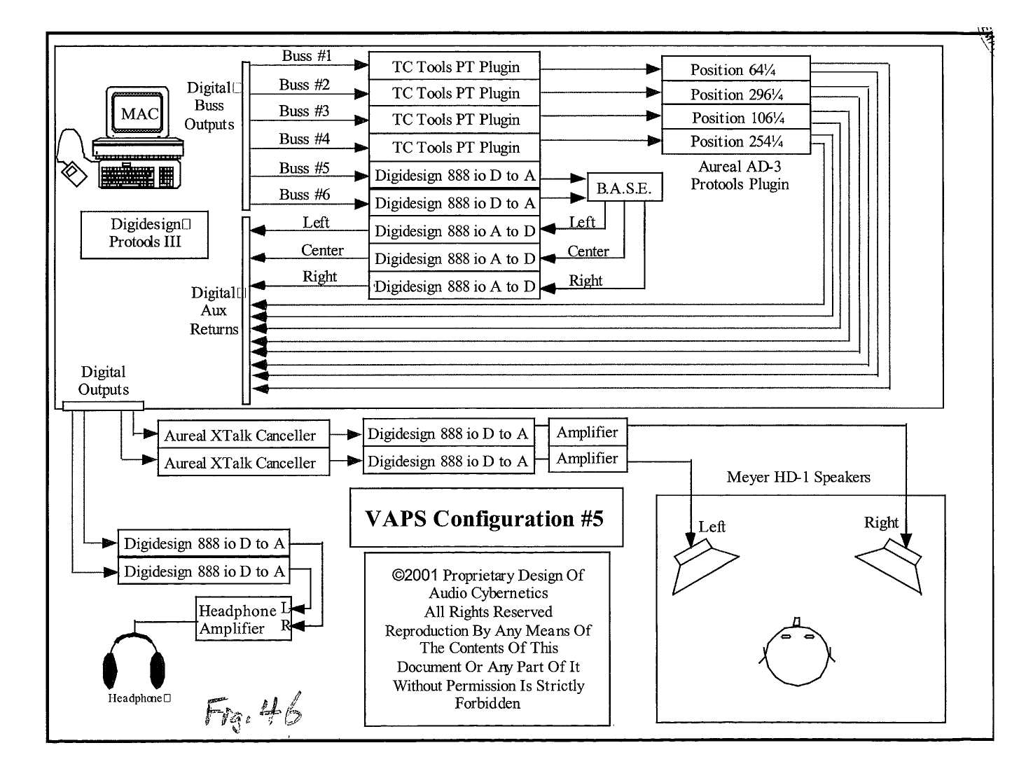

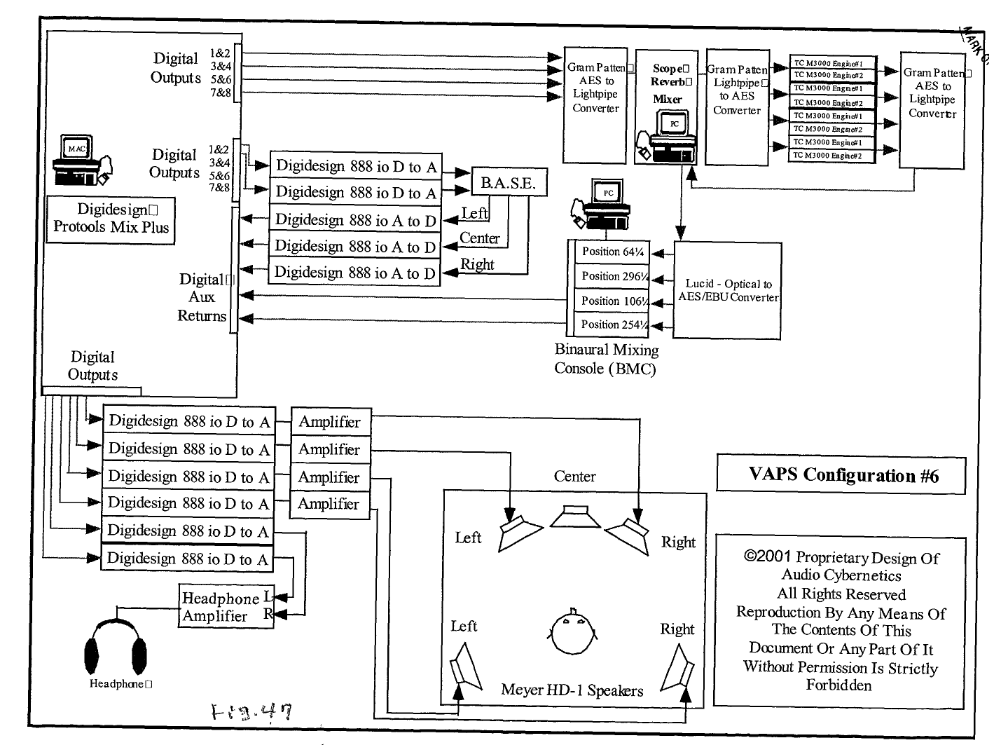

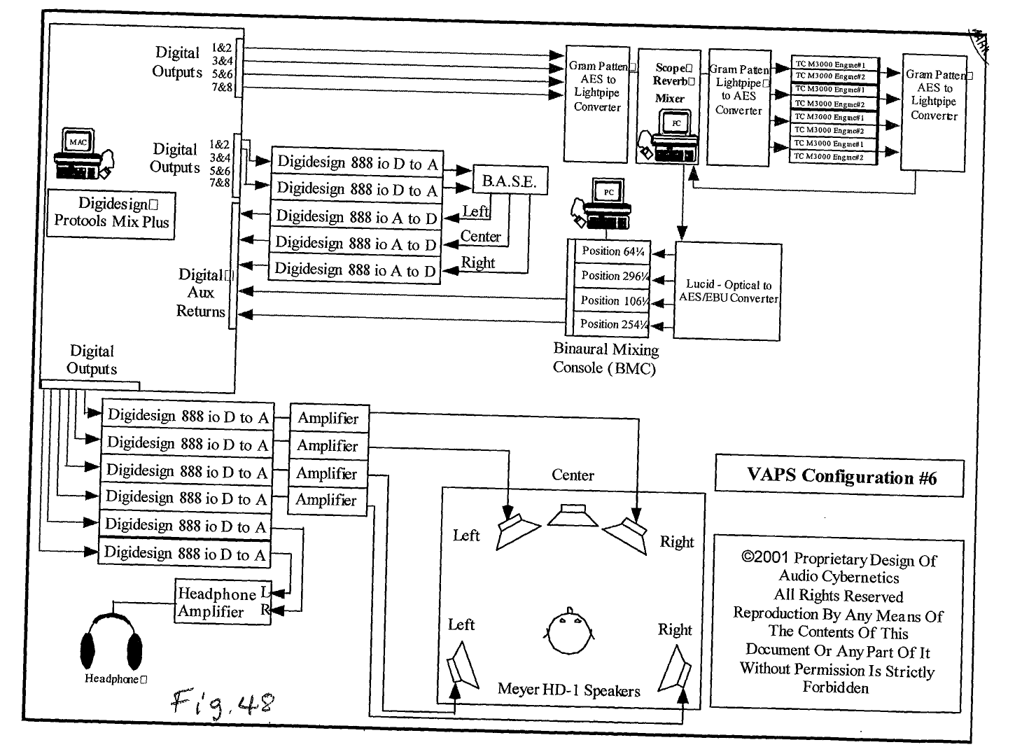

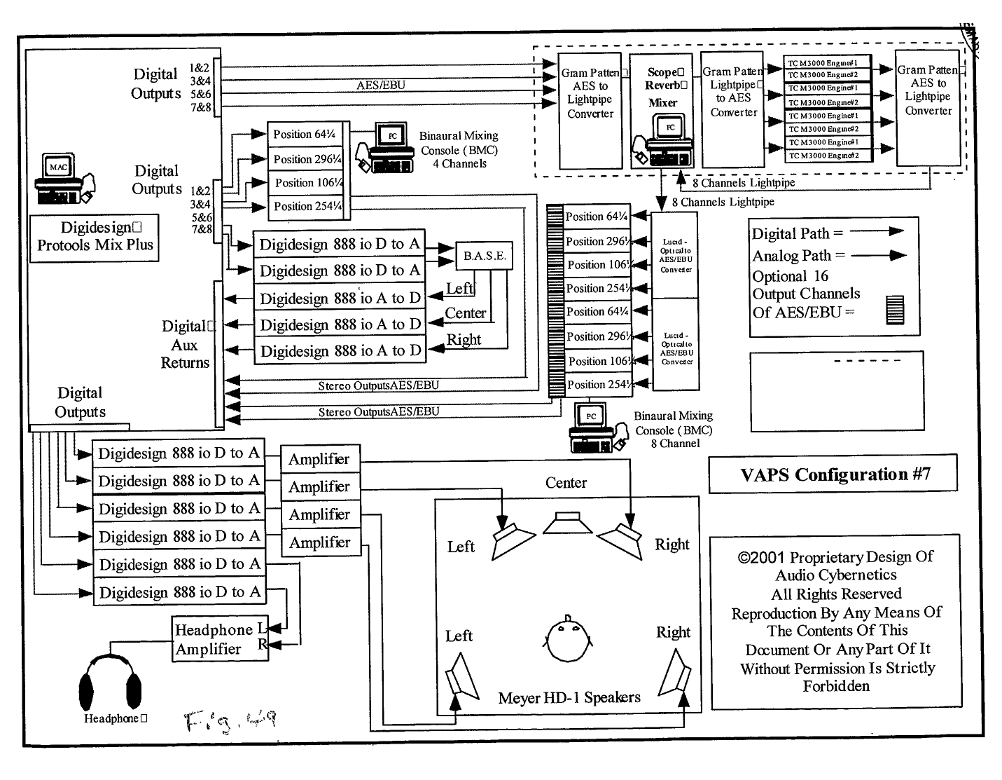

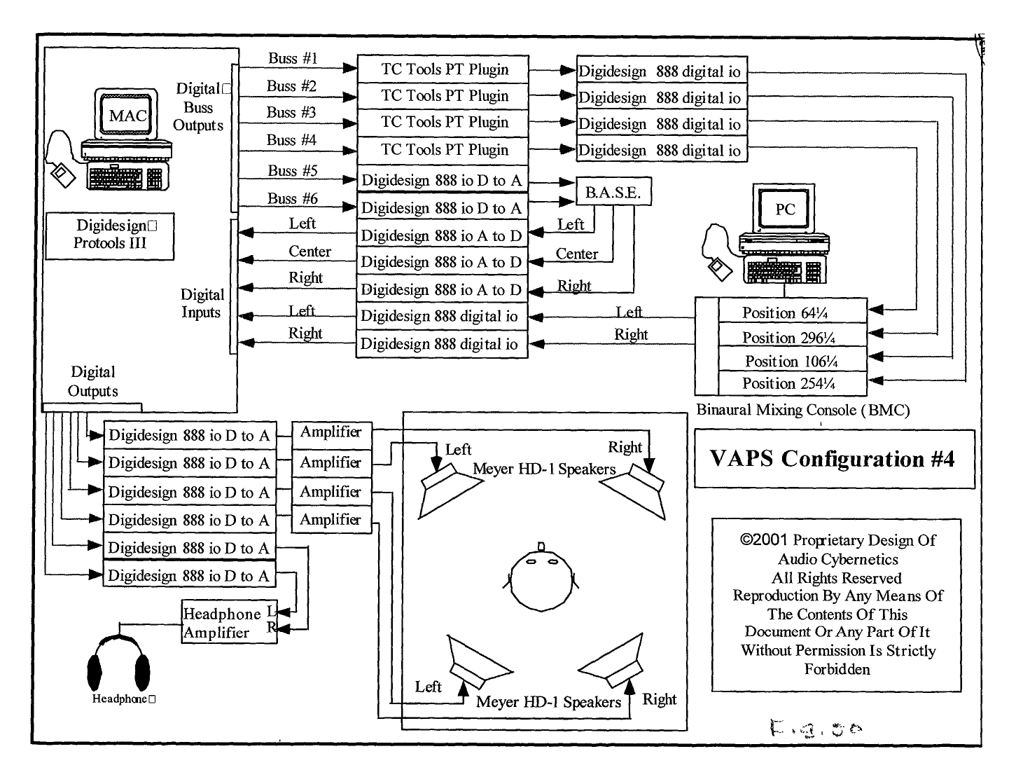

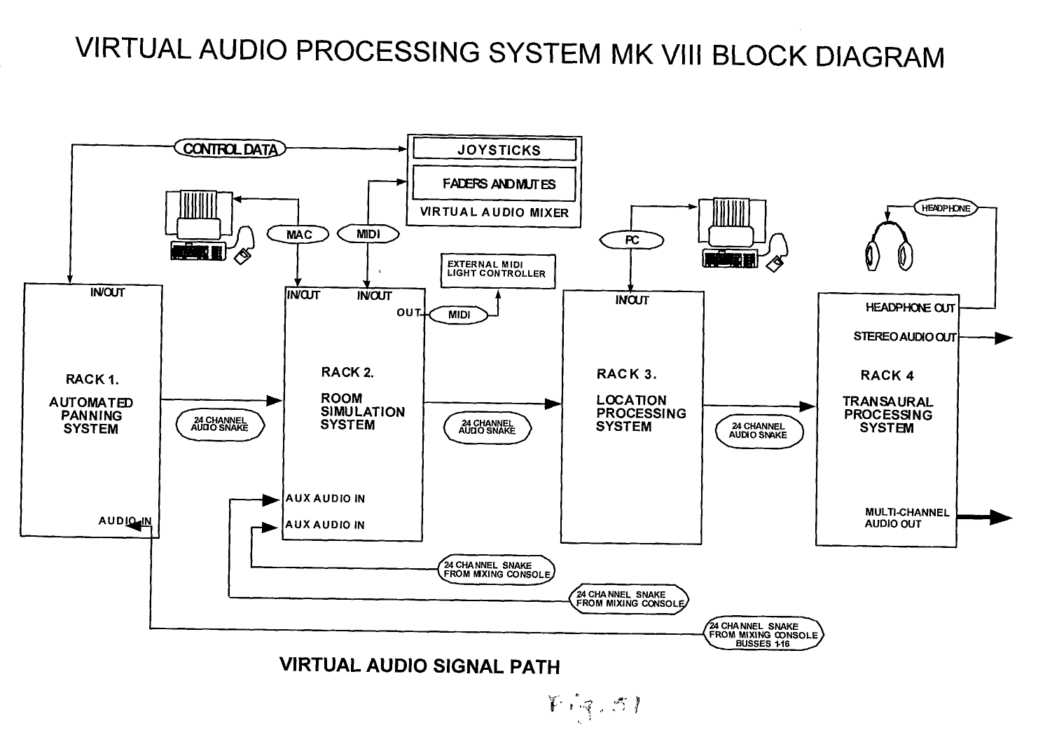

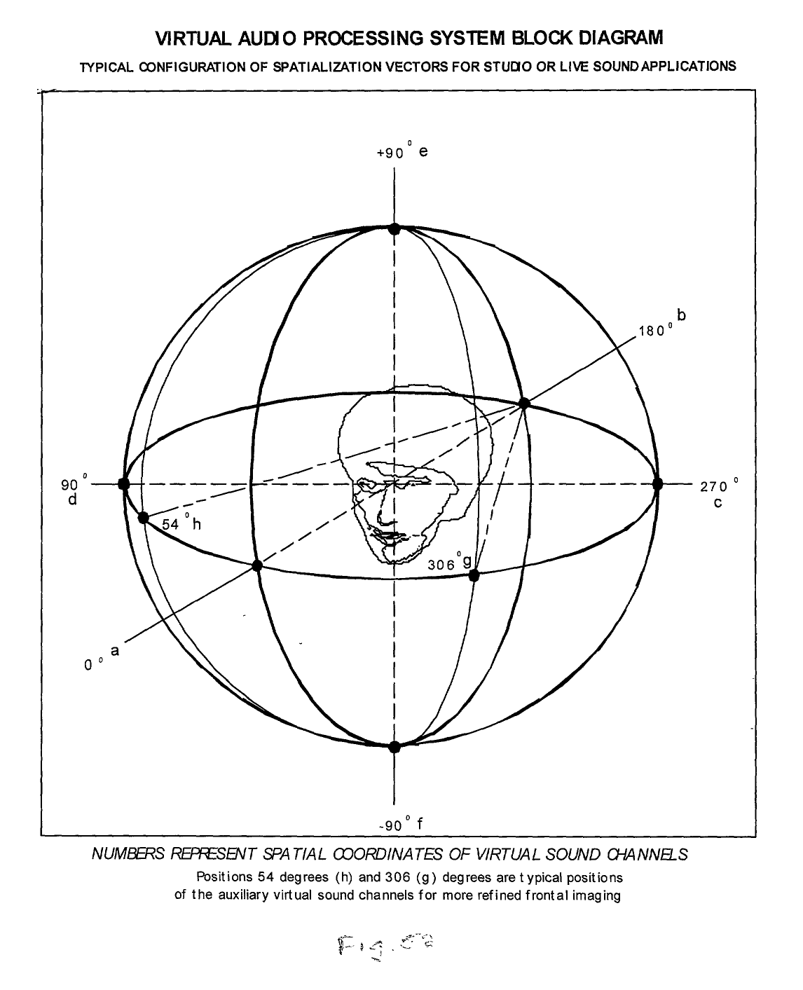

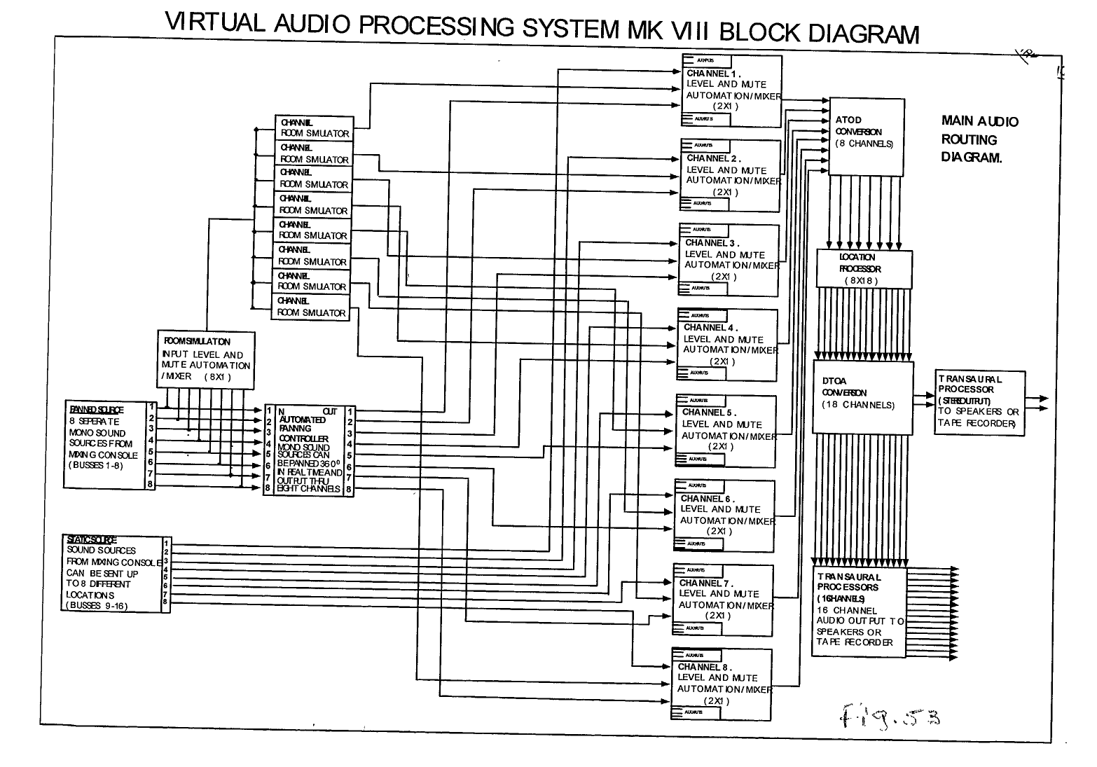

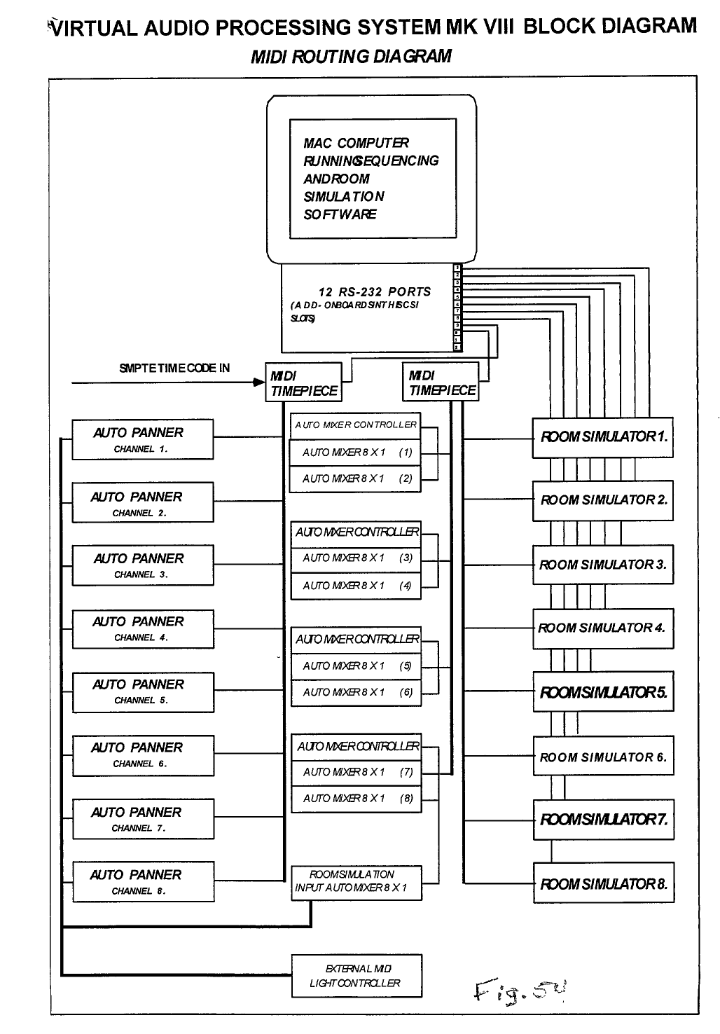

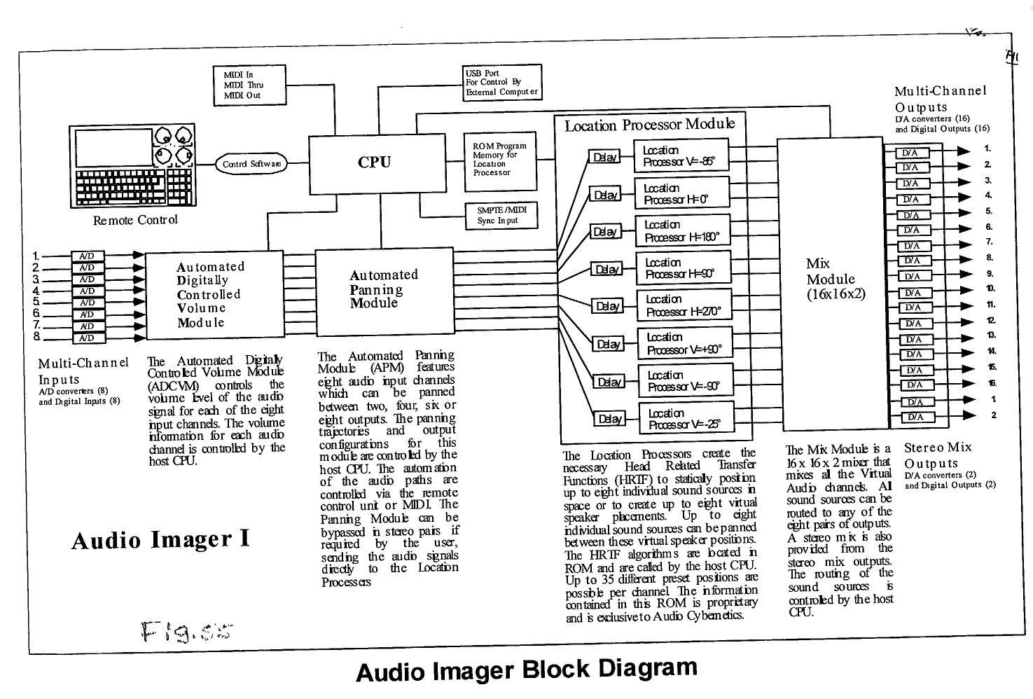

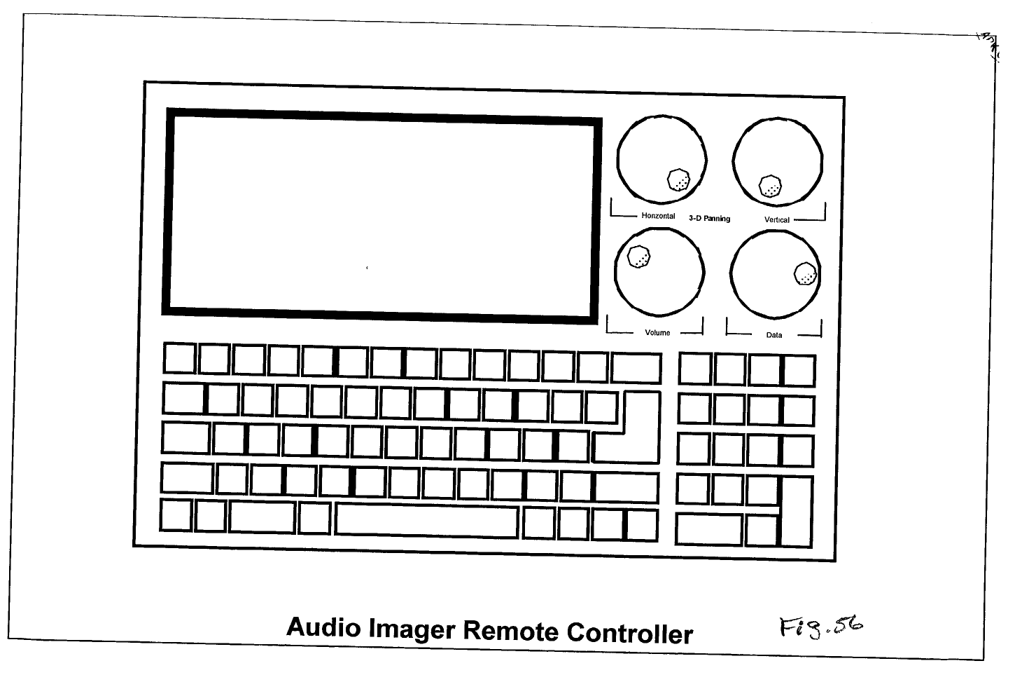

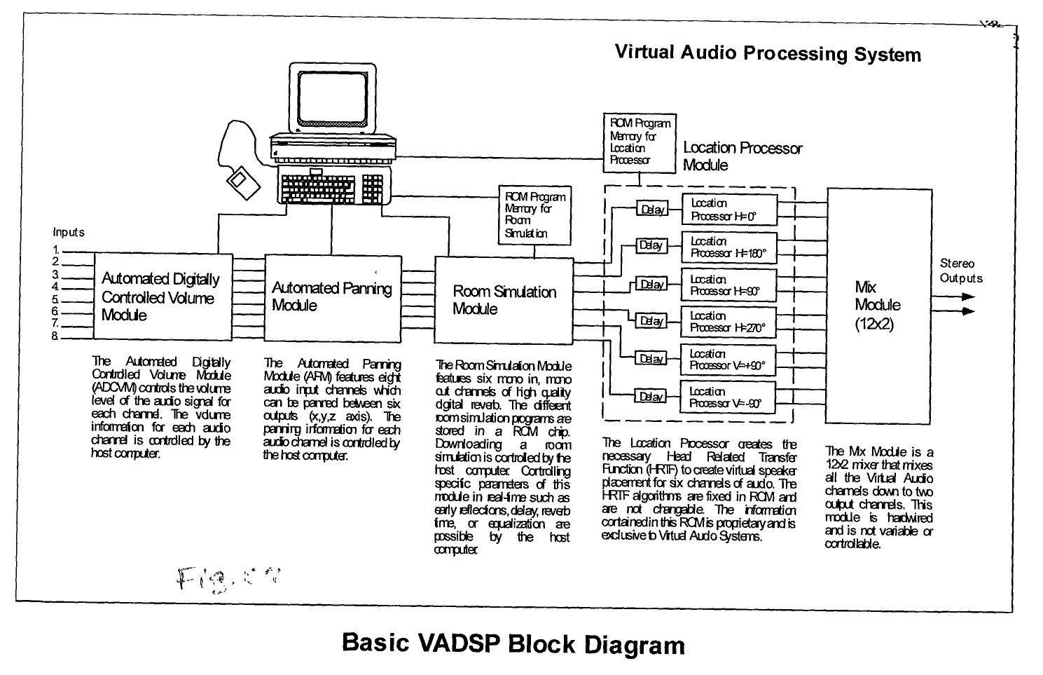

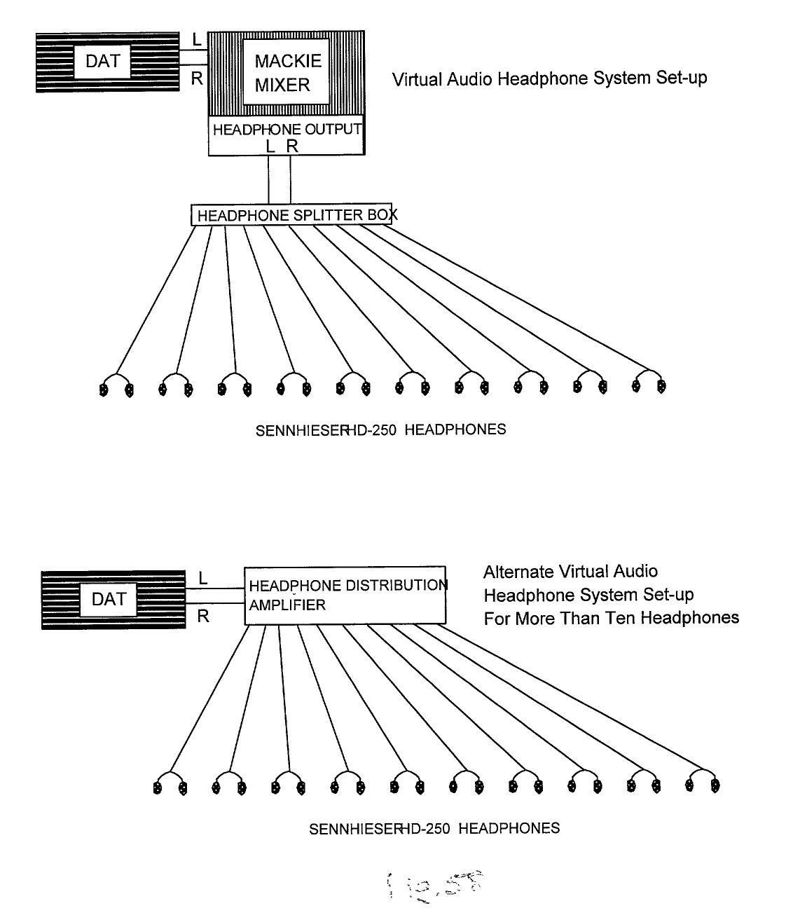

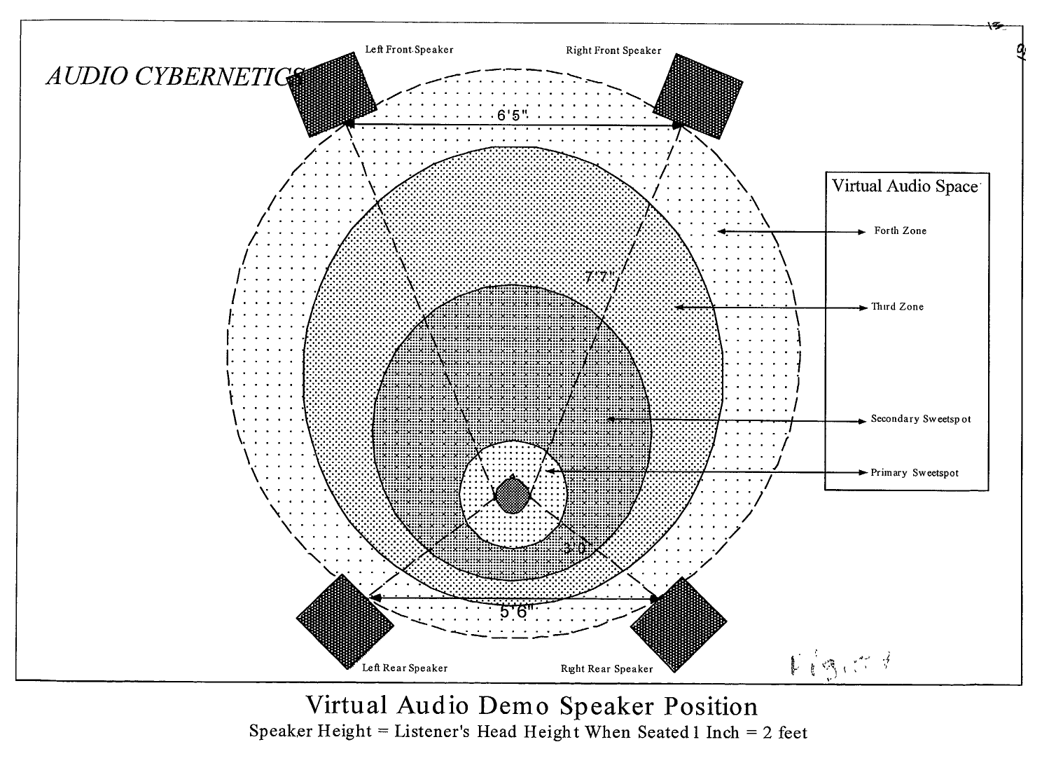

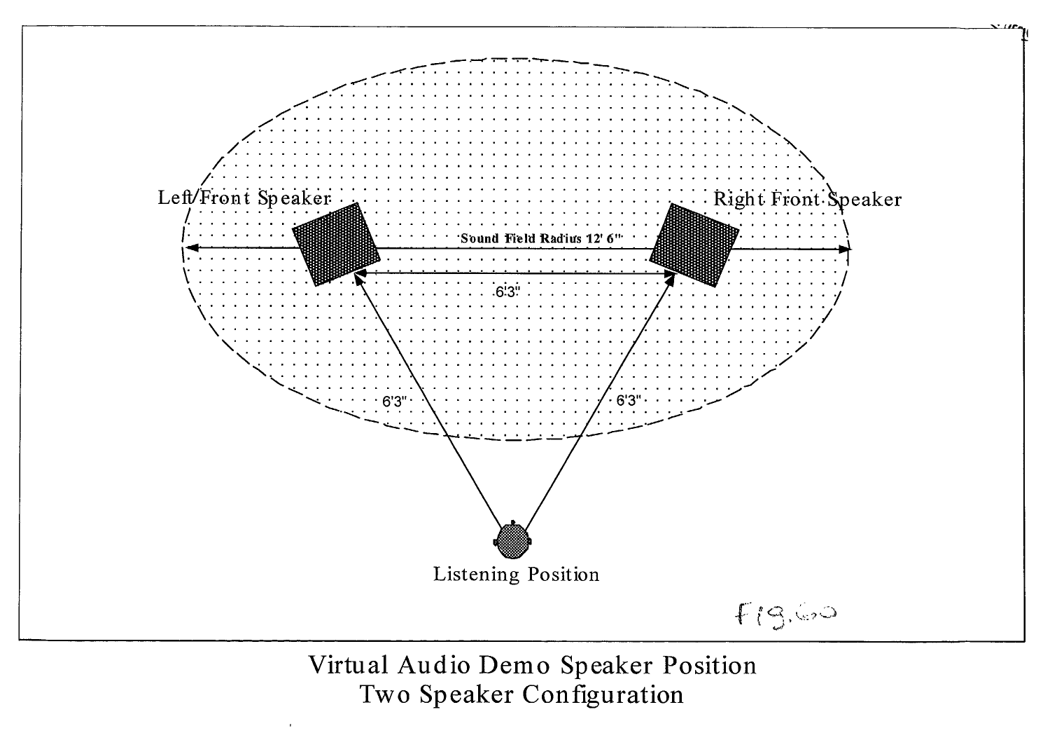

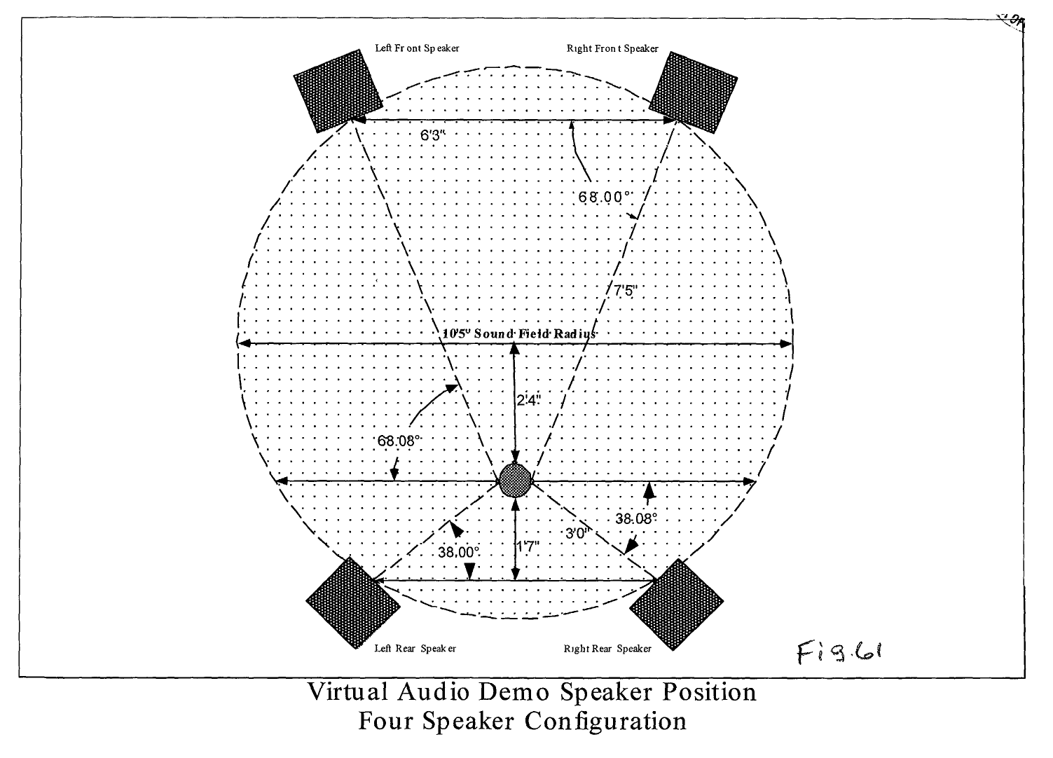

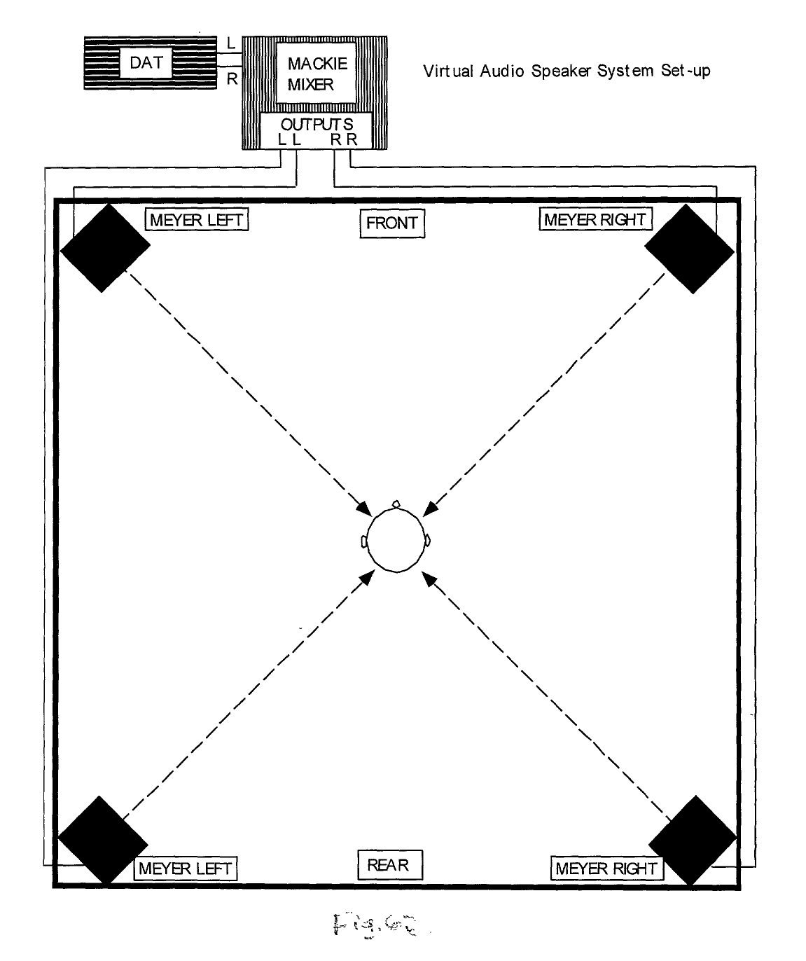

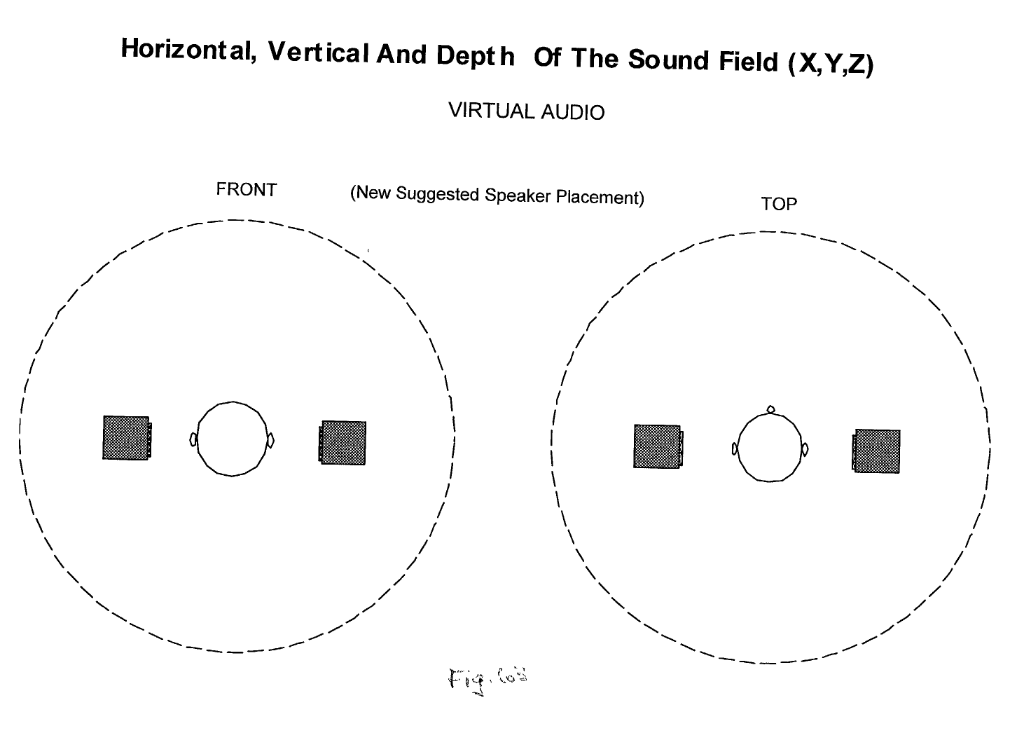

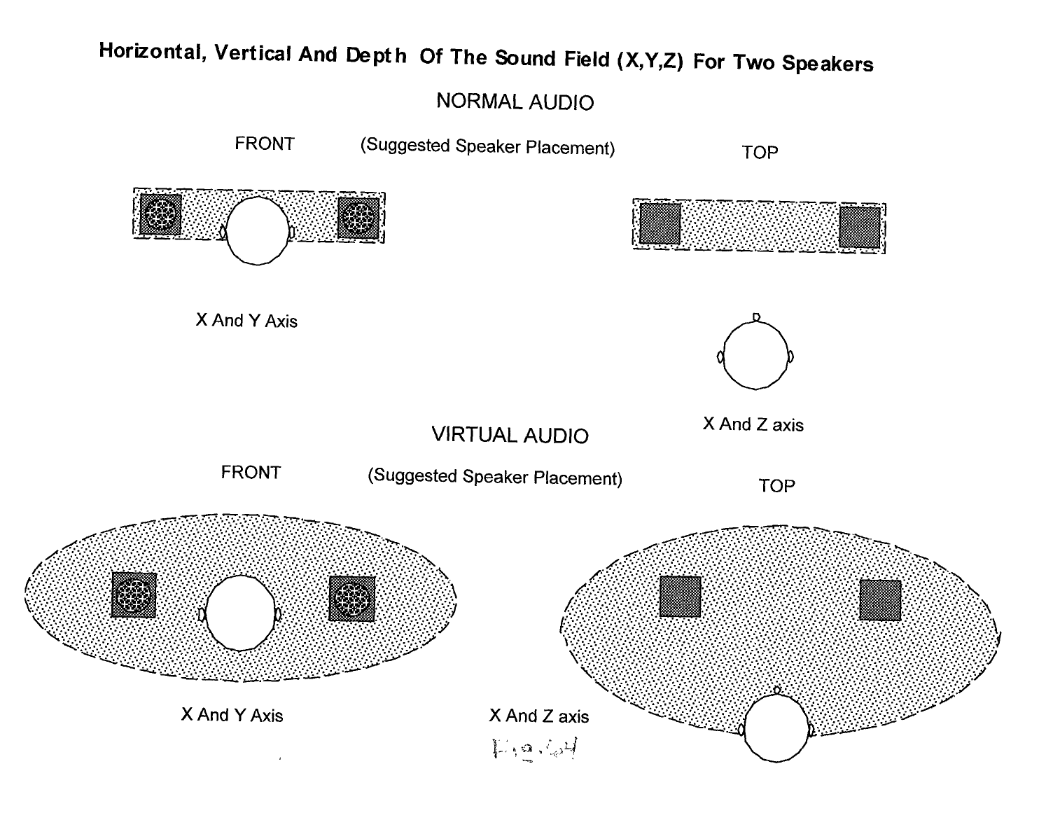

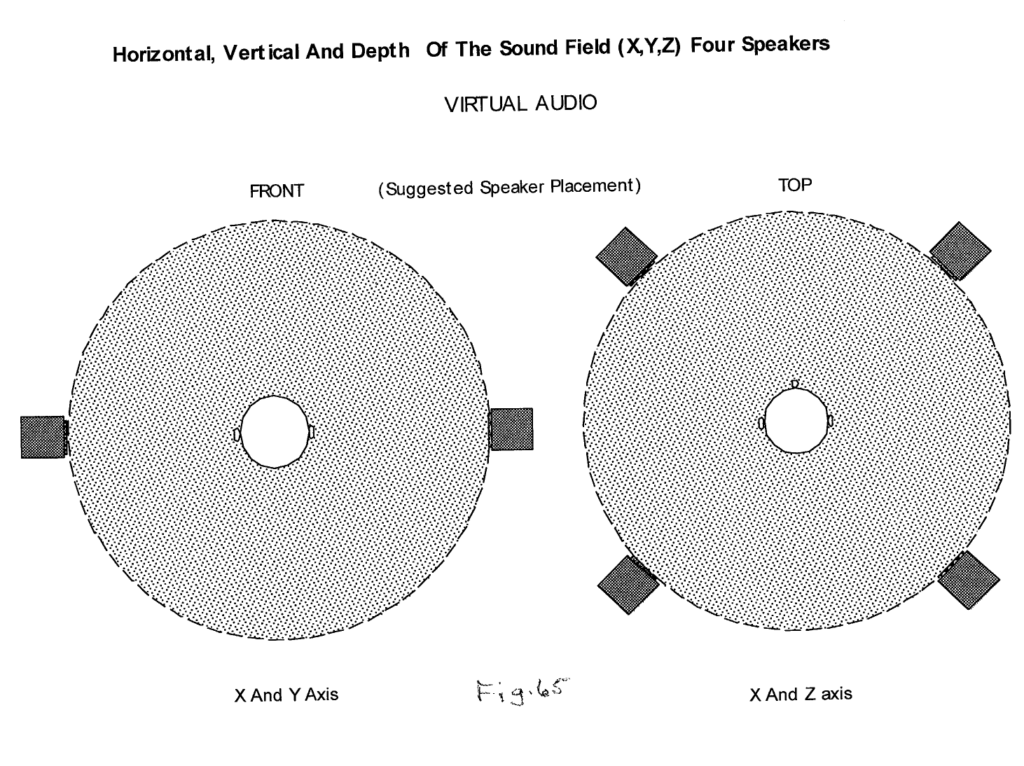

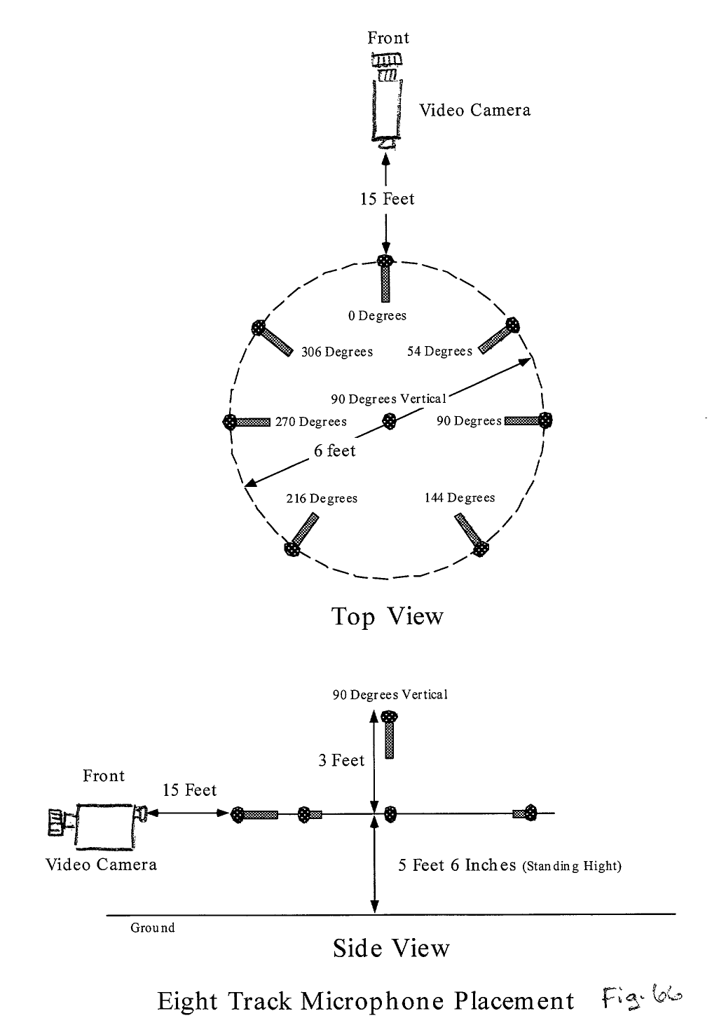

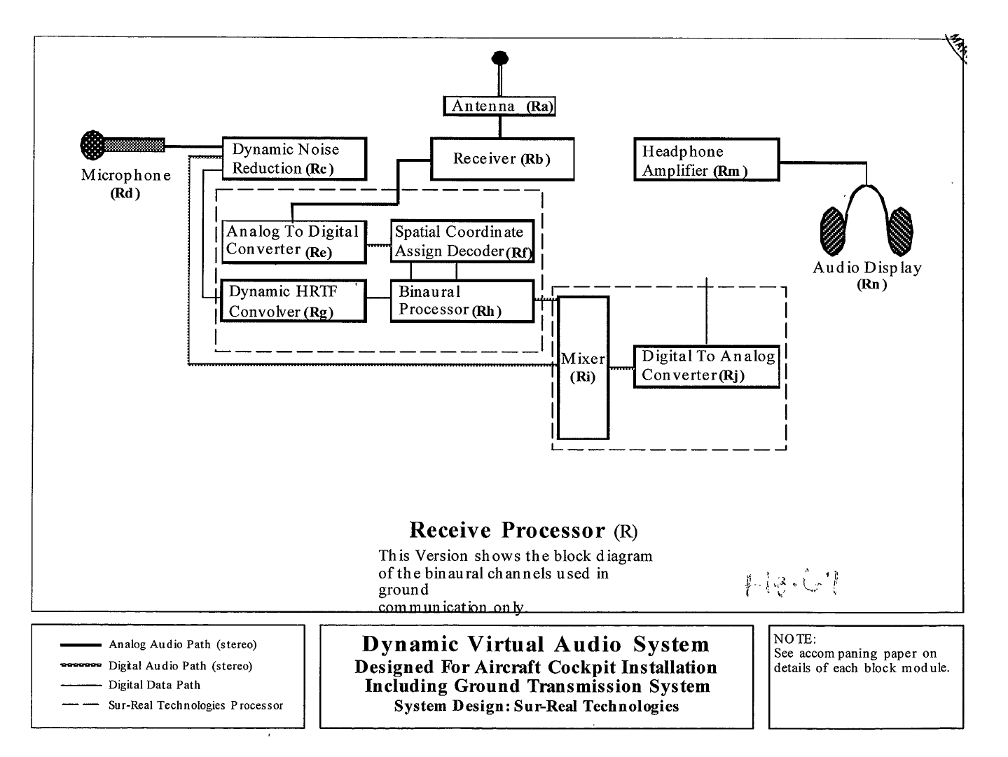

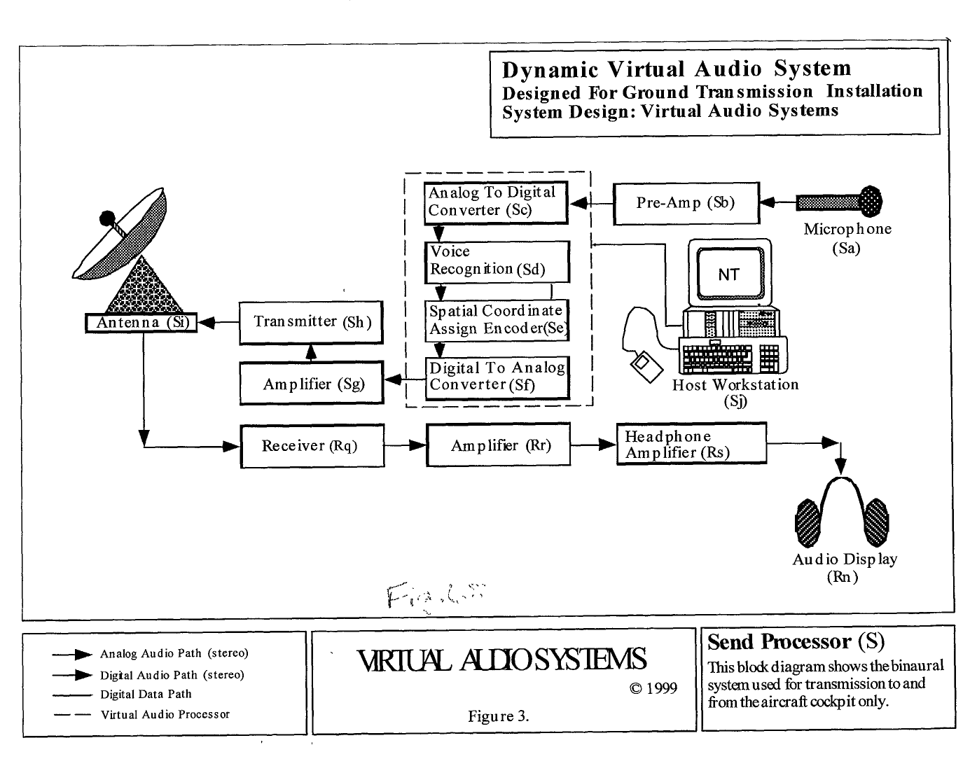

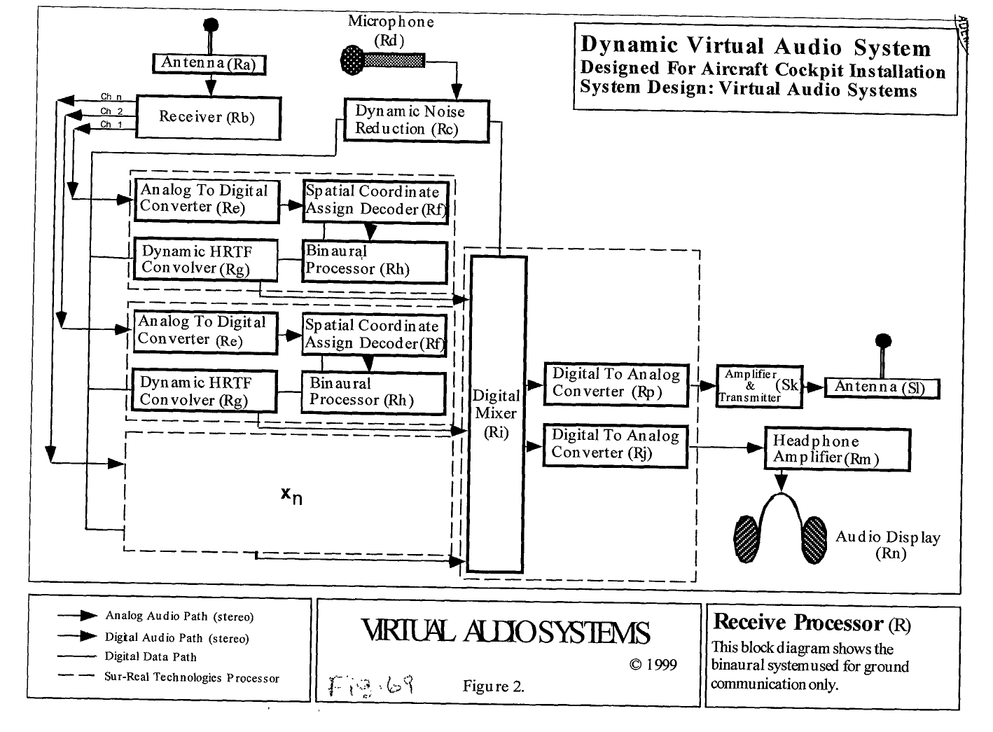

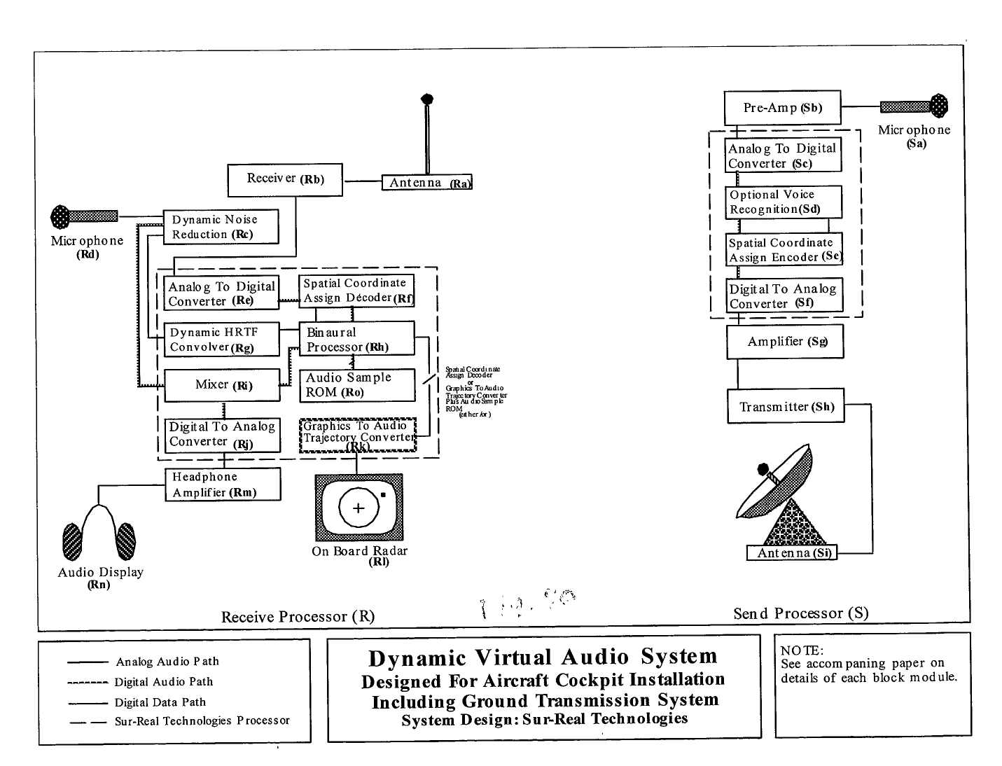

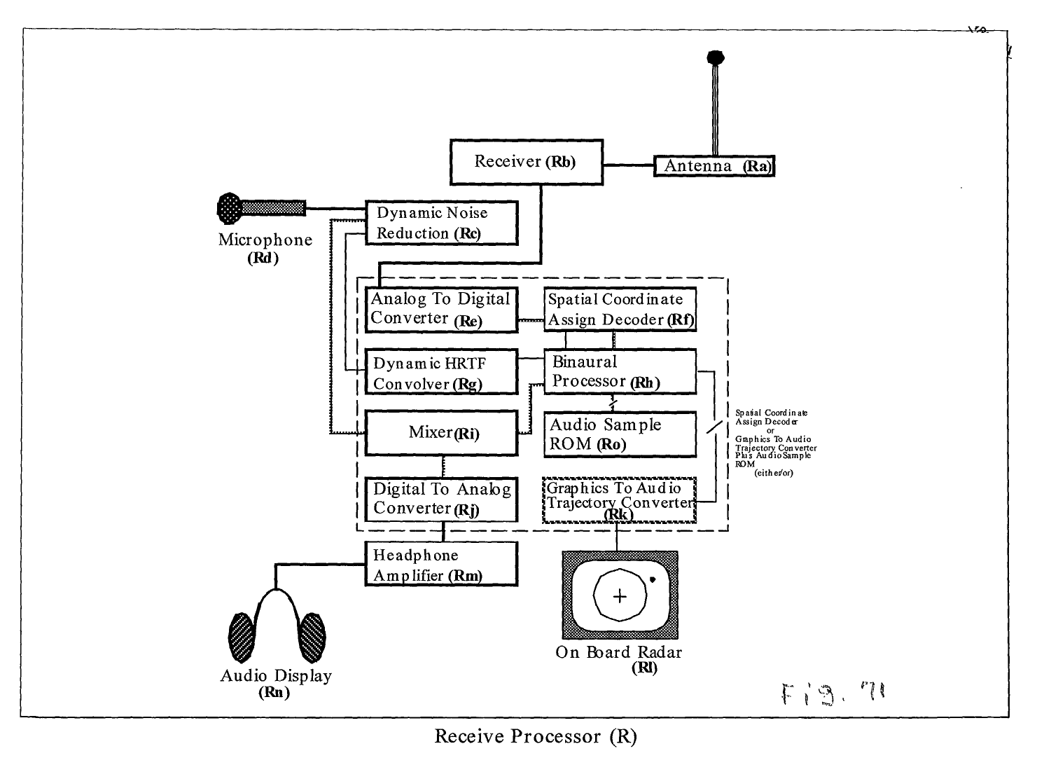

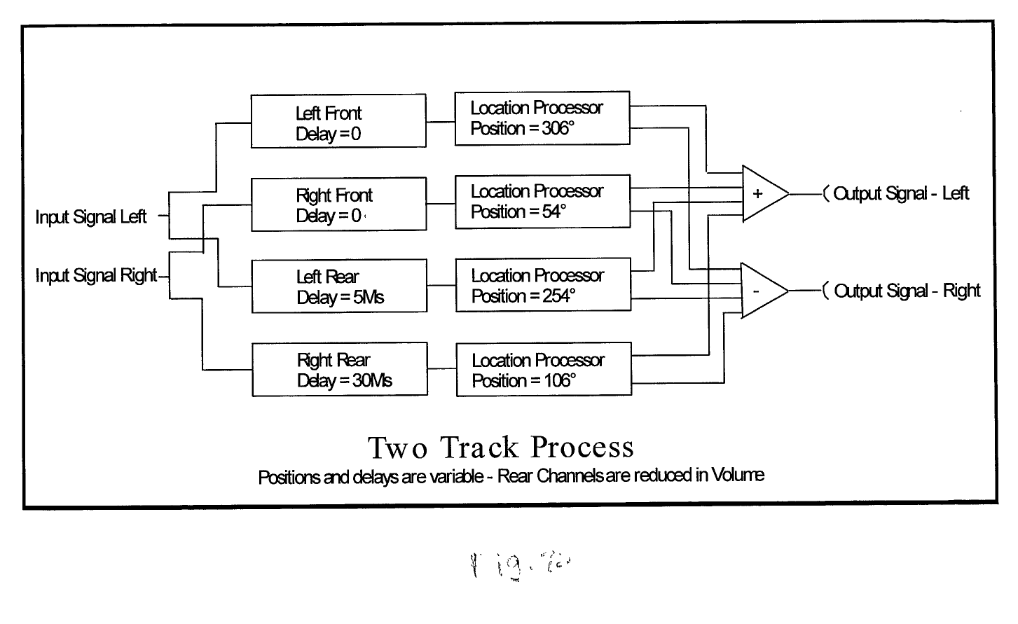

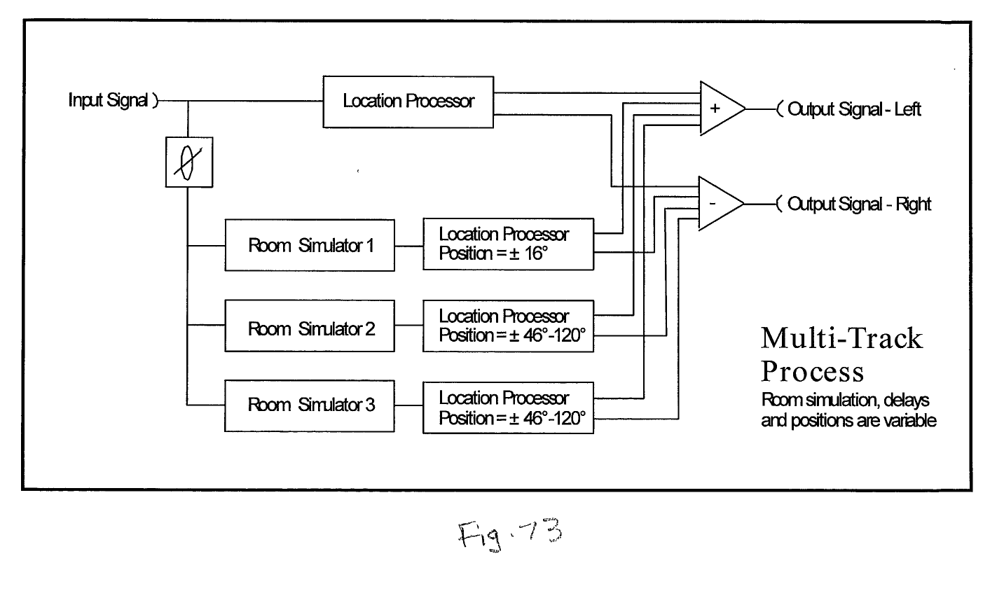

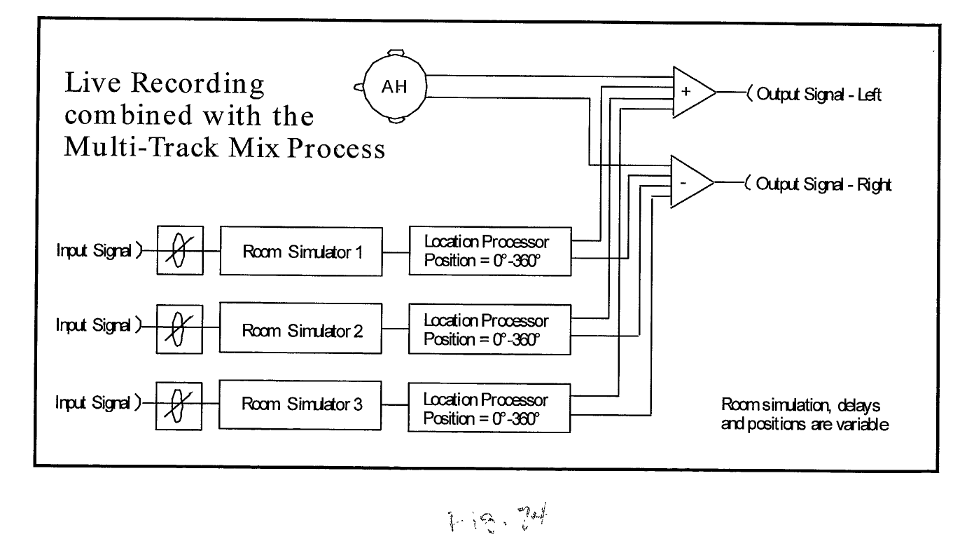

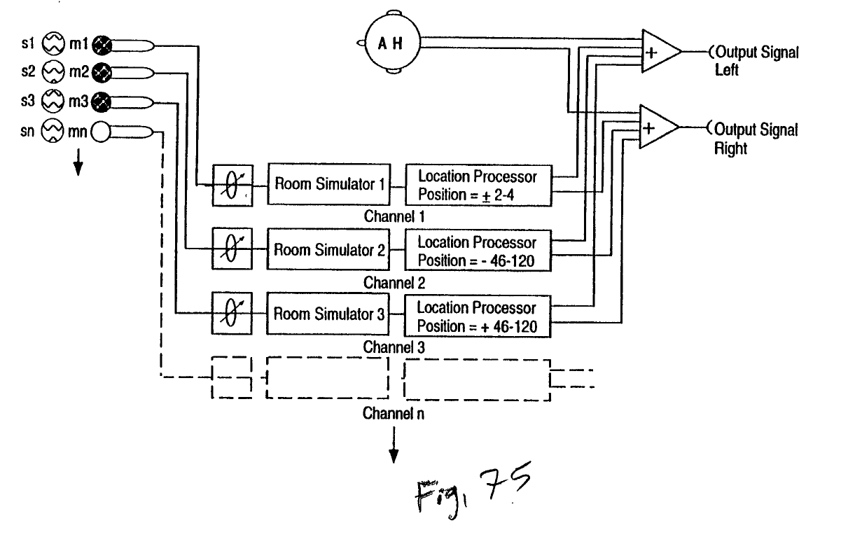

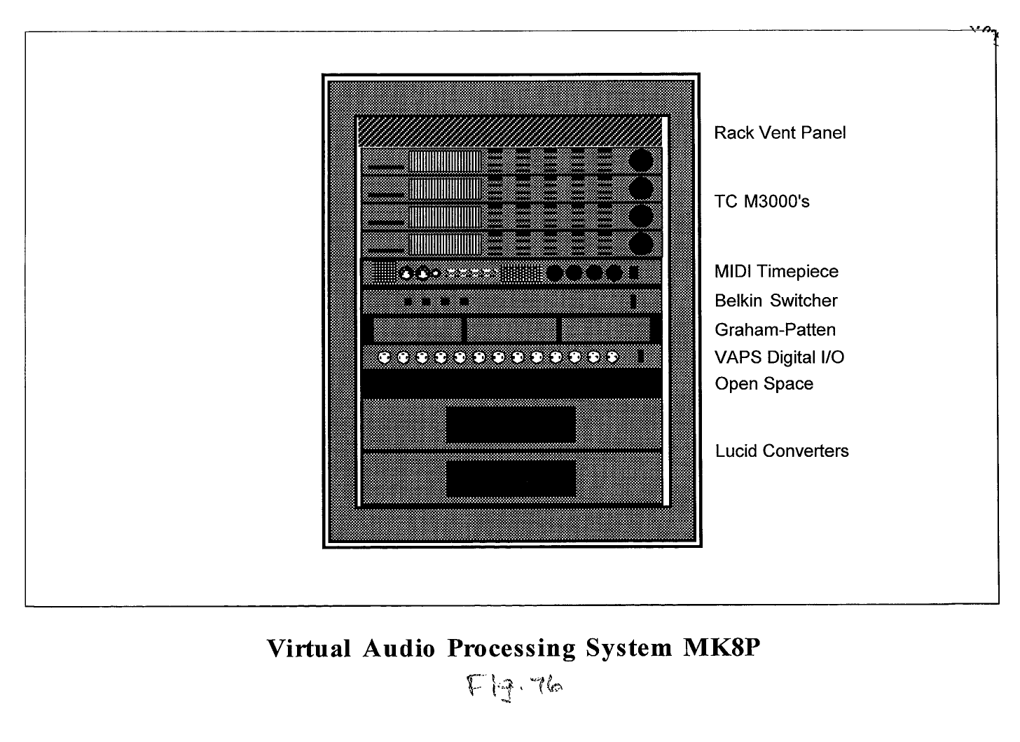

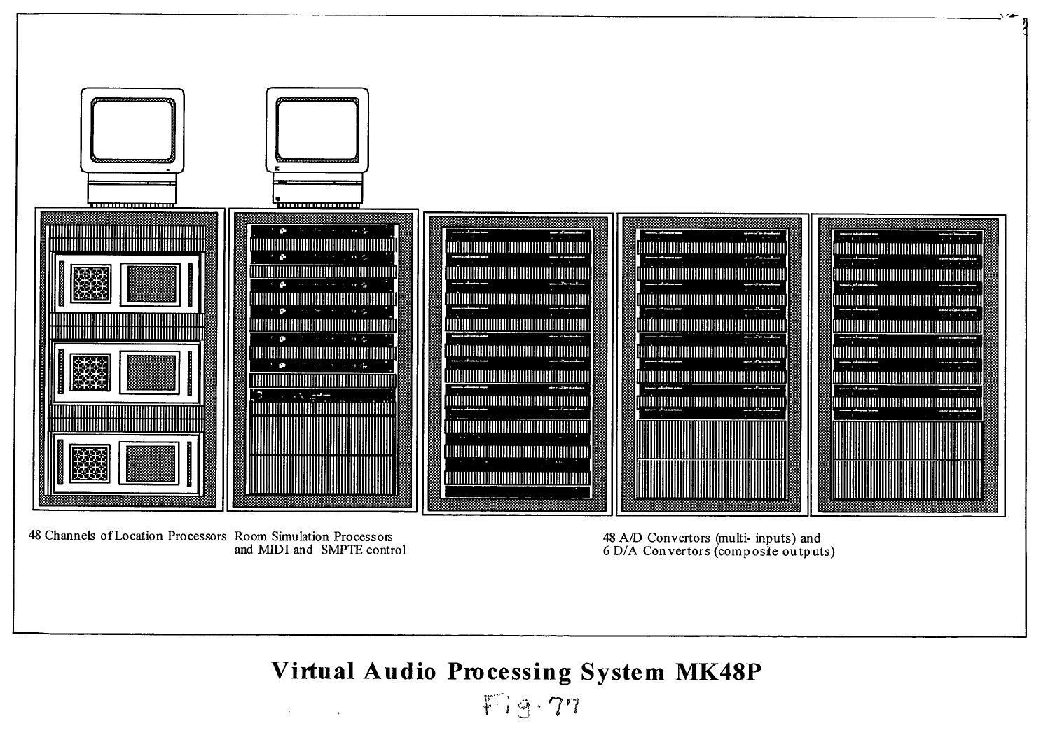

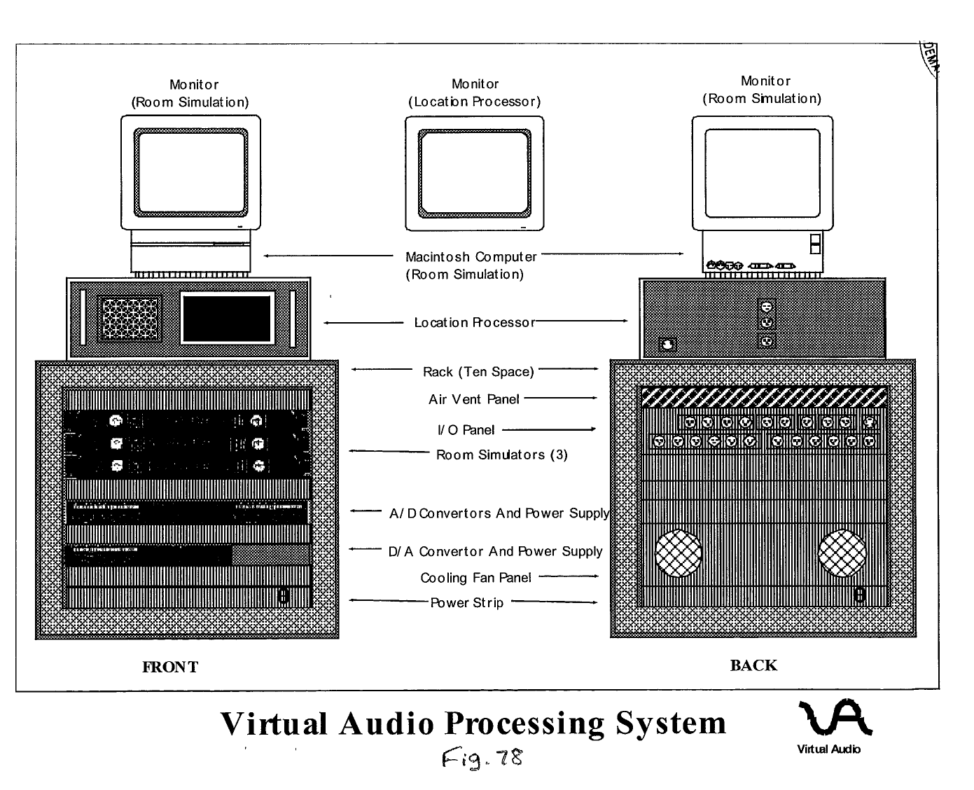

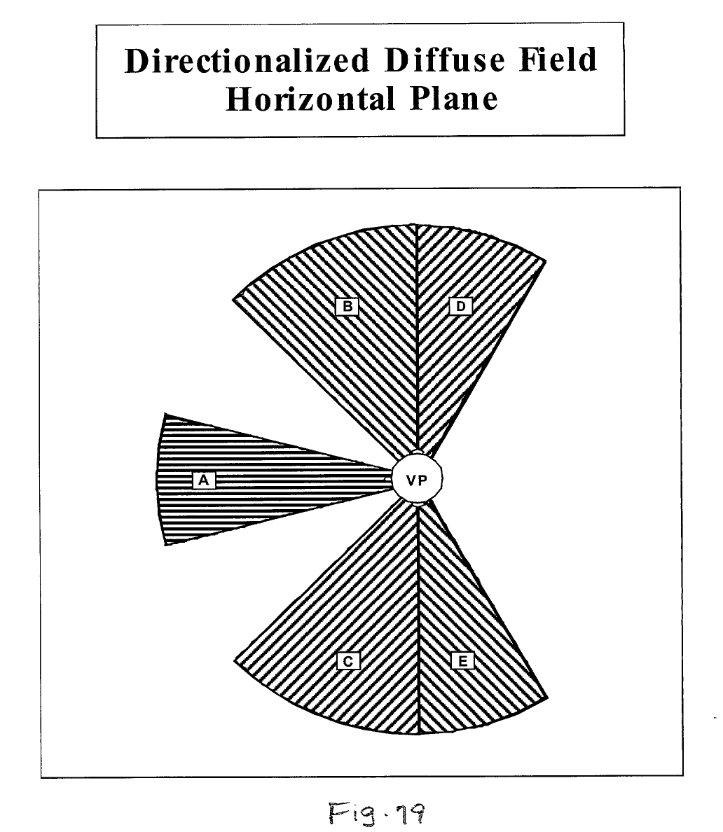

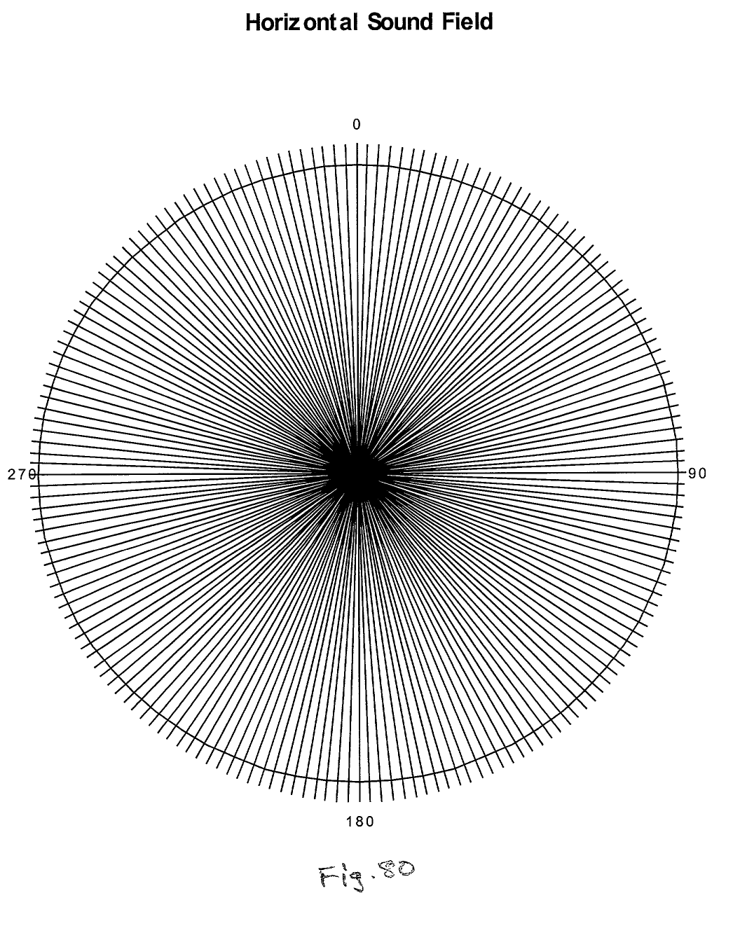

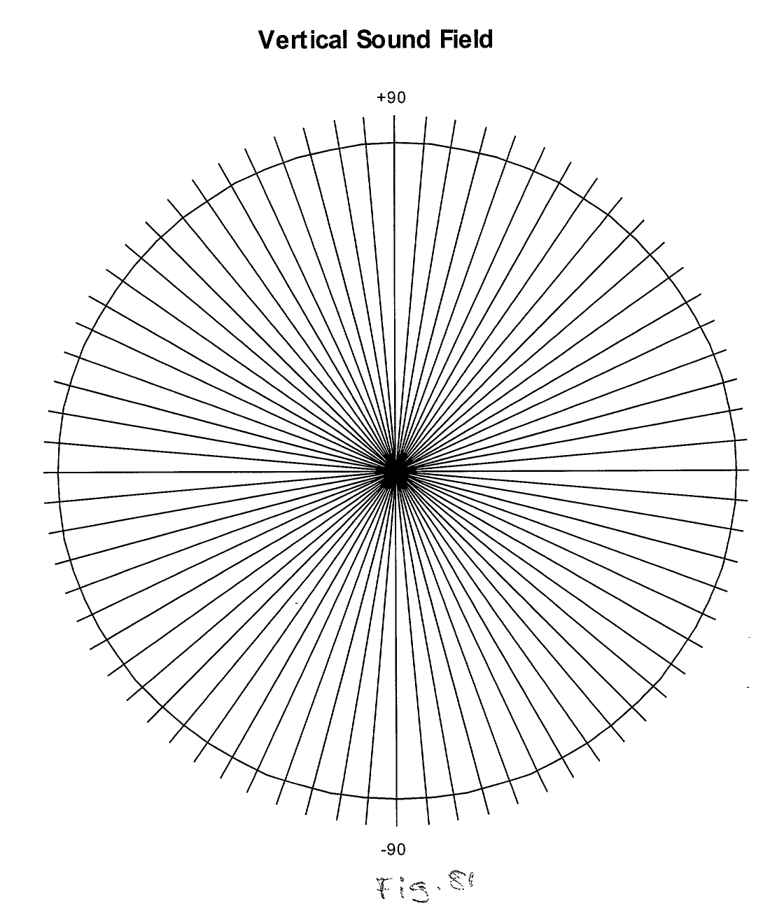

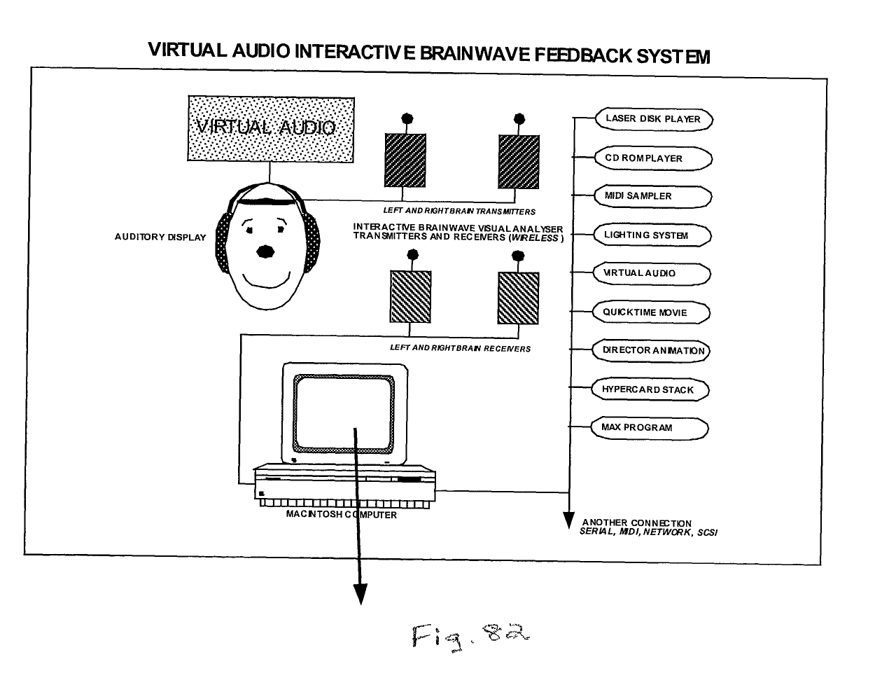

Referring to FIG. 23, the next step is to process the voices of the two actors. The first step is to ensure that the source audio (voices) is synchronized to the actors lip motions on screen. Once that is confirmed the processing can begin. Both the male and female actors are walking side by side, entering from the left. They walk to the center of the screen and stop momentarily in the center of the screen. Having stopped for a moment, they begin to walk again and then walk off the screen to the right while still talking. On screen, it appears that the distance of the actors from the listener is about twelve feet. Starting with the male voice first (mono source), the user uses the Location Processor panner, matches the vertical height of the actors mouth and follows his position on screen as he walks through the scene. The user uses the automation settings to record the motion synchronized to SMPTE time code. Another technique that is very effective is to follow the actor's motion using the Location Processor panner and continue the audio source panning after the actor has walked off the screen. For this to work properly, the audio source (dialog) must continue even though the actor has walked of the screen. The effect is the actor is still present in virtual space even though he is no longer shown on screen. This technique is also useful for different kinds of sound effects, such as cars, airplanes, trains, etc. The effect also creates the illusion that the actual picture screen is much larger than it really is.

Next, the user follows the exact same procedure with the female voice. Initially, the user uses the Distance Control module parameter to individually place the actors at a distance of approximately twelve feet. The female actor is slightly further away so, using the Distance Control module parameter, the user places her at approximately fourteen feet. Having the distance slightly different creates a perspective that contributes to the realism. Another technique that will increase the realism is to use footsteps through the forest as the actors walk. Using individual sound sources for each discreet step, the user places the sounds low in the vertical plane to match the exact location of the actors feet. The user also can do the same with rustling cloths etc.

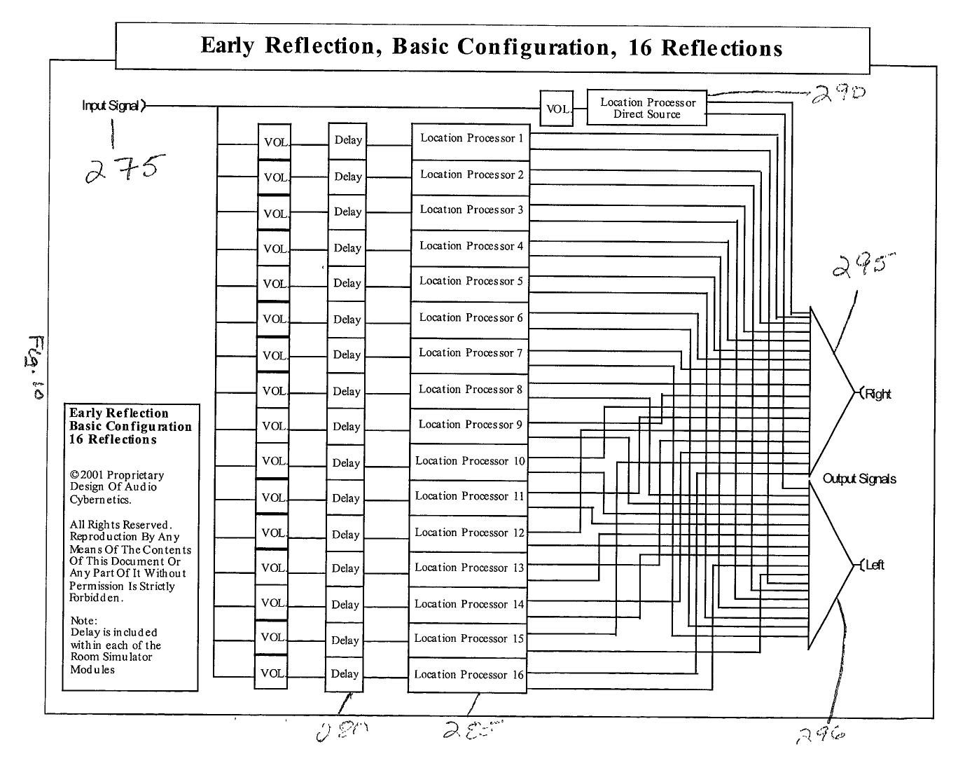

The final group of sounds are the musical instruments (see FIG. 10). The violin, cello and flute sources are all mono. The placement of these sounds are up to the user since there is no representation on the screen of where the instrument locations should be. The only criteria in this case is the instruments should not be in the same virtual space as the actors dialog. If possible, the instruments should be in their own space in between all the other sound sources. It should be noted here that contrary to normal recording knowledge, sounds in virtual space do not mask as easily as in normal recording techniques. This is due to the fact that the sound stage is bigger (360 ) and also there is the additional y (vertical)and z axis (distance). Normal audio is limited to only the x axis (horizontal). Normal sound sources placed on top of each other causes them to compete for clarity and presence (masking). In a virtual acoustic environment, the degree of precise discrete locations for the individual audio elements is within one degree in all directions (x,y,z axis). There are more discreet locations to place the sound sources without them stepping on each other.

For this example, the cello will be placed to the left, slightly down and to the rear of the listener. These are the approximate coordinates:

Cello—H 220×V −25

Use the Distance Control module parameter to place the cello at a distance of approximately 20 feet.

The violin will be placed to the right, slightly elevated and to the front of the listener. These are the approximate coordinates:

Violin—H 45×V 20

Use the Distance Control module parameter to place the violin at a distance of approximately 22 feet.

The flute will be placed in the front and slightly above and to the right of the listener. These are the approximate coordinates:

Flute—H 10×V 24

Use the Distance Control module parameter to place the flute at a distance of approximately 19 feet.

A useful technique for musical instruments which are not exactly considered a point source (such as a piano, pipe organ, and harpsichord etc.) and are recorded in stereo is as follows:

Acoustic grand piano: Use a room simulator programmed for a small concert hall. Process each channel of the stereo recording with different spatial coordinates.

Example: To make the piano fit into an overall virtual environment with other instruments (concert stage), the left and right stereo image usually needs to be reduced. A stereo piano is usually spread rather wide from right to left. In a real environment, this is not realistic unless your viewpoint is sitting directly in front of the piano from the player's perspective. By narrowing the left and right stereo spread, the piano can then be placed on a concert stage equal with other instruments. Use the Distance Control module parameter to create distance between the listener and the piano. If the listener position is from the audience point of view, the piano would be placed on the stage with other instruments maybe thirty feet away. The piano is still facing the listener from the players point of view. Usually the piano is facing sideways from the audience. To simulate this effect, the stereo image must be reduced so that the left and right horizontal coordinates are very close together”

Piano—Left—H 0 and Right H5

Then, use the Distance Control module parameter to push the left channel of the piano further away than the right by about four to five feet. This skewers the perspective of the piano, and in effect, swivels the piano around so that the keys are facing left. This trick can be used on other stereo sound sources as well.

Step 4. The Mix:

The last step in the creation of a virtual acoustic environment is the final mix (FIG. 11). All the sound sources described above have been processed and re-recorded as stereo pairs. The room simulation output is also recorded as a stereo pair. Volume is an active component of the spatializing process (distance cue). Also, each of the sound elements are relative to each other and the type of room programmed into the room simulator. As the spatializing process progresses, the sound elements are balanced as each additional sound element is added. When all the sound sources have been processed, the entire virtual environment should be balanced. Small adjustments can be made in volume and EQ but drastic changes should be avoided at this last step.

The final mix format for this project is stereo and four channel. For stereo, the mix can be transferred to any stereo medium, DAT, CD, cassette, VHS, Mini Disk, DVD, and DVD-A. The four channel format is the standard 5.1 surround format minus the center channel and the sub bass channel.

When mixing down to four channel; there are additional options available.

a. All stereo pairs can be mixed equally in the front and rear channels. This option should also be used when sounds are moving completely around the listeners head (360). It should also be used when there are numerous static elements located around the listener's head (360).

b. All stereo pairs that contain moving and non-moving sound elements located in the frontal hemisphere (270 to 90) can be sent to the front channels only.

c. All stereo pairs that contain moving and non-moving sound elements located in the rear hemisphere (90 to 270) can be sent to the rear channels only.

The intention of this discussion is to give examples of how to use the different modules of a virtual audio processing system (VAPS) and practical examples of methodologies, processes, and techniques for deriving spatial room simulation. It is intended as an introduction to the basics of spatial processing.

New Product: Real Time Virtual Audio Processing System

In prior art virtual audio systems every apparent sound source position in 3D space has associated with it a separate head-related transfer function which modifies the sound in a way that makes a listener think the sound is coming from that direction. These systems typically use programmable digital filters such as location processor 1 of FIG. 1 to implement those head-related transfer functions. Whenever a sound source moves by a small amount, the location processor is reprogrammed with new source position data so that it implements the head-related transfer function for the new location. These systems have difficulty simulating moving sound sources in real time because they must reprogram a location processor for each position of a sound source along its trajectory

A new virtual audio system which can process an audio signal in real time to produce a stereo signal giving a virtual sound source any desired trajectory in three-dimensional space. The system, illustrated in FIG. 2, employs a set of six fixed location processors 1-6. The location processors receive separate mono input signals A′-F′ and employ head-related transfer functions to produce output, two-channel audio signals A-F, respectively. A mixer 7 combines the six two-channel signals S-F to produce a signal stereo output signal. Each two-channel location processor output signal A-F gives a listener the impression of a sound originating from a single (virtual) speaker at a particular location in 3D space with respect to the listener. The head-related transfer functions within the six location processors are designed to surround the listener with six speakers: one to his right (channel A), another to his left (channel B), one above (channel C), one below (channel D), one in front (channel E) and one to the rear (channel F).

The system processes up to 8 audio input signals CH1-CHB. Each input signal passe3 through a volume control, module 8 to an automated panning modules 9. The volume control module separately controls the volume of each input channel CHI-CH8. The panning control module produces six output signals A″-F″, one corresponding to each of the six virtual speaker positions. The panning module receives input position data indicating the desired location of each of the eight sound sources within 3D space and allocates each audio input signal among its six output channels A″-F″ accordingly. For example if an input sound on CHL is to appear to originate from the a source listener's upper right front, the automated panning module allocates the CHi audio input signal proportionately to its front (E″), right (A″), and above (C″) output channels. The panning module also includes filters to adjust the volume and size dynamics of its six output A′-F′ to control the impression of apparent distance of each sound source from the listener.

The six panning module outputs A″-F″ pass to respective room simulation modules 10. Each module 10 provides room simulation effects by adding reflections and reverberations to its input signal to produce six virtual speaker channel signals A′-F′. The respective channel signals A′-F′ are summed by a set of mixers 11 and supplied to location processors 1-6. Each room simulation module is separately programmed by input room data to add room acoustics as appropriate for sounds originating in separate one of the six directions from the listener.

With this system a sound engineer using a set of joy sticks or other input devices can assign a 3D trajectory to any sound arriving on CH1-CH8. The panning module, which allocates sounds to the set of fixed position virtual speakers, facilitates this by allowing an external controller to continuously change the source position data in response to the operator's input. As he moves the joy sticks to define a sound source trajectory, the sound engineer immediately hears that sound follow that defined trajectory. Since the location processors 1-6 are fixed, there is no need for the system to take the time to reprogram them when a sound source moves. This system would allow the sound engineer to add a 3D sound track, for example, to a movie while watching the movie in real time. The same system could be used to engineer a 3D audio recording or to add 3D sound effects to a game, television program, or virtual reality display, all in real time. The system can be expanded to provide additional virtual speaker channels.

The design provides an additional improvement over prior art systems in that it modifies room acoustics relative to the position of sound sources within a room. For example if you were to sit in a cave and watch your friend walk past you from a closed end of the cave toward its entrance, you would expect not only the sound of his footsteps to diminish as he approaches the cave opening, you would also expect the character of the sound of his footsteps to change. Since cave's entrance is open to the world and does not reflect sound like its walls and floors, his footsteps should echo and reverberate less as he approaches the cave entrance.

Thus a virtual audio system ought to be able to continuously change room simulation effects as a sound source moves about in a room, particularly if the room acoustics are not uniform in all directions. Hence early reflections and reverberations produced by the room simulators in response to the sound source do not change with the position of the sound source within the room. Your friend's footstep echo's and reverberations will remain unchanged regardless of whether he walks in a closed end of the cave, near a wall or by its entrance.

The improved virtual audio system of cures this deficiency by adjusting room simulation to account for position of the sound source within the room. Assume that your friend's footsteps originate directly in front of you at a closed end of the cave. In such case, the panning module delivers all of the input audio signal for that sound to the E (front) channel room simulation module. The E channel room simulation module immediately provides a direct portion of the sound on output Channel E′ to be processed by location processor 5. The direct portion of the sound thus appears on the E channel (front) virtual speaker to give you the impression of footsteps directly in front of you. The E channel room simulator module thereafter sends early reflection and reverberation signals out on all channels A′-F′ in a manner that characterizes a sound source originating at the closed end of the cave.

As your friend moves to your right rear, the panning module gradually shifts the input signal to the A (right) and F (rear) room simulators. These two room simulators immediately produce direct sounds on the A and F virtual speakers giving you the impression that your friend is to your right rear. While the A and F room simulators thereafter produce early reflection and reverberation effects on all channels A′-F′, those effects differ from the reflection and reverberation effects produced when the input signal appeared on channel E″. The A channel simulator simulates room effects as would be produced by a sound source near the right wall of the cave while the E channel simulates room effects as would be produced by a sound source to your rear, near the cave entrance. You would hear room simulation effects as a weighted sum of the two, as would be produced by a sound source to your right rear. As your friend nears the cave entrance directly to your rear, the panning module shifts all of the sound source to the F (rear) channel so that the F channel room simulator controls all room simulation effects. This gives you're the acoustic impression that your friend is near the cave entrance.

New Product: Virtual Audio Interface

The advanced room simulation system discussed above would be suitable for providing three-dimensional sound for virtual reality systems, feature films, television programs and audio recording and other applications. An interface would allow a sound engineer to view a virtual room in 2D or 3D space and to assign positions and/or acoustic characteristics to each object in the room by pointing to them. Such objects can include sound sources, listeners, and passive sound reflectors/absorbers such as walls, floors and ceilings. The interface could also allow the technician to assign a trajectory to any object simply by “moving” the object in virtual space.

U. S. Pat. No. 5,208,860 to Lowe et al describes an interface that uses a multi-axis joy-stick to specify sound direction and trajectories in a 2D perspective view of a room. However the Lowe system does not operate in a true virtual 3D environment and does not allow the user to easily assign acoustic characteristics to objects in that space.

New Product: Virtual Audio with Advanced Room Simulation

Prior art virtual audio systems handle room simulation by adjusting reverberation and early reflections to control a room's apparent size and surface texture. But a real room has more character than size and texture. It has a shape and it is filled with objects. Its acoustic character changes as you move about and interact with the objects in it. Your feelings and sense of place change as you move from the corner of a room to its center because the acoustics in the corner of a. room differ from the acoustic of the center of the room. The cozy feeling you have when sitting in a well-padded easy chair comes in large. part from the way the chair-affects the sounds around you. When you walk to an open window, you have a sense of increased space in part because the room acoustics at open window differ: from those at a closed window or at a wall. Thus as you move from one part of a room to another, you experience a continuous change in acoustics due to the changing relationship between you, the room, and the objects in the room. Therefore you experience a continuous change in feeling. Similarly, the quality of sound a stationary listener hears changes as a sound source moves about in a room.

A virtual room having acoustics that do not change with the relative positions of both sound sources and listener within the room has a noticeably unnatural feel. A new system design allows room characteristics to change with the position of the signal source. A next generation virtual audio system design that, in addition to characterizing the shape of the room and texture of the room, characters the size, position and acoustic texture of objects in the room and takes into account the relative positions of both the listener and the sound sources within the room. In this system, as the listener and sound sources move not only do the apparent directions of the sound sources change, so too do the room-influenced and object-influenced characteristics of sounds. When you walk across a virtual room and sit in a virtual easy chair, the characteristic of sounds in the room will change accordingly. Thus the next generation system will add an improved dimension of reality to virtual audio.

The new real time virtual audio system design could be modified to make room simulation characteristics a function of listener position within the room. This system would likely employ one processor per sound source since many computations would be required to make real-time adjustments to room simulation. A major aspect of the project would be developing a model for a room transfer function capable of accounting for the size and shape of the room, the acoustic characteristics of objects in the room and the relative positions of a sound source and the listener within the room.

New Product: Low Cost, Virtual Audio System The visual aspect of interactive virtual reality software for personal computers and game equipment is becoming increasingly realistic. But an effective low cost interactive 3D sound system go with such systems has been elusive. In developing a passive virtual environment, such as a recording which simulates a walk through forest, the sound engineer controls the relative positions of the listener and all sound sources. The listener has no control over the environment. However in an interactive virtual environment, the relative positions of the listener and sound sources change in real time depending on user input. When you walk interactively through a virtual forest, you walk in whatever direction you choose. The virtual reality software includes, for example, a representation of the sound of a waterfall and knows from your input your position with respect to that water fall. But to give the listener the appropriate audio impression of that waterfall, the system must process that waterfall sound to place it in the right direction and at the right volume given your position with respect to it, and must do it in real time.

U.S. Pat. No. 5,026 to Lowe et al describes a sound imaging system for use with video game apparatus. However this system (which is not well detailed in the patent) apparently employs programmable filters to control sound direction since it adjusts the head-transfer function to achieve directionality. Thus this system would probably be relatively expensive to produce.

An inexpensive virtual audio system that could be used, for example, as an improvement to sound boards used in personal computers and video game equipment providing interactive virtual reality systems. Like the Lowe system, this system receives sound and position as input and produces as output the sound at the appropriate place in three-dimensional space using conventional stereo speakers. However this system does not use programmable filters because it does not change the head-related transfer function to adjust directionality. The new design instead employs six, inexpensive non-programmable filters, each implemented by a dedicated integrated circuit. Sound positioning is accomplished by an automatic panning module in a manner similar to his new high-end design. The system can also be easily expanded to include inexpensive filters providing variable room simulation effects.

New Product: Real Time Virtual Audio Processing System

In prior art virtual audio systems every apparent sound source position in 3D space has associated with it a separate head-related transfer function which modifies the sound in a way that makes a listener think the sound is coming from that direction. These systems typically use programmable digital filters such as location processor 1 of FIG. 1 to implement those head-related transfer functions. Whenever a sound source moves by a small amount, the location processor is reprogrammed with new source position data so that it implements the head-related transfer function for the new location. These systems have difficulty simulating moving sound sources in real time, because they must reprogram a location processor for each position of a sound source along its trajectory.

A new virtual audio system which can process an audio signal in real time to produce a stereo signal giving a virtual sound source any desired trajectory in three-dimensional space. The system employs a set of location processors designed to surround the listener with six fixed-location (channel B), one above (channel C), one below (channel D), one in front (channel E) and one to the rear (channel F). The system processes up to 8 audio signals from separate mono sound sources. An automated panning module applies each input signal to sources. An automated panning module applies each input signal to the various six speaker channels according to the desired location of its sound source within 3D space. For example if an input sound is to appear to originate from a source to the listener's upper right front, the automated panning module allocates the input audio signal proportionately to its front (E″), right (A″), and above (C″) virtual speaker channels. The panning module also includes filters to adjust the volume and size dynamics of the six virtual speaker channels to control the impression of apparent distance of each sound source from the listener.

With this system a sound engineer using a set of joy sticks or other input devices can assign a 3D trajectory to any sound. The panning module facilitates this by allowing an external controller to continuously change the source position data in response to the engineer's input. As he moves the joy sticks to define a sound source trajectory, the sound engineer immediately hears that sound follow the defined trajectory. Since the location processors are fixed, there is no need for the system to take the time to reprogram them whenever a sound source moves. This system would allow the sound engineer, for example, to add a 3D sound track to a movie while watching the movie in real time. The same system could be used to mix a 3D audio recording or to add 3D sound effects to a game, television program, or virtual reality display, all in real time.

The new design provides an additional improvement over prior art stereos in that it modifies room acoustics relative to the position of sound sources within a room. For example if you were to sit, in a cave and watch your friend walk past you from a closed end of the cave toward its entrance, you would expect not only the sound of his footsteps to diminish as he approaches the cave opening, you would also expect the character of the sound of his footsteps to change. Since Cave's entrance is open to the world and does not reflect sound like its walls and floors, his footsteps should echo and reverberate less as he approach the cave entrance.

Thus a virtual audio system ought to be able to continuously change room simulation effects as a sound source moves about in a room, particularly if the room acoustics are not uniform in all directions. Prior art virtual audio systems, in which room simulation effects are invariant with respect to the position of a sound source, cannot do this. Hence early reflections and reverberations produced by the room simulators in response to the sound source do not change with the position of the sound source within the room. Your friend's footstep echo's and reverberations will remain unchanged regardless of whether he walks in a closed end of the cave, near a wall or by its entrance.

The improved virtual audio system cures this deficiency by adjusting room simulation to account for the position of the sound source within the room. Assume that your friend's footsteps originate directly in front of you at a closed end of the cave. In such case, the panning module delivers all of the input audio signal for that sound to the E (front) channel room simulation module. A room simulation module immediately provides a direct portion of the sound on the virtual Channel E (front) speaker to give you the impression of footsteps directly in front of you. The room simulator module thereafter sends early reflection and reverberation signals out on all virtual channels A-F in a manner that characterizes a sound source originating at the closed end of the cave.

As your friend moves to your right rear, the gaming module gradually shifts the input signal to the A (right) and F (rear) channels. The room simulator immediately produces direct sounds on the A and F virtual speaker channels giving you the impression that your friend is to your right rear. While the room simulator thereafter produces early reflection and reverberation effects on all channels A-F, those effects differ from the reflection and reverberation effects produced when the input signal aggeared on channel E. The room simulator simulates room effects as would be produced by a sound source at some point between the right wall of the cave and near the cave entrance. As your friend nears the cave entrance directly to your rear, the panning module shifts all of the sound source to the F (rear)channel. The room simulator module responds by adjusting room simulation effects to gives you the acoustic impression that your friend is near the cave entrance.

The basic design can be upgraded to provide additional virtual speaker channels, thereby allowing tighter control over source positioning and more detailed room simulation. The design could also be modified to provide several static input channels bypassing the panning and room simulation modules to allow the sound engineer the freedom to include directed sounds that are not affected by room simulation effects. Also the fixed location processors could be replaced with programmable location processors. This would enable the sound engineer to control the virtual speakers for a given room.

The new design is patentable because it produces a 3D sound effect: by using a novel circuit topology. It is also patentable because the circuit topology allows room simulation effects to change with the position of sound sources within a room.

One implementation of a virtual audio processing system can include the following specifications and technical data:

THE VIRTUAL AUDIO PROCESSING SYSTEM BLOCK DIAGRAM

VIRTUAL AUDIO PROCESSING SYSTEM

Technical Data

Location Processor Section

INTERFACES 2×centronics

2×v−24

2×monitor (analog +TTL)

1×keyboard

INPUTS 4 inputs AES/EBU Format S/P-DIF

Switchable. XLR (use 1z:2=+)and cinch

OUTPUTS AES/EBU format SP-DIF. XLR and cinch

Sampling rate: 144.1 KHz/48 KHz. Automatic switch over

Word width: 24 bit internal processing

SIGNAL PROCESSING

Spatial Resolution

Horizontal Plane: Max 2 degrees (depending on direction of sound incidence)

Spatial Resolution

Vertical Plane: Max 5 degrees (depending on direction of sound incidence)

Dynamic Range: >90 db

Delay (per channel): 0 . . . 250 ms

Volume Control: −. . . 0 db (128 steps)

Level indicator (per channel): −48 . . . 0 db (peak hold)

Graphics Resolution: 640×480 points

Colors: 16

POWER SUPPLY

Supply Voltage: 100 to 250v(switchable 50 to 60 hz)

Power consumption 220w (location processor only)

Environmental temperature: 10 to 40 degree C.

Room simulation processing section.

AUDIO SPECS—(PROCESSED DATA)

Dynamic Range: >90 dB, unweighted

>95 dB, A-weighted

THD: <0.03%

S/N Q OdB Ref.: 78 dB

Frequency Response: 40 Hz . . . 14 KHzQ+/−0.3 dB

20 Hz . . . 15 KHzQ+/−0.3 dB

A/D CONVERSION

Principle: 2×oversampling with digital filtering

Sampling Frequency: 64 KHz

Resolution: 16 bit (linear)

Bandwidth: 15 KHz

Distortion: <0.02%

D/A CONVERSION

Principle: 4× oversampling with digital filtering

Sampling Frequency: 128 KHz

Resolution: 16 bit (linear)

Bandwidth: 15 KHz Distortion: <0.02%

INPUTS

2 XLR-3 Female balanced with floating ground

Level: +6 dBm/−15 dBm (selectable)

Impedance: 13.2K (balanced)

6.8 K (single-ended)

Headroom: +12 db over 0 db ref.

RF rejection: 18 dB/Octabe. 100 KHz

Level Display: −30 . . . +12 dB (dB-linear)

OUTPUTS

2 XLR-3 Male: balanced with floating ground

Level: +6 dBm/−15 dBm (selectable)

Impedance: <40 Ohms (balanced)

<20 Ohms (single-ended)

Headroom: +12 dB over O dB ref.

Minimum Load Resistance: 200 Ohms @I+dB typ.

Level Display: −30 . . . +12 dB (dB-linear)

PROCESSORS

Processors: 68008 control microprocessor

32-bit signal processor architecture

System Clock: 8.192 MHz

Sampling Frequency: 32 KHz

DSP Program: 256 steps per sample

Working Memory: uP-128 KByZe ROM

uP-64 KByte RAM

DSP-256 KByte RAM

RS-232 INTERFACE

Connection: 25-pin female, wired as DCE (modem)

Baud Rates: 300/1200/4800/9600

MIDI

Connections: IN+THRU

Channel (O-15): selectable

Control: -program number selection

recognition of keyboard note and dynamics

editing of look-up tables

system exclusive message capability (i.e. for control of QRS Freeze)further functions under development

FRONT PANEL

Display: 2×40 characters, backlighted LCD

Level Indicators: 4 LAD bargraphs Q 6 dB/step

LED: MIDI active indication

LED: RS-232 active indication

2 Status LEDs: user-programmable

Program Selection: 25 steps /revolution shaft encoder

Effect Mix: 11-position detent pot for mixing of direct and processed signals

MISCELLANEOUS Power Supply: Packaging:

Weight:

Protection Circuits:

PROGRAMS

ROM:

RAM:

ROOM SIMULATION:

FIR Filtering:

Subsampling FIR: Delay, Sampling:

Special Effects: 115/230V(+/−20%)30 VA

19″ standard rack mount

1 unit high, 320 mm deep

4.5 kg

against mains overvoltage

against loss of programs in case of mains failure—elective suppression of mains transient noise

90 preset locations

30 writable locations

Quantec QRS algorithms dual—up to 115 taps mono—up to 230 taps various configurations

MIDI triggerable

dual—max. 1023 msec

mono—max. 2048 msec

Various special Effects, including:

Gated reverb

Enhance effect

Soft attack

Reverse drums

Chorus

Panning effects

Flangers

(further programs in preparation)

Artificial Recording 1&ad

RECORDING HEAD SPECIFICATIONS;

Microphone capsules: -. Schoeps MK 2s mod.

Directional pattern: Structurally averaged monaural outer-ear

transfer function

Transmission range: 20-20.000 Hz

Sensitivity at kOhm: 14.2mV1pa

Equivalent loudness: 24 db

DIN 45405

Equivalent sound

pressure level, IEC 179: 17 dBa

Signal-to-noise-ratio,

referred to 1 pa: 70 db

Peak sound pressure

Kges=0,5%,

(1-kOhm load): 130 db SPL

Rated impedance 1 kOhm

POWER SUPPLY;

48 V phantom

Power consumption 2×4 mA

Polarization voltage 60 V

Connector pairs XLR-Cannon

Dimensions 385×460×210 mm(w×h×d)

Weight 4,9 kg

Headphone Playback Amplifier

AMPLIFIER SPECIFICATIONS:

Frequency range: 1 Hz-50 kHz

Max. sound pressure

with Stax headphone

at 1 kHz: 115 db

Distortion

(1 kHz, 100 dBsp1): co. 0 15%

Dynamic range: >100 dB

Level range: 41-134 dB

Adjustable: in 1-dB steps

Equalization: FF/ID/Lin

Inputs: BNC unbalanced L+R channel

Input impedance: 100 kohm

Equalization: according to equalization chosen on input, Output impedance: c100 ohm

Max. output voltage: 14 Veff

Additional outputs: BNC unbalanced L+R channel Equalization: Linear

Output impedance: c100 Ohm

Max. output voltage: 7 Veff

POWER SUPPLY:

Power supply: ._. loo-120v

_{—}200-240 V

.50/60 Hz

Power consumption: 70 w

HOUSING:

Diplomat housing

with low-noise ventilator

Dimensions: Height:=18 cm

Width:=48 cm

Depth:=33 cm

Weight: 11,1 kg

Stax Lambda SR Pro Headphones

HEADPHONE SPECIFICATIONS

Frequency range: 8 Hz -35 kHz

Distortion: CO, 1% at 100 dB spl at 100 Hz Impedance: 129 kohm at 10 kHz

Electrostatic capacity: 122 pf

Sensitivity: 100 Volt for 100 db at 1 kHz

Maximum peak level: 118 db at 400 Hz

Bias voltage: 580 V DC

Input connector: 6-pole LEMO

Length of cable: 2,4 m

Weight: 450 g (total weight)

340 g (headphone only)

Meyer HD-1 Loudspeakers

ACOUSTICAL-HD-1 SYSTEM (EACH LOUDSPEAKER)

Frequency Response 32 Hz to 22 kHz

Free Field −3 dB at 32 Hz and 22 kHz

+ldB from 40 Hz to 20 kHz

Maximum SPL 125 dB SPL peak (120 dB 81 meter) Signal-to-Noise Ratio >100 dB (noise floor 20 dBA 81 meter)

AUDIO INPUT Type

Connector

Nominal Input Level

AMPLIFIERS Type

Power Output

Low Frequency High Frequency THD, IM, TIM

Electronically balanced, 1 Ok ohms impedance XLR (A-3)female

Accepts either +4 dBU or −10 dBV, switchable′

Complementary power MOSFET output stages

150 watts burst capal$y 75 watt: 2;; capabrllty

0

CROSSOVER

TRANSDI JCERS

Low Frequency

High Frequency

AC POWER

PHYSICAL

Dimensions

Weight

Control rack:

AUDIO MONITORS: Headphone Amplifier: Headphone:

Speaker:

CONTROL MODULES:

PROCESSING RACK: Processing rack:

VIDEO MONITORS:

CRT:

trackballs.

PROCESSING MODULES: Processing Modules:

Optimized pole-zero filter combination to complement

transducer response and to achieve acoustical transparency and flat phase

8″ diameter cone (2″ voice coil)

1″ dome tweeter

3-pin IEC male receptacle, Voltage selector switch

for 100/120/220/240 VAC, 50 or 60 Hz (accepts voltage from 90 to 260 VAC)

16″ H×12″ W×14″ D (+2″ additional depth for amplifier chassels and HF dome clearance)

51 Ibs. (23 kg.)

33″ Rack flight case

Alto to processor rack

Special headphone amplifier system

Stax SR Lambda Pro Headphones

Meyer HD-1 reference speakers

Mic pre-amps (g-channels)

4 Band parametric EQ (4 channels)

Speaker level control (4 channels)

Patch bay

Panasonic SV3900 DAT recorder w/full remote

43″ Rack flight case

Alto to control rack

2 NEC 14″ Multisync 3D-S, high resolution monitors w/keypads and Logitech and Kensington

Location DSP's

Room simulation DSP's

A/D and D/A convertors

Hard drives (2)

Floppy drives (2)

.-.

Input: Apogee A/D 500 (18 bit conversion)

output: -.. A gee A/D 1000 (20 bit conversion) Connections: $VW-XLR

RCA

Another implementation of a virtual audio processing system is as follows:

Virtual Audio is a new process of encoding audio in three dimensions, passively or interactively. Virtual Audio requires no special decoding equipment and provides a very accurate model of our hearing process. Virtual Audio is so accurate that the listener cannot distinguish Virtual Audio recorded sound from reality. Playback can be experienced on two stereo speakers or standard headphones. Virtual Audio systems is currently developing a fully computerized, three-dimensional, multichannel, spatial audio processor that fully simulates the human auditory system, while accurately simulating acoustic responses of sound incidence to a given environment relative to the listener, interactively and in real time. With these new tools, we are able to study psychological phenomena of sound in the human mind that was previously not possible.

The Selective Hearing Process:

In the field of audio, the selective hearing process is fundamental to stress-relief. The selective hearing process in the human auditory system is the ability of the brain to tune into audio cues and tune out unwanted audio cues in the listener's environment. Selective hearing means listening only to audio cues that the listener wants to hear and not to those he does not want to hear, all at the same time. The selective hearing process can be conscious or subliminal. With normal recording technology, the selective hearing process, once recorded, is lost. The human brain can no longer selectively hear. The brain will try very hard to distinguish individual audio cues or try to break down the basic components of the audio cues, but will be unsuccessful. Normal recording methods do not encode the three-dimensional spatial cues necessary for the brain to carry out the selective hearing process. The brain will be unable to pull apart or selectively hear different component audio cues. The exception being that, if the volume of a specific audio cue is very loud, the brain will then be able to perceive the louder sound. Cues that are the same approximate volume will all blend in together. Since the brain is trying very hard to decipher different sounds unsuccessfully, a type of stress is induced. This stress will inhibit the listener from being emotionally involved with the audio cues. Using the sound of nature or music can be very important for relaxation, meditation and the relief of stress. With the use of Virtual Audio, the natural phenomenon of selective hearing is retained in the recording process. Sounds recorded with this method enable the human brain to do what it normally does in nature: to selectively hear various component audio cues in the listening environment.

IMPORTANT!

VAPS MK VIII Documentation

Preliminary Version 1.6

The Virtual Audio Processing System MK VIII (VAPS MK VIII)is a more advanced system than its predecessor, the VAPS MK IV Prototype. The new VAPS MK VIII has many improvements over the VAPS MK IV. These improvements and features lead to many more possibilities in creating Virtual Audio environments for recording or live concerts.

VAPS MK VIII Basic Features

1. Eight Input Channels/Spatial Coordinates

2. Auto Pan Controller (APC)Moves sound in 360_(XYZ Axis)

3. System is Midi controlled from SMPTE

4. Control of up to eight “walls” with Room Simulation in real time.

5. Sixteen audio outputs plus a stereo mix out.

6. Advanced transsexual processing for speakers or headphone playback compatibility.

7. Auto level and mute on individual channels via Midi.

8. System configuration is optimized for both studio and live concerts.

9. Unlimited number of channels can be processed in real time.

10. Forty automated auxiliary inputs (Five for each of the eight spatial coordinates)

11. Midi light controller

The VAPS MK VIII

The Vaps MK VIII Processing begins at the mixing console in the studio or live concert (see FIG. 1). The VAPS MK VIII requires sixteen busses of the mixing board to operate at its full potential. The first eight busses are routed to the Auto Pan Controller (APC)section of the system. I

Panned Source Channels Buss 1-8

The Auto Pan Controller (APC)

The APC is an eight input eight output panning system which can rotate eight separate mono sound sources through eight locations in space (Rack 1). These positions in space are called spatial coordinates and are user definable under Midi control. The APC uses an “Expansion” algorithm that automatically adjusts the volume and size dynamics as a sound moves through space, changing the perceived distance of the sound from the listener.

In physical space, the perceived amplitude of sound drops proportionally to its distance. The APC mirrors this phenomenon by changing the amplitude of the source sound, decreasing it as it moves away from the listener. The scope of this effect is adjusted with the expansion control so as to create sound fields that can vary continuously in size between the following two extremes:

A: a small sound field in which, the perceived amplitude remains the same wherever the source sound moves.

B: a very large sound field, in which the perceived amplitude nearly disappears as the source sound moves to the edge of the sound field. The Expansion function contains distance parameters that are sent to the room simulators. As a sound moves away from the listener, the reverb will get more intense and when the sound comes closer to the listener the reverb will decrease.

The distance parameters are the inverse of the source and sent as Midi data to the Room Simulation Input Level and Mute Automation/Mix module of the VAPS MK VIII.

The Expansion function greatly improves the reality of a sound moving through space and saves much time trying to program these dynamic changes separately.

Spatial Coordinates

The VAPS MK VIII can create up to eight spatial coordinates that can be stored and recalled from memory through Midi control. These spatial coordinates determine where a sound can be panned in space. Many configurations are possible. A typical example of the placement of these coordinates are shown below (see FIG. 2).

A=O_Front Horizontal

B=180_Behind Horizontal

C=270_Left Horizontal

D=90_Right Horizontal

E=t90_Above Vertical

F=−90_Below Vertical

G=306_Mid-left Horizontal

H=54_Mid-right Horizontal

Using the APC, a sound source can be panned in a 360_horizontal and vertical space.

The spatial coordinates can be entered using:

A. The joystick (internally or externally)

8. The internal sequencer in the APC itself.

C. With an external interface (Midi)

The APC section also features a scale function which is used to expand or reduce the size of the spatialization pattern within the sound field. This feature is also controllable through Midi:

Automated Level and Mute Control

The audio is then sent to automated level controls for fine tuning of volume dynamics of each of the eight separate sound sources that have the APC function assigned to them (see also Auxiliary Inputs).

Static Source Channels Buss 9-16

The static source channels begin in the mixing console on busses 9-16. These busses correlate to the spatial coordinates set in the APC. Using FIG. 2 as an example, the busses would equal the following coordinates: Buss

Buss

9=A=O_=Front Horizontal 10=B=180_=Behind Horizontal

11=C=270_=Left Horizontal 12=D=90_=Right Horizontal

13=E=+90_=Above Vertical 14=F=−90_=Below Vertical

15=G=306_=Mid-left Horizontal 16=H=54_=Mid-right Horizontal

By assigning a sound to buss 9, that sound would appear in the center front of the mix. Assigning a sound to buss 13, it would appear over your head. Assigning two busses, 11 and 12 for example, you will be able to position a sound anywhere between those two locations by using the pan pot on the mixing console. By assigning for example busses 11 and 14, you can pan a sound in an arc between these two coordinates using the mixing console pan pot. You will be able to pan up and down by panning between busses 13 and 14. By assigning reverb to all the busses, the reverb would come from all around the listener. Many combinations are possible.

By combining the panned source busses 1-8 and the static source busses in a mix, a complete 360_sound field can be created in which you can assign an unlimited number of sounds to be positioned anywhere in the horizontal and vertical planes. Up to eight sound sources can be assigned any pre-programmed motion or be moved in 369_in real time using the joystick.

The eight static sound sources are mixed with the APC sound sources in the eight Level and Mute Automation/Mix Modules. Each of the eight room simulators (walls)are also mixed here. Each spatial coordinate has its own Level and Mute Automation/Mix Module (Rack 2). For example using an assigned spatial coordinate of “A” O_, Mix Module number one would have channel one of the APC (“A” O_, channel one of the static source (“A” O_), and channel one of the room simulator (“A”″ O) routed to it; which is then mixed and summed together and sent to the Location Processor's channel one (also assigned as “A” O_). The eight Level and Mute Automation/Mix Modules are under separate Midi control for added dynamic effects.

Location Processor (Virtual Speaker Placement)

Eight separate channels of sound sources are sent from the eight Level and Mute Automation/Mix Modules to the eight A/D converters and then processed with a proprietary Head Related Transfer Function (HRTF)in the Digital domain within the Location Processor (Virtual Speaker Placement). Each channel of the Location Processor is controlled by its own DSP. The spatial coordinates in the Location Processor must match the coordinates set up in the APC spatial coordinate assign function. The end result is a Virtual Audio environment that is output to eighteen D/A converters, sixteen separate outputs or a stereo Virtual Audio mix (Rack 3).

Transaural Processors

Special Transaural Processors are used to do mild speaker crosstalk cancellation for each of the total of eighteen output channels. These processors do not degrade headphone listening but enhance and expand the image on speakers. These processors do not limit the listener to a sharp sweet spot, as is common with other systems. The processors can be switched out of the system if desired (Rack 4).

Multiple Outputs

The VAPS MK VIII has sixteen Multiple outputs and has stereo mix outputs for a total of eighteen outputs (Rack 4). The multiple outputs are grouped in stereo pairs because the HRTF is stereo (we have two ears). These eight pairs can be recorded on tape for studio use or multiple speaker channels can be used for live concert work. If less than sixteen speaker channels are desired, a mixer can be used to reduce the number of speaker channels; for example:

16×8

or

16×4

Multiple speaker channels are not required for the Virtual Audio effect. In fact, the stereo outputs will be used the most often. Two speakers are the minimum to experience Virtual Audio. If four speakers are used, (not four channels)and placed in the rear, the full Virtual Audio effect can be achieved. Only a stereo Left and Right channel playback system is required for full 360, horizontal and vertical sound fields to be experienced by the listener. Playback in mono is compatible with VAPS, but there will be no Virtual Audio effect although mono playback will be more clear using VAPS processing. Headphone listening is excellent and will reproduce the full Virtual Audio Effect.

Auxiliary inputs

The VAPS MKVIII has forty auxiliary inputs (Rack 2). These inputs are useful when volume or mute automation is required on the main mix console. There are five separately automated auxiliary inputs for every spatial coordinate used (eight maximum). When a sound is directionalized and does not require movement, but needs precise automated volume or mute control, it should be routed here.

Audio Synchronized Lighting Control

The VAPS MK VIII has the capability to control an external Midi light controller unit, although it could be used for other purposes (Rack 2). The Audio Synchronized Lighting Controller controls the transmission of a series of Midi messages proportional to the output amplitude of each of the APC's eight audio outputs. The external light controller translate these codes into voltages for light dimmers, effectively putting the lighting intensity under the VAPS MKVIII. All spatial pattern creation and manipulation capabilities of the VAPS MKVIII can then be used for special lighting effects.

By creating spatial coordinates with locations corresponding to those of lighting sources, the localized sound positions in the VAPS MKVIII will be directly linked to a “panning” of the light sources. Controlling both the VAPS MKVIII spatial coordinates and light sources can enhance spatialization effects.

The amount of messages sent by Audio Syncronized Lighting Controller increases with the sound source movements. For rapidly moving sound sources, the density of messages will be high (up to 200 per second). The APC's Midi messages can be recorded on a Midi Sequencer like any other Midi messages: They will show as regular notes on the sequencer.

THE VAPS MKVIII HARDWARE

The VAPS MKVIII is designed and built for both studio and live sound work. It is solidly constructed for travel with minimum worries about system failure, The VAPS MKVIII is a sophisticated machine, so some care in transport is recommended. Given reasonable care, the system should function reliably under normal tour conditions.

The VAPS MKVIII is built into four, 26 space racks. Each mounting rack is shock protected by foam around the outside, then surrounded by the main outer rack. These are standard heavy duty flight cases designed for touring.

Each rack has its own power supply with conditioned power. Each rack also has cooling fans that create the proper airflow to keep the components at a safe operating temperature.

The audio specifications are as follows I

1. The Automated Panning Control module:

THD: 0.008% S/N: −90 dB Frequency Response: 10 Hz to 20 khz t/−1 dB Dynamic Range: 95 dB

2. The Automated Mixing module:

THD: 0.01% S/N: −98 dB Frequency Response: 5 Hz to 80 khz +/−1 dB Dynamic Range: 116 dB

3. Room Simulators:

THD: 0.03% S/N: −78 dB Frequency Response: 20 Hz to 15 khz +/−1 dB Dynamic Range: 95 dB

4. Location Processor:

THD: −94 dB S/N: −95 dB Frequency Response: 20 Hz to 20 khz +/−0.025 dB Dynamic Range: 95 dB 44.1 khz or 48 khz sampling rates. AES EBUlSPDIF

5. A/D and D/A converters (Apogee):

THD: −94 dB S/N: −95.5 dB Frequency Response: 10 Hz to 20 khz +/−0.025 dB Dynamic Range: 95 dB AID=18 bits D/A=20 bits 44.1 khz or 48 khz sampling rates. AES EBUISPDIF

6. Transaural Processor:

THD: 0.03% S/N: −99 dB Frequency Response: 10 Hz to 150 khz +/−2 dB Dynamic Range: 103 dB

Overview

The Virtual Audio Mixer: (FIG. 1)

A. The Virtual Audio-Mixing Console Consists of eight pairs of joysticks for entering x, y, z, coordinates. One pair for each APC. Along with. these joysticks is a 32 fader, Midi automated mixing console for programming volume levels and mutes. These faders are the 100 mm type. The mixing console consists of four, eight channel modules. Each module is capable of controlling up to 64 channels in eight banks of eight channels each. These mixers control:

1. Input levels to the Room Simulators.

2. Input levels to the A/D converters of the Location Processor from each of the eight spatial coordinate channels of the APC.

3. Input levels to the AID converters of the Location Processor from each of the eight channels of static source sounds (8 busses from the main mix console).

4. Input Levels to the AID converters of the Location Processor from each of the eight channels of the Room Simulators.

5. Input levels to the A/D converters of the Location Processor from each of the forty auxiliary input channels.

B. The control interface to the Location Processor is a DOS 486 based PC. Using this terminal allows control and placement of the eight spatial coordinates (Virtual Speaker Placement). Input and output levels to and from the location Processor can be monitored and controlled in the digital domain via a digital mixer in the software. All spatial and level configurations can be stored here.

C. The control interface for the Room Simulators, APC, Automated Level /Mute Control is handled from a Macintosh computer using Studio Vision and special Room Simulation software.

Rack #1. Automated Panning System

The Automated Panning System contains the first processor modules in the audio chain. This rack contains eight APC's, one automated level /mute modules, and a conditioned power supply.

Rack #2. Room Simulation System

The Room Simulation System contains eight Room Simulation processors. This rack also contains 4 Automated level/mute modules, two Midi Timepiece II modules, a Macintosh II computer, and a conditioned power supply.

Rack #3. Location Processor System.

The A/D D/A Conversion System contains six A/D converters, ten D/A converters with eight dual power supplies. This rack also contains the Location Processors and conditioned power supply.

Rack #4. Transaural Processing System.

The Transaural Processing System contains nine Transaural Processors, a headphone amplifier, and conditioned power supply.

A number of embodiments of the invention have been described. Nevertheless, it will be understood that various modifications may be made without departing from the spirit and scope of the invention. For example, the apparatus and methods can be implemented in, or as a part of various systems and methods. For example, it may be used in vector modeling: Essentially, vector modeling is the numerical modeling of the transfer functions of a dummy head and of the external ear. The numerical model is created in a computer. By using physics calculations of how sound propagates around the head and shoulders in various environmental conditions simulated in the computer, head related transfer functions (HRTFs) can be derived. With today's computer power, vector modeling can be calculated in real-time. The advantages of this approach are superior to the brute force method of loading a lookup table of HRTF measurements taken in the field. With the vector approach any size head can be simulated. Since the head model is created mathematically, any component such as the pinna, the shoulders, and dimensions of the head can be altered to create many variations of the HRTF's. The listener's head could be simulated to optimize his own perception of 3-D space. Tests have shown that individualized HRTFs provide a better 3-D effect than generic (averaged) HRTFs. Furthermore, hyper effects can be created, such as enlarging the pinnae to twice the size enabling the listener to perceive sounds a great distance. Environmental effects can be also calculated. By specifying the size of the space, the shape, and the absorption/reflection characteristics of the walls, as well as air absorption and temperature, real-time auralization can be realized. This is the definitive new direction in 3-D sound technology.

Advanced 3-D graphic user interfaces (“GUI”) can be created for the VAPS. The creation of complex virtual acoustic environments demand a GUI that is intuitive, and allows user interaction in real-time over the many complex parameters required to generate a convincing and accurate model. The graphics should be seen in 3-D to better parallel the 3-D space metaphor. At the same time, wearing common virtual reality devices (such as data gloves or helmets) are not always practical for everyday work. The graphic monitor can use the dual pixel method of creating a 3-D image without any kind of eye-ware. The GUI allows the user to visualize any room and rotate that room on any axis to gain information about what is going on in the room. The user is able to reach out with his/her hand and grab the room and twist and turn it in any direction. A new control concept called a “Virtual Mouse” would be used to accomplish these types of tasks, described further below. Virtual audio sound objects would have graphic representations to help the user identify sounds in a complex environment. The user can at any time plot the trajectory (i.e., motion path) of any sound object and edit its path. The user can create as many walls in a room as required. Collision detection is implemented so the user can define if two sound objects are occupying the same space. A positional object tracking/capture and reconstruction system also can be implemented so that trajectory information can be plugged into any environment separately from the sound object itself. Time code is implemented (SMPTE) for synchronizing trajectories with visual information such as a film and television. Video edge detection technology is implemented to predict dimension information for sound objects from a two dimensional video.

For a room to have detailed realism, objects such as furniture need to be represented. This is accomplished by implementing 3-D graphic objects (much like a 3-D graphic program), placing them in the room, and covering them with audio texture maps. The GUI is multi-level in that simple tasks can be accomplished easily as a top layer. As more complex tasks are required, the user can move through deeper levels of complexity. The concept here is that people work different ways on many different types of projects. The GUI complexity should only be reflected by the complexity of the task at hand. This concept keeps the user working as expediently and as efficiently as possible without needless levels of commands that the user dose not need.

A three-D infrared hand tracking system (e.g., a Virtual Mouse) also can be implemented for a virtual audio processing system: The Virtual Mouse is a hand tracking system that allows the user to have total freedom of hand movement within a specified zone and allows the user to interact with the graphics in the computer. The concept is that the hand is scanned with infrared beams from x, y, and z directions. When the hand is submerged into this zone, a displacement of light occurs, very much like putting a one's hand in water. This displacement of the infrared beam is sensed and translated into number coordinates, thereby effectively creating a virtual hand in the computer. As the user moves his real hand, a graphic representation on the screen also moves in real-time. The user can grab objects on the screen and move them in any direction. Software control gives the user the ability to customize the tracking speed, the sensitivity of the interaction of objects etc. This concept is much more practical for working in three-space than a Data Glove or joysticks.

A positional object tracking/capture and reconstruction system (“POTCR”) can be used with and for the VAPS. The POTCR is a motion capture technology that allows motion data to be captured in the field, locked to time code so that later the motion data can be loaded into the VAPS and assigned one or more sounds. An example of its use is for dialog for a film. Typically, it is time consuming for the VAPS operator to create trajectory information to match the motion of a performer talking on the film. On the film location, such as outdoors somewhere, the POTCR motion tracker, which is implemented as a very small object, is attached to the actor. The tracker sends out motion data in x, y and z coordinates as the actor is moving. The trajectory is synchronized to time code. This allows the motion data to be synced to the recorded audio/film track. It is common for dialog that is recorded outdoors to be re-recorded in the studio for better quality. This is called dialog replacement or “looping”. When the VAPS operator is given the new, higher quality audio, the motion path of the location shoot is loaded into the VAPS. The new audio is assigned to that motion path using the time code as reference for the start times. New audio is placed on the original motion data and is in sync with the picture and, advantageously, it takes only a few moments. This is a very efficient way of saving time on tasks that can be very complicated and time consuming.

A Virtual Audio Visual detection System (“VAVDS”) can be implemented for blind people. This is a system that allows blind people to “see” by using virtual audio technology. Basically, using ultra sound to reflect off physical objects in the environment and bounce those signals back the blind or visually impaired person can virtually “see” based on the characteristics of the sound the person hear. This device can be implemented as an apparatus that appears like a head band with ultra sound transmitters and receivers mounted around it. Once the ultra sound is received at the headband it is converted into the normal audio band and processed into directionalized Virtual Audio signals using one or more of the techniques described above. The user wears small in-ear headphones that also allow the user to hear normal sounds in the environment. The Virtual Audio signals are then converted to audio that is reverb or ambient in nature but are directionalized as a point source. The user would hear different colors of sound that have x, y and z direction. These colors form an audio sound-scape that reflect the objects in the room.

A blind person would very quickly actually “see” (i.e., hear) the room in his head based on the sound colors. For example, the colors would be more dense and dark as the represented object gets closer to the person. Objects that are further away would be a lighter sound. The walls, floor and ceiling would be a light colored sound that would encompass the listener in a 360 degree space. The accuracy of ultra sound in bats and dolphins is well known. A dolphin at, for example, Sea World can tell the difference between a dime and a nickel at the bottom of the pool using ultra sound alone. Implementing this technology with sufficient training of the user can result in a blind person being able to eventually tell the difference between a knife and a fork at the dinner table. It is even possible that the VAVDS has advantages over visual data because the blind person can hear (see) in 360 degrees. He can see behind him, something that human sight cannot do. As such, the VAVDS can be used by people without hearing impairment to augment their sensory perceptions.

The system and methods can be implemented with a video edge detection converter for the VAPS. This technology is based on Video Edge Detection technology developed by StarBridge super computer company. StarBridge has developed a technology that allows x, y and z coordinate data to be extracted from a two dimensional image. A Video Edge Detection Converter is a device that turns graphic coordinate data into data that can place sound objects in a three dimensional space based on two dimensional data such as a movie film or television.

Even though video and film graphics are not three dimensional, the VAPS can create a three dimensional Virtual Audio environment that exactly matches the actual space represented in two dimensions. This can be done automatically using the Video Edge Detection Converter. All coordinates of the room would be created automatically, advantageously saving the VAPS operator time in creating a room to match the video.

The system and methods can be used with audio texture maps. For example, when a VAPS operator is creating a room, the total cubic space has to first be defined. The air absorption and temperature is then determined. Finally the absorption/reflection characteristics are implemented. The final action that gives a room definition and character are the objects one finds in a room, such as furniture, tables, shelves etc. Other past 3-D systems did not take these objects into account. Primarily this is because other systems were not detailed enough that one could tell a difference. In use, the VAPS operator would create a 3-D object much like a simple 3-D graphics program. Simple objects could be created within VAPS or imported using standard graphics formats such as DXF. Once the operator creates an object such as a couch, the Audio Texture Map is applied. An Audio Texture Map works the same way as a graphic texture map does. It is a map that is wrapped around the object to give it a quality. In graphics, it gives the object the appearance that it is made of rock or wood by using a picture of rock or wood and wrapping it around the object. In Virtual Audio technology, the map is made up of Sabine coefficients. As noted and described herein, Sabine coefficients are the mathematical equivalents to absorption and reflection characteristics of materials in a room such as walls and furniture. The Audio Texture Map interacts with the reflections of the room and the head measurements to create a composite I-IRTF in real-time. The movement of the head through a room would be exceptionally realistic. For example, if a user puts their head very near the couch and someone called from across the room, the reflections would be absorbed by the couch the same way they would in a real environment. These Audio Texture Maps could be applied to walls, ceiling and floors as well. Special effects could be created by morphing or cross fading Audio Texture Maps with other Audio Texture Maps. Simulations such as moving water could be created by animating the cross-fading and morphing the maps.

These Audio Texture Maps can be measured using Sabine math. A library is built for the operator to choose what they need quickly. Another approach is that the operator creates their own Audio Texture Maps using Procedural Audio Texture Maps. These maps are made up of an algorithm whose parameters can be changed by the operator to synthesize any type of Audio Texture. These parameters can be automated by the VAPS to advantageously create many interesting effects.

A Virtual Audio Interactive Brainwave Feedback System can be used implementing the systems and methods herein, and is used to help patents in the medical field. The Virtual Audio Interactive Brainwave Feedback System is designed to help patents with the process of visualization. For example, patents that are undergoing radiation therapy for cancer are very weak and it is difficult for them to expend their energy for visualization techniques that may improve their condition. The Virtual Audio Interactive Brainwave Feedback System puts patents into a high definition virtual acoustic environment such as a forest with a gentle stream running nearby. The environments are so real that it takes very little energy for the patent to relax into this world. Meanwhile, the doctor/therapist is monitoring the brainwave activity through a high quality EEG system, for example, Random Electronics Design's IBVA system. This EEG is wireless so as to be as non-intruding as possible to the patent. The EEG is programmable and runs on a Macintosh computer. It is possible, for example, to program a narrow band of Alpha waves, although a full range is possible including REM, Alpha, Theta, Beta, Delta, etc.). When the patent reaches this state (i.e., a good state for health), the EEG program triggers a MIDI (Musical Instrument Digital Interface) event that turns on and controls a Positional Audio channel of a special version of VAPS. In this example, this Positional Audio channel is programmed with the movement of a bird flying and singing in virtual space. The bird comes flying into the forest environment that the patent is virtually immersed within. The bird is a natural occurrence in nature so it is a pleasant experience and keeps the patent in Alpha. As long as the patent is in the Alpha wave state, the bird keeps flying around, and the system may use its interactive features. For example, during this state, the bird gets closer to the patent or chirps different songs as the strength of Alpha waves get stronger. Similarly, the bird flies away if the Alpha waves get weak. In this way, a doctor can create a program that is designed specifically for the individual patent's problem or condition. An entire session can be recorded for further analysis by the doctor/therapist, including the brainwave activity, as well as playback of the actual audio events triggered by the patent.

The Virtual Audio Interactive Brainwave Feedback System is basically divided into two parts, a hardware part and a software part. The hardware part includes a high resolution VAPS, a headphone system, and an IBVA system. The software includes standard therapy programs that have been designed by medical doctors. The software can be licensed and various software programs would be an ongoing development. An entire business can be created with this system, including selling the hardware and the software to medical professionals.

Accordingly, other embodiments are within the scope of the following claims.

What is claimed is:

1. A sound processing apparatus for creating virtual sound sources in a three dimensional space, the apparatus comprising:
an aural exciter module;
an automated panning module;
a distance control module;
a delay module;
an occlusion and air absorption module;
a Doppler module for pitch shifting;
a location processor module; and
an output.

2. The sound processing apparatus of claim 1 wherein the aural exciter module is configured to receive an input from a multi-track output.

3. The sound processing apparatus of claim 1 wherein the delay module is configured to delay sound for between 0 milliseconds and 300 milliseconds.

4. The sound processing apparatus of claim 1 wherein the location processor module is configured to use head related transfer functions to process a signal.

5. The sound processing apparatus of claim 1 wherein the location processor module is configured to use a FIR filter to process a signal.

6. The sound processing apparatus of claim 1 wherein the location processor module is configured to use a free field equalization to process a signal.

7. A sound processing apparatus for creating virtual sound sources in a three dimensional space, the apparatus comprising:
means for providing direct audio signals;
reverberation means for creating at least one reverberant stream of signals from the audio signals to simulate a desired configuration of reflected sound; and
directionalizing means for applying spectral directional cues to one or multiple reverberant streams to generate at least one pair of output signals.

8. The apparatus of claim 7 wherein multiple reverberant streams are generated by the reverberation means and the directionalizing means is configured to apply a directionalizing transfer function to each reverberant stream to generate multiple directionalized reverberant streams from each reverberant stream.

9. The apparatus of claim 8 further comprising output means for producing a multiple of output signals, each output signal comprising the sum of multiple directionalized reverberant streams, each being derived from a different reverberant stream.

10. The apparatus of claim 8 wherein each reverberant stream includes at least one direct sound component and wherein a free field directional cue is superimposed on the direct sound component.

11. The apparatus of claim 8 further comprising a stereo filter means for filtering at least one pair of directionalized reverberant streams.

12. The apparatus of claim 8 further comprising a gain control configured to emphasize at least one part of one reverberant stream.

13. The apparatus of claim 8 further comprising specifications of a reverberant apparatus for the application of scaling data to the audio signals to simulate sound absorption and reflection.

14. The apparatus of claim 8 further comprising specifications of a reverberant apparatus for the implementation of a filter to filter the audio signals to simulate sound absorption and reflection.

15. A method of processing sound signals comprising of steps of:
generating at least one reverberant stream of audio signals simulating a desired configuration of reflected sounds; and
superimposing at least one spectral directional cue on at least part of one reverberant stream.

16. The method of claim 15 wherein generating at least one reverberant stream comprises generating at least one direct sound component as part of the reverberant stream.

17. The method of claim 15 further comprising filtering at least one of the reverberant streams.

18. The method of claim 15 further comprising emphasizing at least part of one reverberant stream.

19. The method of claim 15 wherein generating at least one reverberant stream further comprises filtering during generation of the reverberant stream to simulate sound absorption and reflection.

20. The method of claim 15 further comprising dynamically changing the spectral directional cues to simulate sound source and listener motion.
